(19) United States
(12) Patent Application Publication
(10) Pub. No.: US 2015/0083180 A1
(43) Pub. Date: Mar. 26, 2015

(54) SYSTEMS, METHODS AND/OR APPARATUS FOR THERMOELECTRIC ENERGY GENERATION

(71) Applicant: Electron Holding, LLC, Las Vegas, NV (US)

(72) Inventor: Daniel Stewart Lang, Las Vegas, NV (US)

(21) Appl. No.: 14/358,688

(22) PCT Filed: Nov. 15, 2012
(86) PCT No.: PCT/US12/65170

§ 371 Date: May 15, 2014

Related U.S. Application Data
(60) Provisional application No. 61/647,863, filed on May 16, 2012.
(60) Provisional application No. 61/648,034, filed on May 16, 2012.

(51) Int. Cl. H01L 35/30

(52) U.S. Cl. CPC H01L 35/30
USPC 136/207

(57) ABSTRACT

Systems, methods and/or apparatus for the conversion of various types of energy into thermal energy that may be stored and/or then converted into electrical energy. The electrical energy may be available on demand and/or at a user's desired power requirements (e.g., power level and/or type). For example, the energy may be available at a particular voltage and either as direct current (DC) energy or alternating current (AC) energy. The electrical energy may be easily transported and therefore available at a user's desired location. For example, the systems, methods and/or devices may eliminate or reduce the need for electricity transmission, at least for certain applications. In exemplary embodiments, the system may include an organic phase change material for storing the thermal energy.

### CROSS-REFERENCE TO RELATED APPLICATIONS

This application claims priority to U.S. Provisional Application No. 61/647,863, filed on May 16, 2012, U.S. Provisional Application No. 61/648,034, filed on May 16, 2012, International Application No. PCT/US2011/060937, filed on Nov. 16, 2011, and International Application No. PCT/US2011/060942, filed on Nov. 16, 2011. This application is also related to U.S. Provisional Application No. 61/413,995, filed on Nov. 16, 2010 and U.S. Provisional Application No. 61/532,104, filed Sep. 8, 2011. Each of these applications is herein incorporated by reference in their entirety.

### FIELD

This disclosure generally relates to generally to the conversion of a thermal energy into electrical energy. This disclosure is also generally related to the conversion of a temperature difference into electrical energy.

### BACKGROUND

It is becoming more important to reduce the amount of energy generated by consumable heat source power plants, (e.g., natural gas, coal, fossil fuel, nuclear, etc.) and replace them with renewable and/or clean energy sources.

A challenge faced by current renewable clean energy technologies is that they are almost as, and in some cases more, complicated than the legacy technologies they are attempting to replace. Most of these technologies are focused on alternative generation of electricity and they miss the fact that most of the inefficiencies in getting the energy to the customer occur along the countless steps between the conversion into electrical energy and the actual use of the energy.

Factoring in the energy consumed developing, deploying and maintaining both the new and old technologies there often insufficient return of the investment.

There is a need for improved systems, devices, and/or method directed to localized, sustainable, and/or renewable clean energy that can be stored more efficiently and then converted into electrical energy when desired. The present disclosure is directed to overcome and/or ameliorate at least one of the disadvantages of the prior art as will become apparent from the discussion herein.

### SUMMARY

Exemplary embodiments relate to the conversion of various types of energy into thermal energy that may be stored and/or then converted into electrical energy. In exemplary embodiments the electrical energy may be available on demand and/or at a user's desired power requirements (e.g., power level and/or type). For example, the energy may be available at a particular voltage and either as direct current (DC) energy or alternating current (AC) energy.

In exemplary embodiments, the electrical energy may be easily transported and therefore available at a user's desired location. For example, in exemplary embodiments, the systems, methods and/or devices may eliminate or reduce the need for electricity transmission, at least for certain applications.

In exemplary embodiments, the thermal energy may be locally stored.

In exemplary embodiments, the system may include organic phase change material(s) for storing the thermal energy. In addition, other types of phase change materials for storing the thermal energy are also contemplated.

In exemplary embodiments, the system may include a petroleum-based phase change material (e.g., paraffin) for storing the thermal energy.

In exemplary embodiments, the system may include a mineral based-phase change material (e.g., salt hydrates) for storing the thermal energy.

In exemplary embodiments, the system may include a water based-phase change material (e.g., water) for storing the thermal energy.

In exemplary embodiments, the system may include an organic phase change material for storing the thermal energy.

In exemplary embodiments, two thermal mass types (hot and cold or a first temperature or temperature range and a second temperature or temperature range, wherein the first is greater than the second in order to create a sufficient thermal difference) may be used and in exemplary embodiments, one or both of the materials may be pre-charged and provided to a user in a state ready for use by an end user.

In exemplary embodiments a system for converting thermal energy into electrical energy may comprise: a thermoelectric generator; a high temperature storage in contact with a first side of the thermoelectric generator; a low temperature storage in contact with a second side of the thermoelectric generator; a high temperature regenerator for maintaining the high temperature storage at a high temperature; and a low temperature regenerator for maintaining the low temperature storage at a low temperature. The difference in the temperatures of the high temperature storage and the low temperature storage creates a thermal difference between the two sides of the thermoelectric generator that creates the electrical energy.

In certain embodiments, at least one first temperature storage material and at least one second temperature storage material may be used to create a temperature differential. In addition, a combination of first temperature materials and a combination of second temperature materials may be used to create a temperature in combination with one or more thermal electric generators to generate electricity. In exemplary embodiments, the high temperature storage and low temperature storage are phase change materials. In certain embodiments, the higher temperature storage and lower temperature storage materials may be organic phase change materials, other types of phase change materials, batteries, engines, solar, geothermal, electromagnetic, differences in ambient environmental temperatures, heat exhaust, heat waste exhaust, or combinations thereof.

In exemplary embodiments, the electrical energy is DC current.

In exemplary embodiments, the high temperature regenerator comprises: a thermoelectric generator that uses the high temperature storage on one side and an ambient temperature (that is sufficiently lower than the higher temperature) on the other side to create a temperature difference across the thermoelectric generator. The thermal difference across the thermoelectric generator generates electrical energy.

In certain embodiments, at least a portion of the electrical energy of the at least one first temperature regenerator is used to power a thermal source to keep the at least one first temperature storage at an appropriate temperature. In exemplary embodiments, the electrical energy of the high temperature regenerator is used to power a heater to keep the high temperature storage at a high temperature. In certain embodiments, at least a portion of the electrical energy of the higher temperature regenerator is used to power a heater to keep the higher temperature storage at a higher temperature. In certain embodiments, at least a portion of the electrical energy of the higher temperature regenerator is used to power a heating source to keep at least in part the higher temperature storage at a higher temperature.

In certain embodiments, at least a portion of the electrical energy of the at least one second temperature regenerator is used to power a thermal source to keep the at least one first temperature storage at an appropriate temperature. In exemplary embodiments, the electrical energy of the second temperature regenerator is used to power a heating or cooling source to keep the second temperature storage at a second temperature. In certain embodiments, at least a portion of the electrical energy of the second temperature regenerator is used to power a heating or cooling source to keep the second temperature storage at a second temperature. In certain embodiments, at least a portion of the electrical energy of the second temperature regenerator is used to power a heating or cooling source to keep at least in part the second temperature storage at a second temperature.

In exemplary embodiments, the lower temperature regenerator comprises: a thermoelectric generator that uses the lower temperature storage on one side and an ambient temperature on the other side to create a temperature difference across the thermoelectric generator. The thermal difference across the thermoelectric generator generates electrical energy.

In exemplary embodiments, the electrical energy of the lower temperature regenerator is used to power a chiller to keep the lower temperature storage at a low temperature.

In exemplary embodiments a system for converting thermal energy into electrical energy may comprise: a thermoelectric generator means for converting a temperature difference into electrical energy; a high temperature storage means for storing thermal energy in contact with a first side of the thermoelectric generator means; a low temperature storage means for storing thermal energy in contact with a second side of the thermoelectric generator means; a high temperature regenerator means for maintaining the high temperature storage means at a high temperature; and a low temperature regenerator means for maintaining the low temperature storage means at a low temperature. The difference in the temperatures of the high temperature storage means and the low temperature storage means creates a thermal difference between the two sides of the thermoelectric generator means that creates the electrical energy.

In exemplary embodiments, the high temperature storage means and low temperature storage means are phase change materials.

In exemplary embodiments, the electrical energy is DC current.

In exemplary embodiments, the high temperature regenerator means comprises: a thermoelectric generator means for converting a temperature difference into electrical energy that uses the high temperature storage means on one side and an ambient temperature on the other side to create a temperature difference across the thermoelectric generator means. The thermal difference across the thermoelectric generator means generates electrical energy.

In exemplary embodiments, the electrical energy of the high temperature regenerator means is used to power a heater means to keep the high temperature storage means at a high temperature.

In exemplary embodiments, the low temperature regenerator means comprises: a thermoelectric generator means for converting a temperature difference into electrical energy that uses the low temperature storage means on one side and an ambient temperature on the other side to create a temperature difference across the thermoelectric generator means. The thermal difference across the thermoelectric generator means for converting a temperature difference into electrical energy generates electrical energy.

In exemplary embodiments, the electrical energy of the low temperature regenerator means for storing thermal energy is used to power a chiller to keep the low temperature storage at a low temperature

As well as the embodiments discussed in the summary, other embodiments are disclosed in the specification, drawings and claims. The summary is not meant to cover each and every embodiment, combination or variations contemplated with the present disclosure.

### DESCRIPTION OF THE DRAWINGS

Exemplary embodiments will now be described, by way of example only, with reference to the accompanying drawings in which:

FIG. 1 is a schematic drawing of an exemplary embodiment of a thermoelectric energy generation system;

FIG. 2 is a schematic drawing of another exemplary embodiment of a thermoelectric energy generation system;

FIG. 3 is a schematic drawing of another exemplary embodiment of a thermoelectric energy generation system;

FIG. 4 is a schematic drawing of another exemplary embodiment of a thermoelectric energy generation system;

FIG. 5 is a schematic drawing of another exemplary embodiment of a thermoelectric energy generation system;

FIG. 6 is a schematic drawing of another exemplary embodiment of a thermoelectric energy generation system;

FIG. 7 is a schematic drawing of another exemplary embodiment of a thermoelectric energy generation system;

FIG. 8 is a schematic drawing of another exemplary embodiment of a thermoelectric energy generation system;

FIG. 9 is a schematic drawing of another exemplary embodiment of a thermoelectric energy generation system;

FIG. 10 is a schematic drawing of another exemplary embodiment of a thermoelectric energy generation system;

FIG. 11 is a schematic drawing of another exemplary embodiment of a thermoelectric energy generation system;

FIG. 12 is a schematic drawing of another exemplary embodiment of a thermoelectric energy generation system;

FIG. 13 is a schematic drawing of another exemplary embodiment of a thermoelectric energy generation system;

FIG. 14 is an exploded view of an exemplary embodiment of a thermoelectric device that may be utilized in exemplary thermoelectric energy generation systems;

FIG. 15 is an isometric view of an exemplary embodiment of a thermoelectric device that may be utilized in exemplary thermoelectric energy generation systems;

FIG. 16 is a plan view of an exemplary embodiment of a thermoelectric device that may be utilized in exemplary thermoelectric energy generation systems;

FIG. 17 is a cross-sectional view of an exemplary embodiment of a thermoelectric device that may be utilized in exemplary thermoelectric energy generation systems;

FIG. 18 is an isometric view of an exemplary embodiment of semiconductor posts that may be used in exemplary embodiments of thermoelectric devices;

FIG. 19 is a plan view of an exemplary embodiment of semiconductor posts that may be used in exemplary embodiments of thermoelectric devices;

FIG. 20 is a cross-sectional view of an exemplary embodiment of semiconductor posts that may be used in exemplary embodiments of thermoelectric devices;

FIG. 21 is a schematic drawing of another exemplary embodiment of a thermoelectric energy generation system;

FIG. 22 is a schematic drawing of another exemplary embodiment of a thermoelectric energy generation system;

FIG. 23 is a schematic drawing of another exemplary embodiment of a thermoelectric energy generation system;

FIG. 24 is a schematic drawing of another exemplary embodiment of a thermoelectric energy generation system;

FIG. 25 is a schematic drawing of another exemplary embodiment of a thermoelectric energy generation system;

FIG. 26 is a schematic drawing of another exemplary embodiment of a thermoelectric energy generation system utilizing spent nuclear fuel rods as the harvested heat source;

FIG. 27 is a schematic drawing of another exemplary embodiment of a thermoelectric energy generation system;

FIG. 28 is a schematic diagram of an exemplary embodiment of a solar thermal and photovoltaic energy harvesting system to provide buildings with thermoelectric electricity, hot water, comfort heating, comfort cooling or combinations thereof;

FIG. 29 is a plan view and corresponding elevation and isometric views of an exemplary embodiment of a solar thermal collection system;

FIG. 30 is a plan view with corresponding section views of an exemplary embodiment of a solar thermal collection system;

FIG. 31 is a plan view and corresponding elevation, section and isometric views of an exemplary embodiment of a solar thermal hot water tank;

FIG. 32 is a plan view and corresponding elevation views of an exemplary embodiment of a thermoelectric comfort heating and/or comfort cooling system;

FIG. 33 is plan view and corresponding isometric views of an exemplary embodiment of a thermoelectric comfort heating and/or comfort cooling system;

FIG. 34 is plan view and corresponding section views of an exemplary embodiment of a thermoelectric comfort heating and/or comfort cooling system;

FIG. 35 is an isometric view and corresponding detail views of an exemplary embodiment of a thermoelectric comfort heating and/or comfort cooling system;

FIG. 36 is a plan view and corresponding elevation and isometric views of an exemplary embodiment of a thermoelectric cooling system;

FIG. 37 is plan view and corresponding section and detail views of an exemplary embodiment of a thermoelectric cooling system;

FIG. 38 is a plan view and corresponding elevation and isometric views of an exemplary embodiment of a portable thermoelectric heating, cooling and/or electrical generation system;

FIG. 39 is an elevation view and corresponding section views of an exemplary embodiment of a portable thermoelectric heating, cooling and/or electrical generation system;

FIG. 40 is an elevation view and corresponding other elevation, plan and isometric views of an exemplary embodiment of a thermoelectric solid-state refrigeration system;

FIG. 41 is a plan view and corresponding section and detail views of an exemplary embodiment of a thermoelectric solid-state refrigeration system;

FIG. 42 is a schematic section view of an exemplary embodiment of a thermoelectric harvesting configuration;

FIG. 43 is a block diagram of an exemplary embodiment of a thermoelectric generating system utilizing multiple thermal regeneration methods for use in, for example, land vehicles;

FIG. 44 is a schematic diagram of an exemplary embodiment of a thermoelectric regenerating system thermal energy harvester for use in, for example, land vehicles during sunlight and in warm to hot temperatures;

FIG. 45 is a schematic diagram of an exemplary embodiment of a thermoelectric regenerating system thermal energy harvester for use, in for example, land vehicles during cloudy to dark and in cool to freezing temperatures;

FIG. 46 is a schematic diagram of an exemplary embodiment of a thermoelectric generating system for use, in for example, marine vessels;

FIG. 47 is a schematic diagram of an exemplary embodiment of a thermoelectric generating system for use for the production of hydrogen gas from water by means of electrolysis;

FIG. 48 is a schematic section of an exemplary embodiment of a thermoelectric solid-state chiller system for the purposes of, for example, cooling nitrogen gas into a liquid from average ambient temperatures;

FIG. 49 is a schematic section of an exemplary embodiment of a thermoelectric generator with sufficiently isolated high and low temperature storage.

FIG. 50 is a schematic diagram of an exemplary embodiment of an electromagnetic and/or thermal energy harvesting power supply for use, in for example, mobile phones and/or handheld devices;

FIG. 51 is a schematic diagram of an exemplary embodiment of cross-section A of the exemplary power supply of FIG. 50;

FIG. 52 is a schematic diagram of an exemplary embodiment of cross-section B of the exemplary power supply of FIG. 50;

FIG. 53 is a schematic diagram of an exemplary embodiment of cross-section C of the exemplary power supply of FIG. 50;

FIG. 54 is a schematic diagram of an exemplary embodiment of a thermoelectric harvesting device and/or generator that may be utilized in large industrial facilities, that permits the recycling and/or storing of wasted thermal energies and the converting of such wasted thermal energies to electrical energy;

FIG. 55 is an isometric section of an exemplary embodiment of a thermoelectric generator, heater and/or cooler for use in vertical farming;

FIG. 56 is an isometric section of an exemplary embodiment of a thermoelectric generator, heater and/or cooler powered vertical farming grow cell; and

FIG. 57 is an isometric view of an exemplary embodiment of a thermoelectric device.

FIGS. 58 and 59 are schematic diagrams of an apparatus developed to test the benefits of organic phase change materials over water and chemical based phase change materials for use in thermoelectric energy generation.

### DETAILED DESCRIPTION

Exemplary embodiments described in the disclosure relate to the conversion of various types of energy into thermal energy that may be stored and/or then converted into electrical energy. The thermal energy also may be used for other purposes as well such as heating and/or cooling. As will be readily understood by a person of ordinary skill in the art after reading this disclosure, the exemplary embodiments described herein may be beneficial for environment as well as economic reasons. In exemplary embodiments, the electrical energy may be easily transported and therefore available at a user's desired location reducing transportation costs etc. In exemplary embodiments, the systems, methods and/or devices may eliminate or reduce the need for electricity transmission, at least for certain applications, thereby reducing the need for electricity generation based, on for example, fossil fuels. In exemplary embodiments, the thermal energy may be locally stored. In other exemplary embodiments, the thermal energy may be stored and be mobile. In exemplary embodiments, the system may include an organic phase change material, for storing the thermal energy, thereby reducing non-biodegradable waste generated by the system.

In certain embodiments, systems, methods and/or devices are disclosed that may provide, for example, comfort heating, comfort cooling, hot water heating, refrigeration, electrical energy or combinations thereof, wherein such embodiments may be partially, substantially, or completely independent of electrical grid energy and/or fossil fuels. Certain embodiments may be at least 20%, 40%, 50%, 60%, 75%, 85%, 90%, 95%, or 99% independent of the electric grid energy and/or fossil fuels for the operating period. Certain embodiments may be between 20% to 99%, 20% to 40%, 10% to 30%, 20% to 50%, 40% to 99%, 50% to 100%, 70% to 95%, 65% to 100%, 80% to 95%, 80% to 100%, 90% to 99% or 90% to 100% independent of the electric grid energy and/or fossil fuels for the operating period. Certain embodiments may provide a return of the investment within 6 months, 1 year, 2 years, 2.5 years, 3 years, 5 years or 10 years. In exemplary embodiments, buildings or other structures may be retrofitted or built without the need of natural gas, or a reduced need of natural gas, being delivered for heating and/or cooking requirements. In certain embodiments, this could be done at a cost that is 10%, 20%, 30% or 50% less than that of conventional methods. In certain embodiments, buildings or other structures may be retrofitted or built wherein at least 40%, 50%, 60%, 70%, 80%, 90%, 95% or 100% of the natural gas used for providing heating and/or cooking requirements is eliminated. In certain embodiments, buildings or other structures may be retrofitted or built wherein at least 40%, 50%, 60%, 70%, 80%, 90%, 95% or 100% of the natural gas used for providing heating and/or cooking requirements is eliminated. Combinations of reducing the need for grid electricity, power plant generated electricity, fossil fuel generated power, and/or natural gas is also contemplated.

In certain embodiments, land vehicles may be manufactured and/or retrofitted to eliminate or reduce the use of fossil fuels or, on electric vehicles, chemical batteries. Certain embodiments may reduce the need for fossil fuels and/or chemical batteries by at least 20%, 40%, 50%, 60%, 75%, 85%, 90%, 95%, or 100%. Certain embodiments may reduce the need for fossil fuels and/or chemical batteries by between 20% to 99%, 20% to 40%, 10% to 30%, 20% to 50%, 40% to 99%, 50% to 100%, 70% to 95%, 65% to 100%, 80% to 95%, 80% to 100%, 90% to 99% or 90% to 100% for a portion of the operating period, a substantial amount of the operating period, or for the entire operating period. Such systems, methods and/or devices may reduce the initial cost, the maintenance cost and/or the recurring fuel cost associated with land vehicles.

In certain embodiments, marine vessels may be manufactured or retrofitted to eliminate or reduce the need of fossil fuel, or in the case of electric marine vessels, to eliminate or reduce the need of chemical batteries and/or the electrical energy cost of recharging those batteries. In certain embodiments, the associated cost of disposing of chemical batteries is eliminated or reduced. In certain embodiments, the solid-state nature of certain disclosures substantially or completely reduces the cost of maintenance and/or replacement. In certain embodiments, building cost may be reduced, or substantially reduced, by the elimination, or reduction, of grid tie methods such as transformers and large gauge wiring. In certain embodiments, the size and cost of solar and/or wind energy generations may be reduced, or substantially reduced, when the energy is converted into thermal energy and stored, in for example, the organic phase change material. Due to the efficiency of the thermal storage, the use of batteries and/or solar tracking systems may be eliminated or reduced, further reducing the cost of purchase and/or maintenance. Additional advantages will be apparent to a person of ordinary skill in the art. Certain embodiments may reduce the need for fossil fuels and/or chemical batteries by at least 20%, 40%, 50%, 60%, 75%, 85%, 90%, 95%, or 100%. Certain embodiments may reduce the need for fossil fuels and/or chemical batteries by between 20% to 99%, 20% to 40%, 10% to 30%, 20% to 50%, 40% to 99%, 50% to 100%, 70% to 95%, 65% to 100%, 80% to 95%, 80% to 100%, 90% to 99% or 90% to 100% for a portion of the operating period, a substantial amount of the operating period, or for the entire operating period.

As used herein, the terms a “first temperature” and a “second temperature” are used in terms of a relevant comparison wherein the first temperature is higher than the second temperature. These terms also may cover temperature ranges as well, wherein the “first temperature” and the “second temperature” cover temperature ranges and the first range is higher, or substantially higher, then the second temperature range. In certain embodiments, there may be a partial overlap of the first temperature range and the second temperature range. In certain embodiments, the overlap may be between 0% to 10%, 0% to 20%, 1% to 8%, 2% to 5%, 4% to 8%, 0.5% to 3%, 0% to 5%, 0% to 2%, etc. In certain embodiments the “first temperature” may vary ±0.5%, 1%, 5%, 10%, 20%, 40%, 50%, 60%, 80%, 100%, 125%, 150%, or 200%. In certain embodiments the “first temperature” may vary by at least ±0.1%, 0.25%, 0.5%, 1%, 5%, 10%, 20%, 40%, 50%, 60%, 80%, 100%, 125%, 150%, 200% etc. In certain embodiments the “first temperature” may vary by less than ±0.5%, 1%, 5%, 10%, 20%, 40%, 50%, 60%, 80%, 100%, 125%, 150%, 200%, etc. In certain embodiments the “second temperature” may vary by ±0.5%, 1%, 5%, 10%, 20%, 40%, 50%, 60%, 80%, 100%, 125%, 150%, 200%, etc. In certain embodiments the “second temperature” may vary by at least ±0.1%, 0.25%, 0.5%, 1%, 5%, 10%, 20%, 40%, 50%, 60%, 80%, 100%, 125%, 150%, 200%, etc. In certain embodiments the “second temperature” may vary by less than ±0.5%, 1%, 5%, 10%, 20%, 40%, 50%, 60%, 80%, 100%, 125%, 150%, 200%, etc. Combinations of the variation in the “first temperature” and the “second temperature” are also possible in certain embodiments. In certain embodiments, there may also be additional temperatures such as a “third temperature”, a “fourth temperature” etc. In certain embodiments at least 1, 2, 3, 4, 5, 6, 7, 10, or more temperature differences may be used.

Using the “first temperature” and “second temperature” as exemplary illustrations, this could mean a first and second temperature wherein both hotter than a typical room temperature; a first and second temperature wherein both are cooler than a typical room temperature; or wherein the first temperature is greater than a typical room temperature and the second temperature is less than a typical room temperature. As used herein, the terms “high temperature and “low temperature” are also used in terms of a relevant comparison where the high temperature is greater than the low temperature. As used herein, the terms “higher temperature and “lower temperature” also are used in terms of a relevant comparison where the higher temperature is greater than the lower temperature.

Designing the desired level of the voltage and current being supplied from the system(s), method(s) and/or device(s) may be a useful end result in certain embodiments. It is often an advantage if the system, method and/or device that provides the generation of electricity can provide that electricity at a specific level of voltage and current or a substantially specific level of voltage and current. Because of the electrical properties of thermoelectric generator modules, their electrical output being based on series connections of the individual couples in the module, a maximum voltage and current is “built-in” to the thermoelectric module that is based on a thermal difference on either side. By using specific temperature differences and electrically connecting the individual modules in either series or parallel a number of power output options may be designed into the system. Certain embodiments of the present disclosure may provide voltages of 12, 24, 48, 110, 120, 230, 240, 25 kV or 110 kV. Other higher and lower voltages are also contemplated. Certain embodiments of the present disclosure may be designed to have an output of voltage in increments as low as millivolts and current as low as milliamps e.g., −75 mV to 900 mV and 0.01 mA to 900 mA. Other suitable ranges may also be used. Certain embodiments of the present disclosure may provide a system with multiple differing electrical outputs available to a user. Certain embodiments of the present disclosure may enable the user to adjust the electrical output by allowing the module connections to be altered on demand, or substantially on demand, by way of jumpers that, are typically used in the electronics industry.

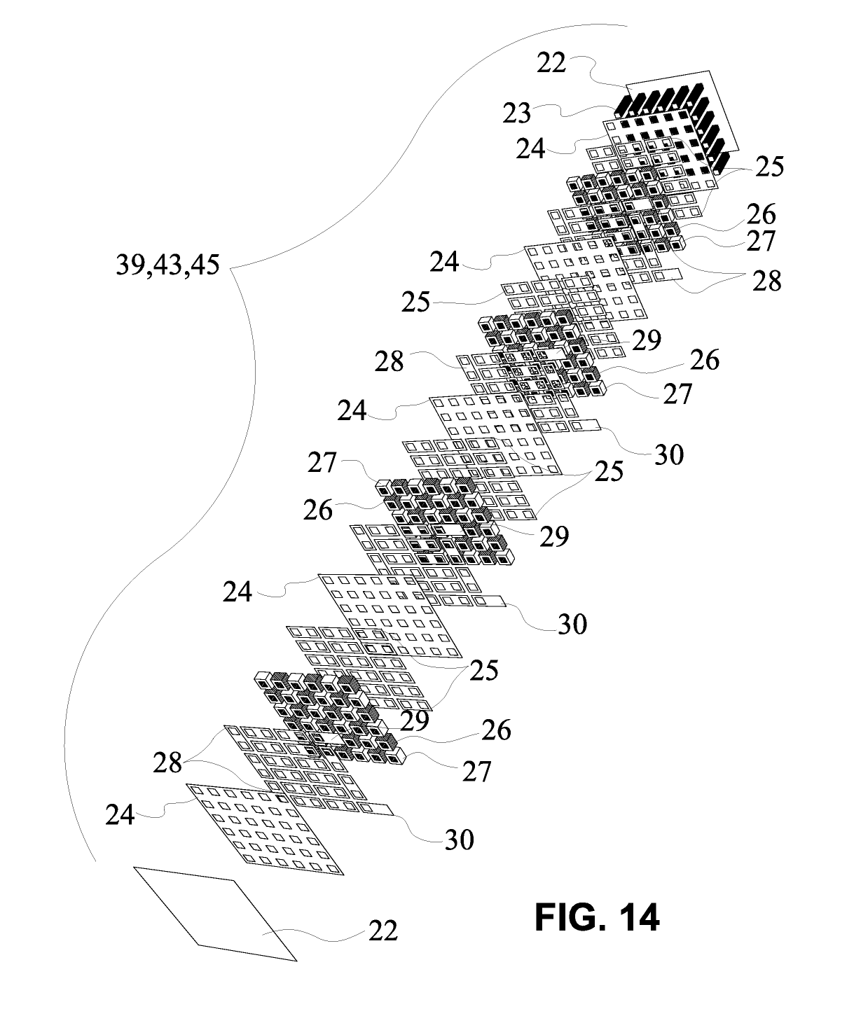

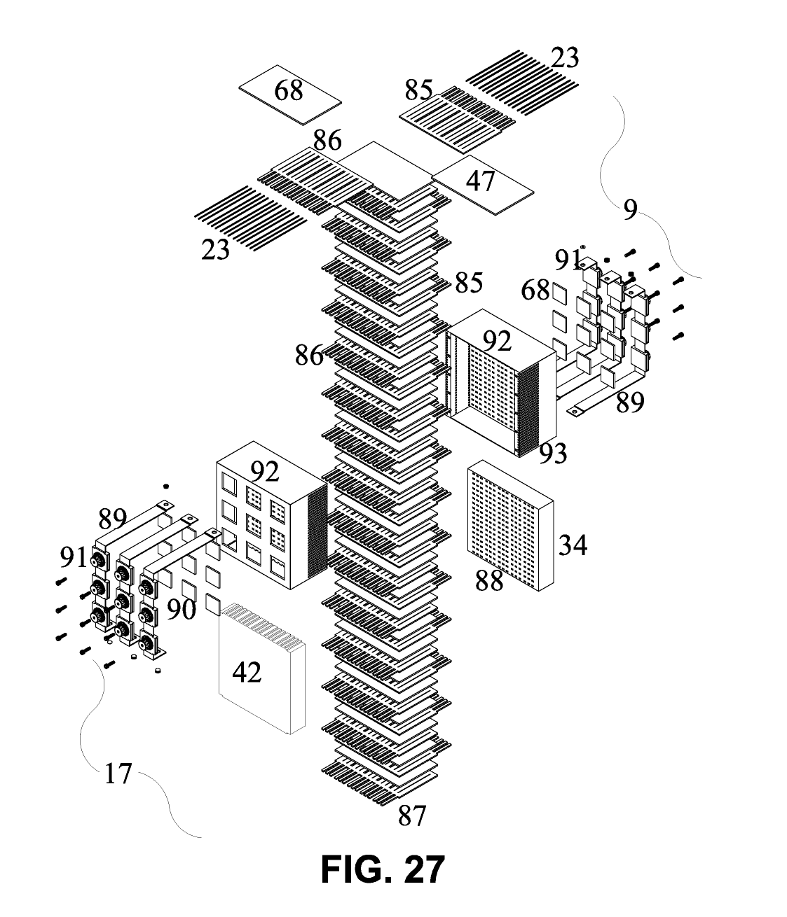

Another advantage of certain embodiments is the high Watts per square millimeter that may be delivered. Certain embodiments of the present disclosure may enable the system to be designed in three dimensions allowing for a smaller square footage footprint. By vertically stacking embodiments, for example as shown in FIG. 14 or 27, systems may be constructed that allow increased amounts of electricity to be generated in the footprint provided. With other renewable energy sources such as photovoltaic and wind, there is less ability of gaining more power per square millimeter or per square meter by adding panels or turbines above or below one another. Because of the remote thermal communication nature of the thermal storage and the thermoelectric modules, the stacking of thermoelectric modules with thermal transport layers into the thermal storage reservoirs increases Watts per square millimeter. For example, if a single 50 square millimeter thermoelectric module is thermally connected to a low temperature thermal storage reservoir on one side and is thermally connected to a high temperature thermal storage reservoir on the other providing it a thermal difference of, for example, 150° C. it may yield 8 Watts of power or 0.16 Watts per square millimeter. By adding a second 50 square millimeter thermoelectric module thermally connected to the same low temperature thermal storage reservoir on one side and thermally connected to the same high temperature thermal storage reservoir on the other also providing it a thermal difference of, for example, 150° C. the yield is now 16 Watts of power or 0.32 Watts per square millimeter. This may be done on larger or smaller footprints up to structurally reasonable heights. In certain embodiments, the stack comprises at least 1, 2, 3, 4, 5, 6, 7, 8, 10, 15, 20, 30, 40, 100, etc. of the thermoelectric modules. In certain embodiments, the stack comprises between 2 to 100, 2 to 5, 5 to 30, 5 to 10, 5 to 15, 10 to 50, 25 to 50, 40 to 80, 50 to 200, etc. of the thermoelectric modules. The stacked modules may be in thermal communication to a similar number of higher temperature thermal storage reservoirs and/or a similar number of lower thermal storage reservoirs. In some aspects of the technology, less thermal storage reservoirs may be needed because a thermal reservoir may act as the higher thermal reservoir for one thermoelectric module and the lower thermal reservoir for another thermoelectric module. Certain embodiments, may use at least 1, 2, 3, 4, 5, 6, 7, 8, 9, 10, 15, 20, etc. temperature differences in the stack. Various combinations of the number of stacked thermoelectric modules, the number of thermal storage reservoirs, and the number of temperature difference are contemplated. The stacking may be done in a vertical construction, a substantially vertical construction, a horizontal construction, a substantially horizontal construction, other three dimensional constructions, or combinations thereof.

Certain embodiments are directed to systems that use at least a portion of the electrical energy generated by the thermoelectric generators to power heaters and/or chillers that at least in part assist in maintaining the phase change materials at the appropriate temperature. Using thermal differences that are available to the system and by allocating at least a portion of the electrical energy generated to power devices that at least in part assist in maintaining the phase change materials at the appropriate temperature, certain embodiments are able to extend the operating time of the system without having to rely on other power sources. For example, if a system is able to sustain its power generation by taking advantage of the thermal energy provided by sunlight and some other source of cooler thermal energy when the sunlight is not available, the system is still able to operate and generate electricity for a longer period of operating time by using at least a portion of the electrical energy generated to continue to heat the phase change material on the higher temperature side.

In certain embodiments, the system is able to operate in a self sustaining manner between 30% to 50%, 40% to 60%, 50% to 70%, 30% to 95%, 50% to 100%, 70% to 95%, 80% to 98%, 90% to 99.5%, or 80% to 100% of the desired operating period. Certain embodiments are directed to a system that may provide sufficient electricity between 30% to 50%, 40% to 60%, 50% to 70%, 30% to 95%, 50% to 100%, 70% to 95%, 80% to 98%, 90% to 99.5%, 95% to 100%, or 80% to 100% of the time that the system is in operation. Certain embodiments are directed to a system that may provide sufficient electricity, heating and/or cooling between 30% to 50%, 40% to 60%, 50% to 70%, 30% to 95%, 50% to 100%, 70% to 95%, 80% to 98%, 90% to 99.5%, 95% to 100%, or 80% to 100% of the time that the system is in operation. Certain embodiments are directed to a system that may provide sufficient electricity, heating and/or cooling between 30% to 50%, 40% to 60%, 50% to 70%, 30% to 95%, 50% to 100%, 70% to 95%, 80% to 98%, 90% to 99.5%, 95% to 100%, or 80% to 100% of the time that the system is in operation without the need for supplemental external power sources.

Certain embodiments disclose a system wherein at least a portion of the electrical energy of the at least one first temperature regenerator is used to power a heating or cooling source to keep the at least one first temperature storage at, or substantially at, a first temperature or temperature range; and at least a portion of the electrical energy of the at least one second temperature regenerator is used to power a heating or cooling source to keep the at least one second temperature storage at a second temperature, or substantially at a second temperature range; wherein the first temperature is higher than the second temperature and the system provides sufficient electricity between 30% to 50%, 40% to 60%, 50% to 70%, 30% to 95%, 50% to 100%, 70% to 95%, 80% to 98%, 90% to 99.5%, 95% to 100%, or 80% to 100% of the time that the system is in operation.

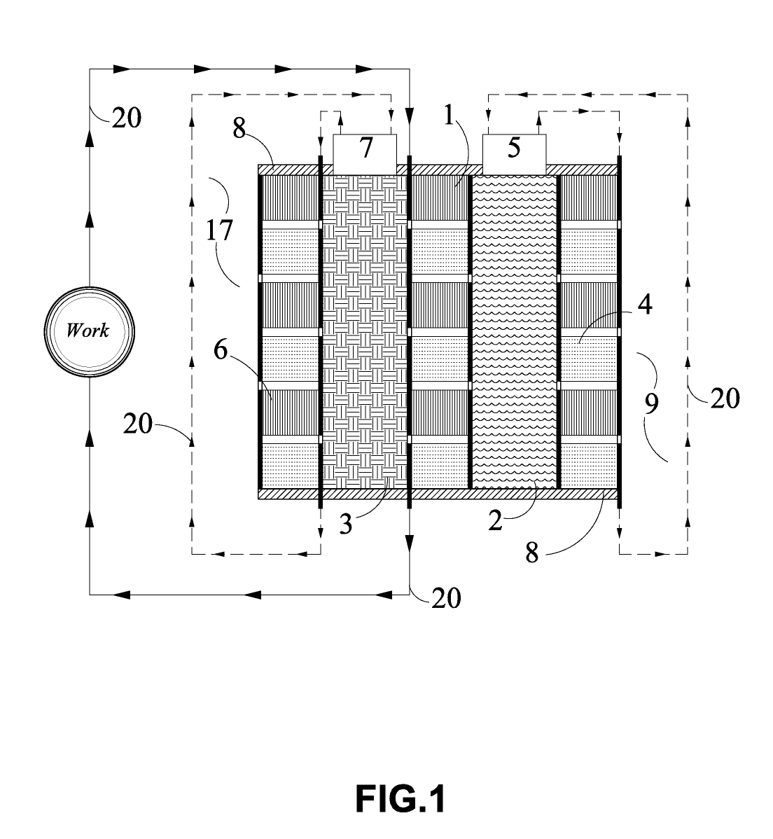

Certain embodiments are directed to a system for converting thermal energy into electrical energy comprising: at least one thermoelectric generator; a first temperature storage material in substantially direct or indirect contact, with a first side of the thermoelectric generator; a second temperature storage material in substantially direct or indirect contact with a second side of the thermoelectric generator; a first temperature regenerator for maintaining at least in part the first temperature storage material at a first temperature; and a second temperature regenerator for maintaining at least in part the second temperature storage material at a second temperature, wherein the difference in the temperatures of the first temperature storage material and the second temperature storage material creates a thermal difference between the two sides of the thermoelectric generator which creates the electrical energy and wherein the system provides sufficient electricity between 30% to 50%, 40% to 60%, 50% to 70%, 30% to 95%, 50% to 100%, 70% to 95%, 80% to 98%, 90% to 99.5%, 95% to 100%, or 80% to 100% of the time that the system is in operation. In certain embodiments, the first and/or second temperature regenerators may be replaced, partially replace, or supplemented with an alternative power source. The applications and locations of use of the technology disclosed herein are broad. The number of suitable sources of regeneration of the thermal storage, whether it be higher or lower, is also broad. Some examples for direct or indirect heat regeneration may be solar thermal, geothermal, waste industrial heat, volcanic, spent nuclear fuel rods, heat from chemical reactions, heat from metabolism, heat from electrical resistance and waste biofuel burning, or combinations thereof. Some examples for heat regeneration, by powering a heater, may be photovoltaic, wind energy, hydroelectric, kinetic to electrical, electromagnetic, piezoelectric, thermodynamic and other types of harvested waste energy sources that may be available at specific locations or combinations thereof. Some examples for direct or indirect cooling regeneration may be bodies of water, subterranean structures, caves, ice, snow, city waterlines, city sewer-lines, high altitudes, and substances under high atmospheric pressures or combinations thereof. Some examples for cold regeneration by powering a chiller may be photovoltaic, wind energy, hydroelectric, kinetic to electrical, electromagnetic, piezoelectric, thermodynamic and other types of harvested waste energy sources that may be available at specific locations or combinations thereof. The above non-limiting listed examples may also be combined in various suitable manners. FIG. 1 is a schematic drawing of an exemplary embodiment of a thermoelectric energy generation system. The system in FIG. 1 includes a thermoelectric generator 1. One side of the thermoelectric generator is placed in contact, or in thermal communication with, high temperature storage 2 while the other side is placed in contact, or in thermal communication with, low temperature storage 3. The difference in the temperatures of the high temperature storage 2 and the low temperature storage 3 creates a large thermal difference between the two sides of the thermoelectric generator 1 which creates an electrical output. For example, in the exemplary embodiment of FIG. 1, the electrical output is identified by direct current 20 that flows between positive and negative terminals.

A thermoelectric generator is a device that converts heat (i.e., a temperature difference as described herein) into electrical energy, using a phenomenon called the “thermoelectric effect”. The amount of temperature difference that may be used may vary depending on a number of factors, including but not limited to, the type of thermoelectric generator used in a particular embodiment, the type of phase change material used or the type of regeneration system(s) used.

In exemplary embodiments such as the one illustrated in FIG. 1, the high temperature storage 2 may be kept at a high temperature by employing a high temperature regenerator 4. In certain embodiments, the higher temperature storage may be kept at a higher temperature by employing at least 1, 2, 3, 4, 5, or 6 high temperature regenerator(s), other sources of the higher temperature energy or combinations thereof. In exemplary embodiments, the high temperature regenerator 4 may comprise a thermoelectric generator 1. In certain embodiments, the high temperature regenerator may comprise at least 1, 2, 3, 4, 5, 6, or other sources of the higher temperature or combinations thereof. The thermoelectric generator 1 of the high temperature regenerator 4 operates in a substantially similar manner to the originally described thermoelectric generator 1 except it uses the high temperature storage 2 on one side and high temperature ambient temperature 9 on the other side to create a temperature difference across the thermoelectric generator 1. The thermal difference across thermoelectric generator 1 creates an electrical output identified by direct current 20. The electrical output of thermoelectric generator 1 may be used to power a heater 5 which may be used to keep high temperature storage 2 at a high temperature. In certain embodiments, the electrical output of at least one thermoelectric generator may be used to power at least one heater and/or other sources of energy, such as thermal energy, may be used to keep the higher temperature storage at a higher temperature.

Similarly, in exemplary embodiments such as the one illustrated in FIG. 1, the low temperature storage 3 may be kept at a low temperature by employing a low temperature regenerator 6. In certain embodiments, the lower temperature storage may be kept at a lower temperature by employing at least 1, 2, 3, 4, 5, or 6 low temperature regenerator(s), other sources of the lower temperature energy or combinations thereof. In exemplary embodiments, the low temperature regenerator 6 may comprise a thermoelectric generator 1. In certain embodiments, the lower temperature regenerator may comprise at least 1, 2, 3, 4, 5, 6, other sources of the lower temperature, or combinations thereof. The thermoelectric generator 1 of the low temperature regenerator 6 operates in a substantially similar manner to the originally described thermoelectric generator 1 except it uses the low temperature storage 3 on one side and low temperature ambient temperature 17 on the other side to create a temperature difference across the thermoelectric generator 1. The thermal difference across thermoelectric generator 1 creates an electrical output identified by direct current 20. The electrical output of thermoelectric generator 1 may be used to power a chiller 7 which may be used to keep the low temperature storage 3 at a low temperature. In certain embodiments, the electrical output of at least one thermoelectric generator may be used to power at least one chiller and/or other sources of energy, such as thermal energy, may be used to keep the lower temperature storage at a lower temperature. The sources of thermal energy may be selected from various sources that produce suitable thermal energy. For example, a lower temperature source may be a building's concrete slab or foundation, a large body of water, an aquifer, a geothermal loop, a city water main, a vehicle's metal chassis, the outdoor temperature in cooler climate zones or ice or snow in cooler climate zones or combinations thereof.

In exemplary embodiments, the surfaces of the high temperature storage 2 and low temperature storage 3 may be insulated with an insulating barrier 8 to help conserve the thermal energy stored in the materials. In certain embodiments, at least a portion of the surfaces of the high temperature storage 2 and/or the low temperature storage 3 is insulated, or substantially insulated, with an insulating barrier 8 to help conserve the thermal energy stored in the materials

In certain embodiments, the surface of the phase change material may be in direct contact, or in thermal communication with, the surface of the thermoelectric generator. The amount of contact, or thermal communication, either direct or indirect, between at least a portion of the surface of the phase change material and/or at least a portion of the thermoelectric generator may vary depending upon the particular configuration of the embodiment selected. In certain embodiments, at least a portion of the surface or a substantial portion of the surface, of the phase change material may be in direct contact, or in thermal communication with, at least a portion of the surface, or a substantial portion of the surface, of the thermoelectric generator. In certain embodiments, the surface of the phase change material may be in indirect contact with the surface of the thermoelectric generator. In certain embodiments at least a portion of the surface or a substantial portion of the surface of the phase change material may be in indirect contact with at least a portion of the surface or a substantial portion of the surface of the thermoelectric generator. In certain embodiments, there may be, as illustrated in FIG. 1, a spacer material that is in thermal communication or contact with, the surface of the phase change material and also in thermal communication, or contact with, the surface of the thermoelectric generator. This spacer material may be made of various materials, such as silver, copper, gold, aluminum, beryllium or some thermally conductive plastics, polymers, or combinations thereof. In certain embodiments, the spacer material may be part of the thermal electric generator used; the spacer material may be part of the surface of container being used to hold the phase change material; a separate spacer; or combinations thereof.

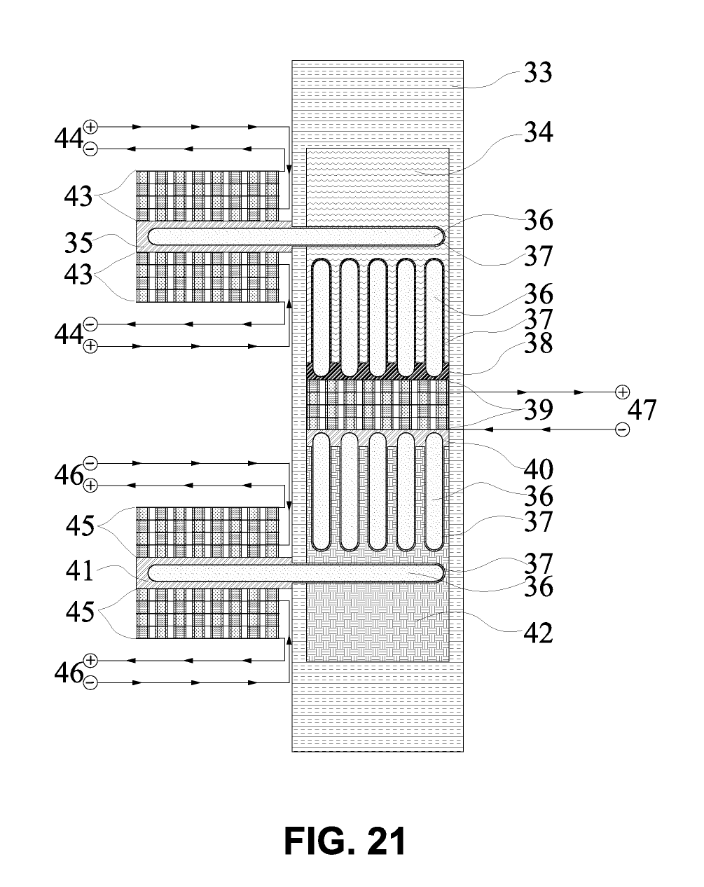

In certain embodiments, various configurations and/or structures may be used to transport, conduct and/or move thermal energy from the thermal storage material to the surface of the thermoelectric generator. This may be done using one or more of the four fundamental modes of heat transfer; conduction, convection, radiation and advection. For example, the phase change material may be in thermal communication with the surface or surfaces of the thermoelectric generator by the use of some type of heat pipe or heat conduit, (for example, the configurations illustrated in FIGS. 21, 22, 23, and 24). In certain embodiments, there may be advantages to thermally isolating the higher temperature thermal storage material and/or the lower temperature thermal storage material from each other and/or the surfaces of the thermoelectric generator. Thermal isolation may be accomplished in a number of suitable ways including, but not limited to, increasing the distance between the higher and/or lower thermal sources, insulating the higher and/or lower thermal sources, treating the surfaces of thermoelectric generator, treating the surface of the thermal storage container, magnetism of certain materials, actively chilling the area to be isolated from heat energy or combinations thereof. In certain embodiments, the structure used for transporting, conducting and/or moving thermal energy from the thermal storage material to the surface of the thermoelectric generator may include fluids within the heat pipe, (e.g., water, ammonia, acetone, helium, pentane, toluene, chlorofluorocarbons, hydrochlorofluorocarbons, fluorocarbons, propane, butane isobutene, ammonia, or sulfur dioxide or combinations thereof).

In exemplary embodiments, the phase change material may be an acceptable material or combinations of materials that achieves and maintain the desired temperature, temperatures or desired temperature range. Most commonly used phase change materials are chemical formulations derived from petroleum products, salts, or water. For example, water, water-based salt hydrates, various forms of paraffins, fatty acids and esters, trimethylolethane, organic thermal salts, inorganic thermal salts, ionic liquids, thermal composites, vegetable-based fats or oils, or combinations thereof. These types of phase change materials may be limited in temperature range options, containment methods, thermal cycles and/or latent heat capacities.

A phase change material is a material that uses phase changes (e.g., solidify, liquefy, evaporate or condense) to absorb or release large amounts of latent heat at relatively constant temperature. Phase change materials leverage the natural property of latent heat to help maintain products temperature for extended periods of time. In exemplary embodiments, the phase change material may be manufactured from renewable resources such as natural vegetable-based phase change materials. For example, in exemplary embodiments, the phase change materials may be a type manufactured by Entropy Solutions and sold under the name PureTemp. For example, PureTemp PT133 and PT-15 may be used wherein PT133 is the higher temperature phase change material used for storing thermal energy and PT-15 the lower temperature phase change material used for storing thermal energy. Another example would be using PureTemp PT48 and PT23 wherein PT48 is the higher temperature phase change material used for storing thermal energy and PT23 the lower temperature phase change material used for storing thermal energy.

In certain embodiments, phase change materials can be used in numerous applications so a variety of containment methods may be employed, (e.g., microencapsulation (e.g., 10 to 1000 microns, 80-85% core utilization)(e.g., 25, 50, 100, 200, 500, 700, 1000 microns etc.), macro encapsulation (e.g., 1000+ microns, 80-85% core utilization) (e.g., 1000, 1500, 2000, 2500, 300, 4000, 5000+ microns etc.), flexible films, metals, rigid panels, spheres and others). As would be understood by those of ordinary skill in the art, the proper containment option depends on numerous factors.

In certain embodiments, the number of thermal cycles that the phase change material may go through and still perform in a suitable manner may be at least 400, 1000, 3000, 5,000, 10,000, 30,000, 50,000, 75,000 or 100,000 thermal cycles. In certain embodiments, the number of cycles that the phase change material may go through and still perform in a suitable manner may be between 400 and 100,000, 5000 and 20,000, 10,000 to 50,000, 400 to 2000, 20,000 to 40,000, 50,000 to 75,000; 55,000 to 65,000 thermal cycles. PureTemp organic phase change material has been proven to retain its peak performance through more than 60,000 thermal cycles.

In exemplary embodiments, the temperature difference between the hot and cold phase change materials may be anywhere from a fraction of a degree to several hundred degrees at least in part depending on the power requirements. In exemplary embodiments, the phase change material heat differential may be capable of producing 1 watt of power with, e.g., 5 grams of phase change material or about 3.5 kilowatts with 1.3 kilograms of material. 100 watts with 50 grams of material, 500 watts with 200 grams of material, 1 kilowatt with 380 grams of material, 100 kilowatts with 22.8 kilograms of material or 1 Megawatt with 14 metric tons of material. As the mass of the thermal storage increases so does the power output per gram. Other ranges of kilowatts are also contemplated. Dimensionally, in exemplary embodiments, the system may be the size of a cell phone battery (e.g., 22 mm×60 mm×5.6 mm for 1 watt) (e.g., 0.7, 0.8, 0.9, 1, 1.1, 1.2, 1.3, 1.4, 1.5, 1.6, etc.) or larger (e.g., 21 cm×21 cm×21 cm for about 3.5 kilowatts) (e.g., 3, 3.1, 3.2, 3.3, 3.4, 3.5, 3.6, 3.7, 3.8, 3.9, 4 kilowatts). Other dimensional sizes and amounts are also contemplated and to a certain extent may depend on the application and/or the configuration of the system.

In certain embodiments, the amount of phase change material that may be used in a particular embodiment may range from 1 gm to 20 kg, 0.5 gm to 1.5 gm, 20 kg to 50 kg, 1 gm to 100 gm; 500 gm to 2 kg, 250 gm to 750 gm, 4 kg to 10 kg, 10 kg to 20 kg, 25 kg to 40 kg, 100 kg to 500 kg, 500 kg to 1 ton or other acceptable amounts.

In exemplary embodiments, multiple thermoelectric generators may be utilized to increase the amount of energy that is being produced. For example, between 1 and 10 (e.g., 1, 2, 3, 4, 5, 6, 7, 8, 9, 10, 2-4, 3-5, 4-6, etc.) generators may be used in a cell phone whereas the larger 3.5 kilowatt device may use 300-1000 (e.g., 300, 400, 500, 600, 200-400, 300-500, 400-600, etc.) generators. In certain embodiments, the number of thermoelectric generators may range from 1 to 10, 15 to 2000, 5 to 20, 15 to 40, 20 to 100, 50 to 200, 100 to 400, 200 to 1000, 600, to 1200, etc. The number of thermoelectric generators to a certain extent may depend on the application and/or the configuration of the system. In certain embodiments, the thermoelectric generator(s) may be combined with other thermal and or power sources.

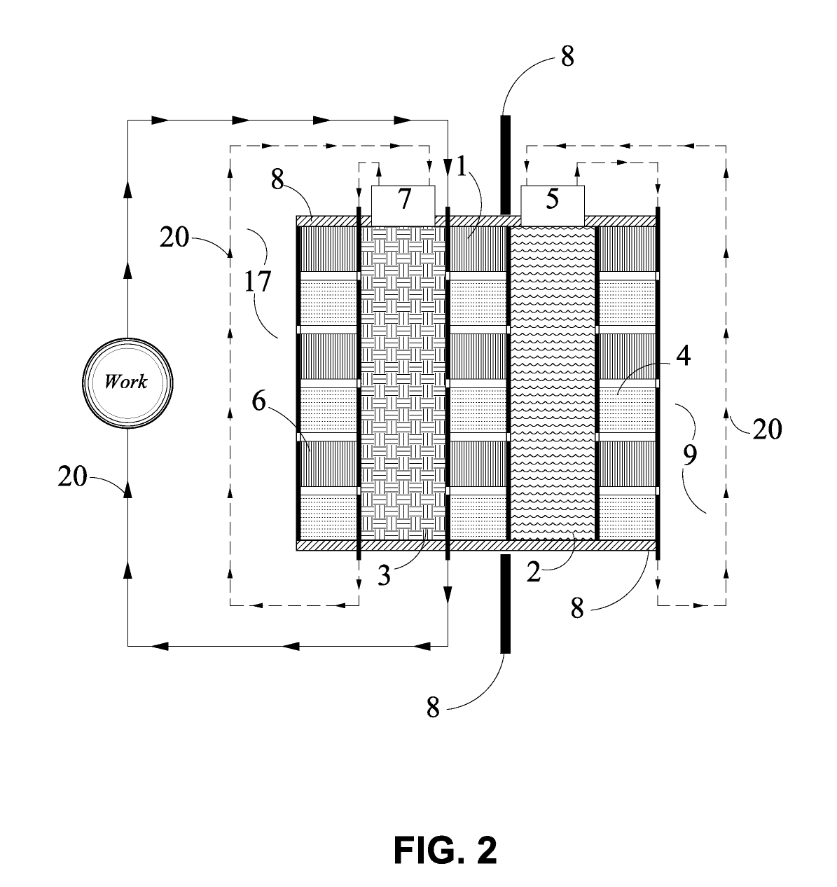

FIG. 2 is a schematic drawing of another exemplary embodiment of a thermoelectric energy generation system that takes advantage of the energy stored in ambient temperature. The embodiment in FIG. 2 is similar to the embodiment of FIG. 1 except an insulating barrier 8 is used to maintain two different ambient temperatures, a high side ambient temperature 9 and a low side ambient temperature 17. This arrangement may be beneficial when, for example, the high temperature storage 2 is kept at a relatively low temperature. In this case, the high side ambient temperature 9 may be maintained at a lower temperature than the low side ambient temperature 17. The higher side temperature and/or the lower side temperature may be in direct contact, in direct contact, or in thermal communication with the thermoelectric generator.

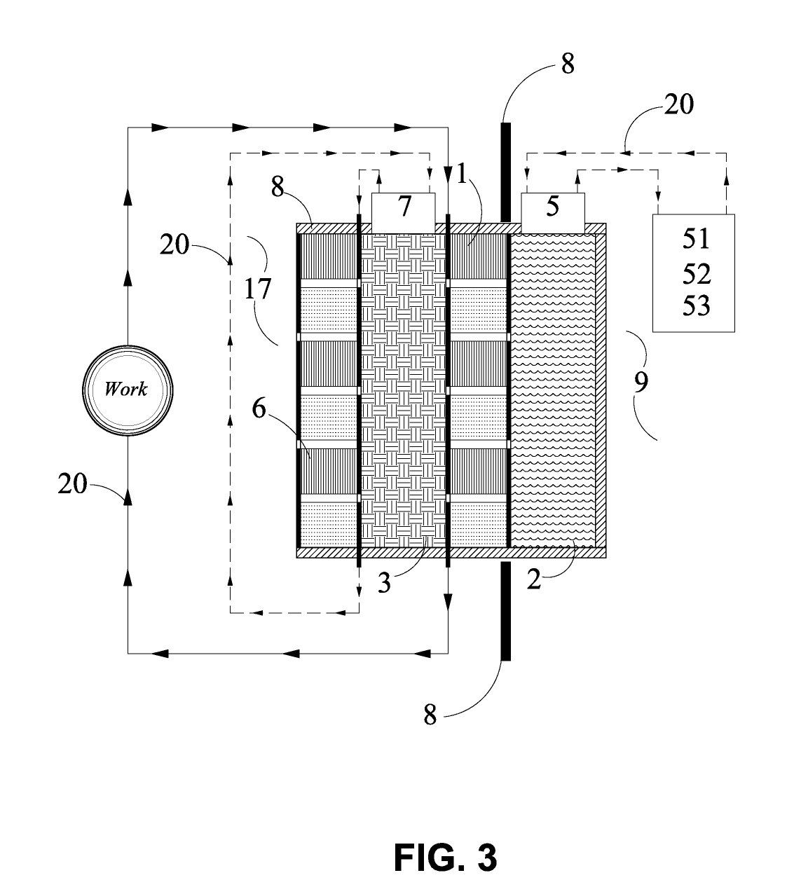

FIG. 3 is a schematic drawing of another exemplary embodiment of a thermoelectric energy generation system. The embodiment in FIG. 3 is similar to the embodiment of FIG. 2 except, instead of a high temperature regenerator, an alternative power source providing photovoltaic direct current electric energy 51, piezoelectric direct current electric energy 52, or electromagnetic electrical energy 53 is provided for the heater 5. The alternative power source may also be a conventional power source such as a battery, an engine, etc. The higher side temperature and/or the lower side temperature may be in direct contact, indirect contact, or in thermal communication with the thermoelectric generator.

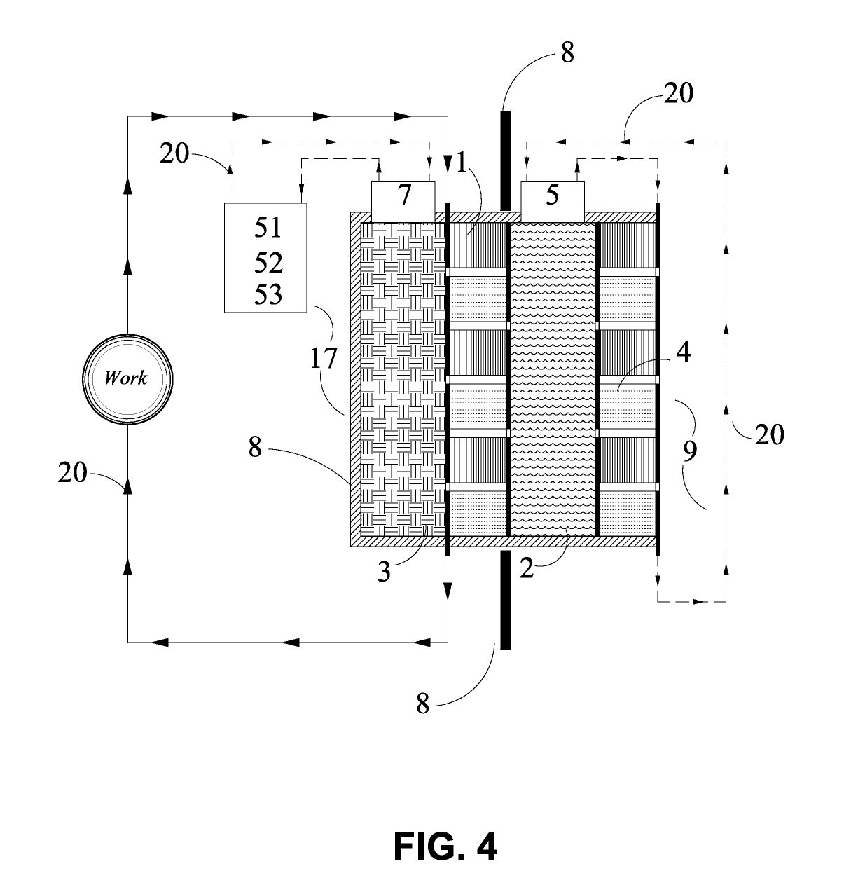

FIG. 4 is a schematic drawing of another exemplary embodiment of a thermoelectric energy generation system. The embodiment in FIG. 4 is similar to the embodiment of FIG. 2 except, instead of a low temperature regenerator, an alternative power source providing photovoltaic direct current electric energy 51, piezoelectric direct current electric energy 52, or electromagnetic electrical energy 53 is provided for the chiller 7. Again, the alternative power source also may be a conventional power source such as a battery, an engine, etc. The higher side temperature and/or the lower side temperature may be in direct contact, in direct contact, or in thermal communication with the thermoelectric generator.

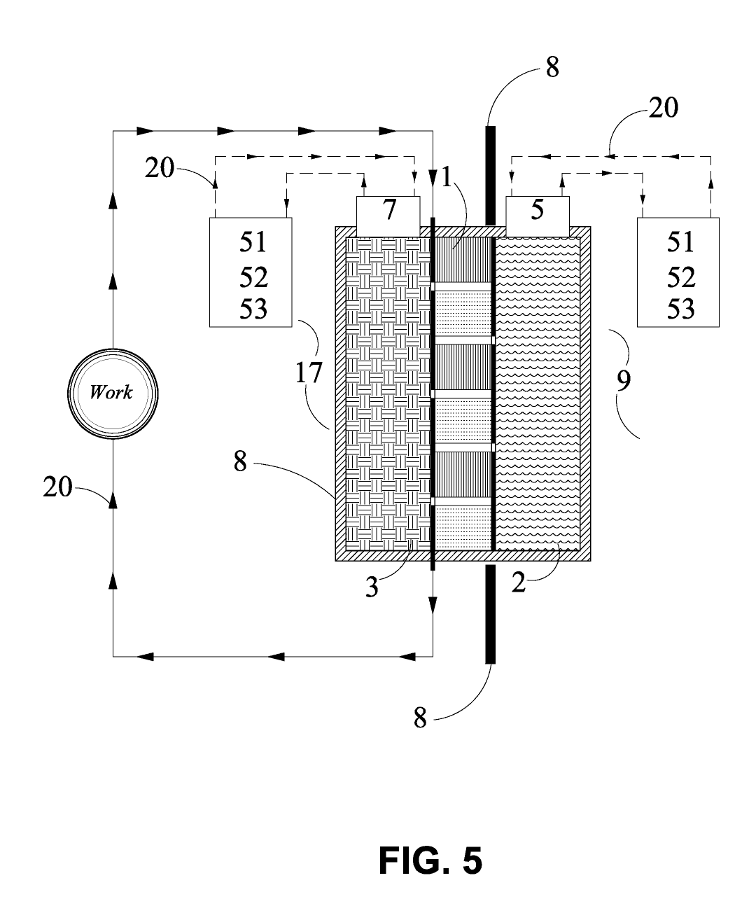

FIG. 5 is a schematic drawing of another exemplary embodiment of a thermoelectric energy generation system. The embodiment in FIG. 5 is similar to the embodiment of FIG. 2 except, instead of a high temperature regenerator and low temperature regenerator, both are replaced with an alternative power source providing photovoltaic direct current electric energy 51, piezoelectric direct current electric energy 52, or electromagnetic electrical energy 53 for the heater 5 and chiller 7. The power sources may also be a conventional power source such as a battery, an engine, solar, geothermal, electromagnetic, etc. This embodiment may be beneficial when both energy sources have an available man-made wasted thermal energy source. In this case, it may not be necessary to include regeneration capabilities in the system. This embodiment may be beneficial when one or more energy sources have an available man-made wasted thermal energy source. In this case, it may not be necessary to include regeneration capabilities in the system or it may only be necessary to include a reduced capacity for regeneration of the thermal energy needed to maintain the phase change materials at the appropriate temperature. The higher side temperature and/or the lower side temperature may be in direct contact, in direct contact, or in thermal communication with the thermoelectric generator.

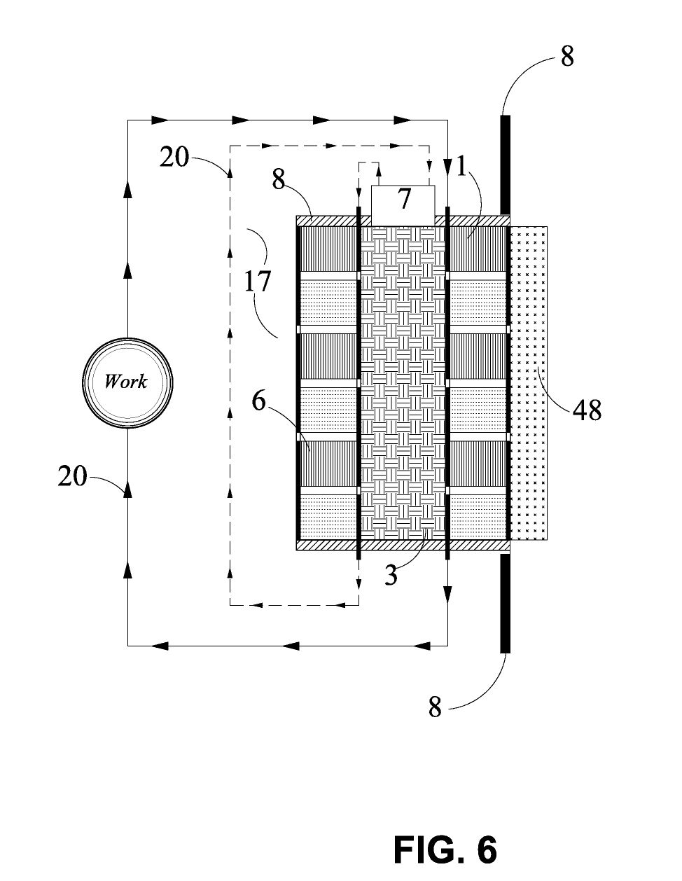

FIG. 6 is a schematic drawing of another exemplary embodiment of a thermoelectric energy generation system. In FIG. 6, the high temperature source is replaced with an alternative high temperature heat source 48. In exemplary embodiments, the high temperature heat source 48 may be, e.g., heat from nuclear fuel rods, lava from an active volcano, heat from a furnace, body temperature, etc. The higher side temperature and/or the lower side temperature may be in direct contact, in direct contact, or in thermal communication with the thermoelectric generator.

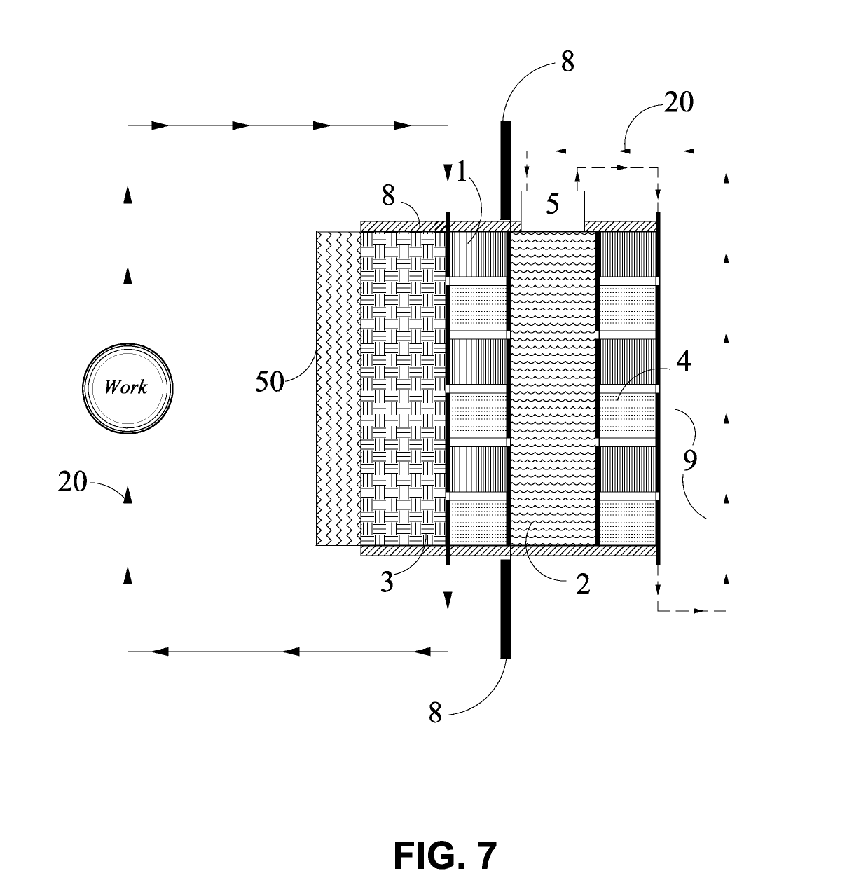

FIG. 7 is a schematic drawing of another exemplary embodiment of a thermoelectric energy generation system. In FIG. 7, the low temperature source is replaced with an alternative cold temperature source 50. In exemplary embodiments, the low temperature source may be, e.g., from a glacier, ocean, etc. The higher side temperature and/or the lower side temperature may be in direct contact, in direct contact, or in thermal communication with the thermoelectric generator.

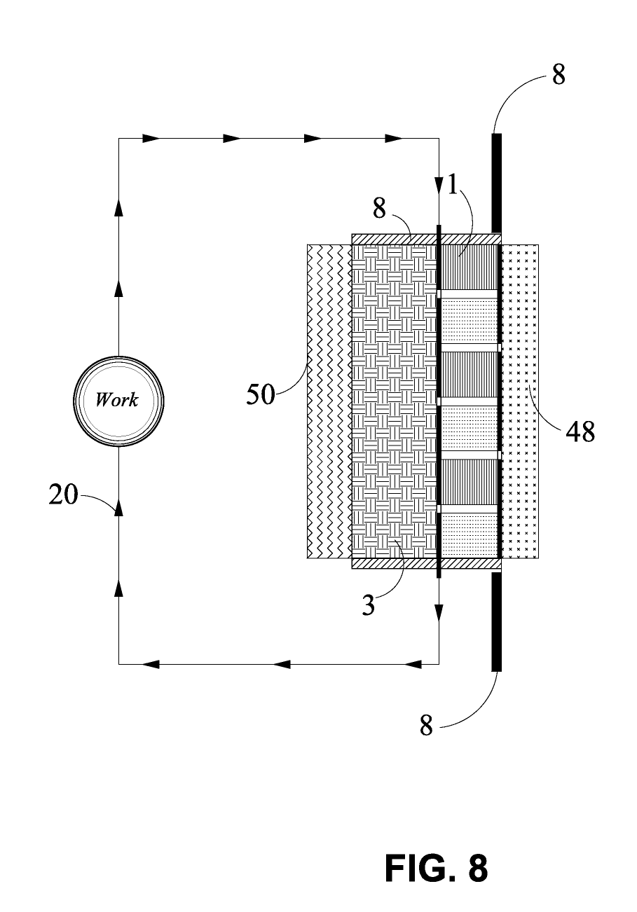

FIG. 8 is a schematic drawing of another exemplary embodiment of a thermoelectric energy generation system. FIG. 8 is similar to FIG. 7 except the high temperature storage 2 is replaced with a direct connection to an alternative high temperature heat source 48. In exemplary embodiments, the high temperature heat source 48 may be, e.g., heat from nuclear fuel rods, lava from an active volcano, heat from a furnace, body temperature, etc. The higher side temperature and/or the lower side temperature may be in direct contact, in direct contact, or in thermal communication with the thermoelectric generator.

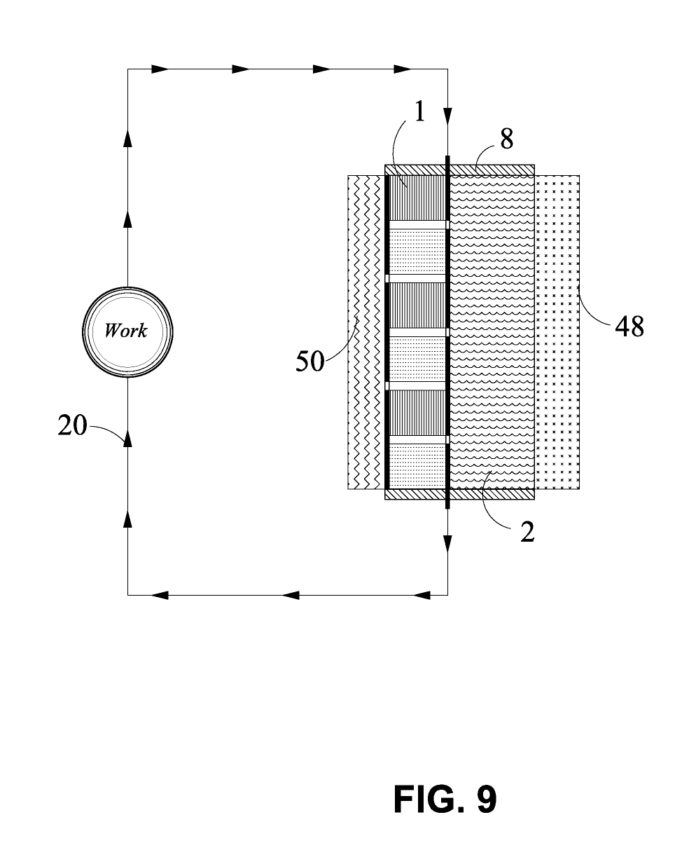

FIG. 9 is a schematic drawing of another exemplary embodiment of a thermoelectric energy generation system. FIG. 9 is similar to FIG. 6 except the low temperature storage 3 is replaced with a connection to an alternative cold source 50. As described above, various alternative sources are available. The higher side temperature and/or the lower side temperature may be in direct contact, in direct contact, or in thermal communication with the thermoelectric generator.

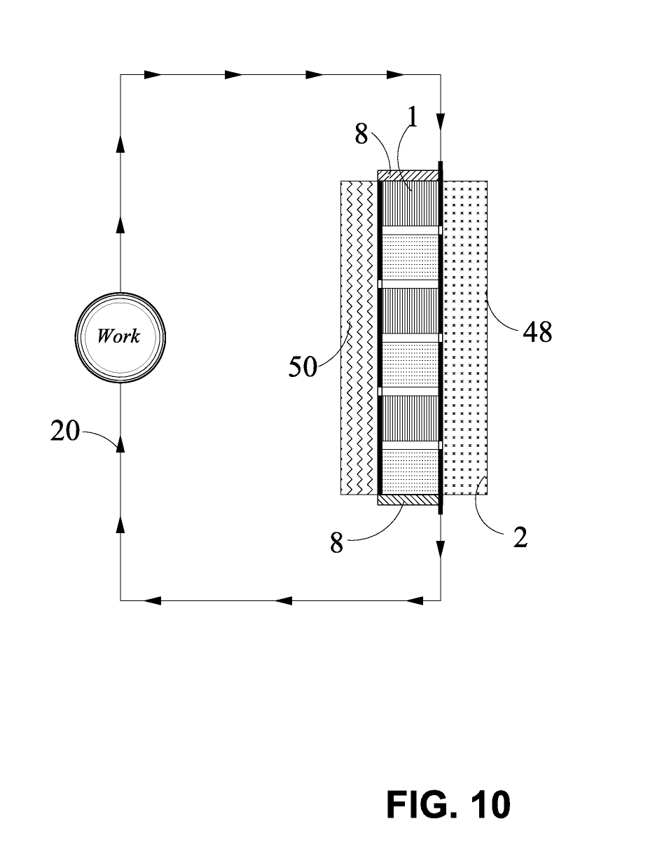

FIG. 10 is a schematic drawing of another exemplary embodiment of a thermoelectric energy generation system. In FIG. 10 the high temperature storage 2 is replaced with a connection to an alternative high temperature heat source 48 and the low temperature storage 3 is replaced with a direct connection to an alternative cold source 50. As described above, various alternative sources are available. The higher side temperature and/or the lower side temperature may be in direct contact, in direct contact, or in thermal communication with the thermoelectric generator.

FIGS. 6-9 are similar to the embodiment of FIG. 10 except a phase change material is also present in case the alternative sources are intermittent or fluctuating in temperature.

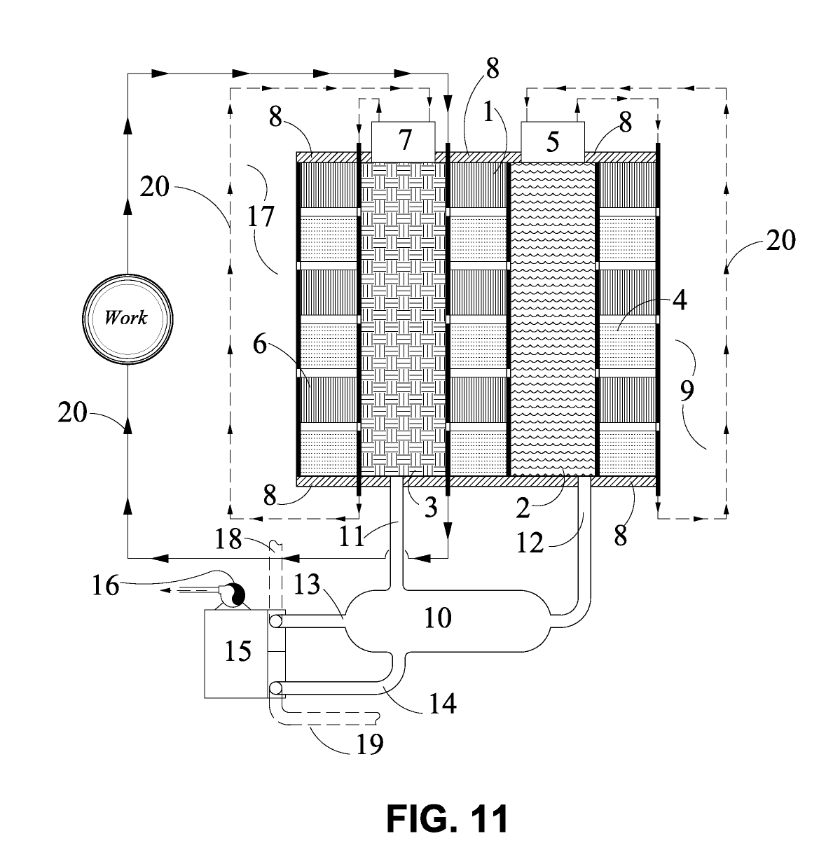

FIG. 11 is a schematic drawing of another exemplary embodiment of a thermoelectric generator, heating and cooling system. FIG. 11 is similar to the embodiment illustrated in FIG. 1 but also includes a heat exchanger 10 to provide heating and/or cooling on demand. In this exemplary embodiment, the high temperature inlet 12 and low temperature inlet 11 provided use liquid or vapor that is heated or cooled by the high temperature storage 2 or the low temperature storage 3 to the heat exchanger 10 which cools the liquid or vapor received from the low temperature inlet 11 or further warms the liquid or vapor received from the high temperature inlet 12. The liquid or vapor then exits the heat exchanger through the high temperature outlet 13, or the low temperature outlet 14, into a plenum or tank 15 where it is distributed to desired locations via pipe or duct, by traditional methods using pumps or fans 16. It releases its thermal energy into the atmosphere to be heated or cooled and then is returned to the high temperature storage 2 or the low temperature storage 3 via the high temperature return 18 or low temperature return 19, the plenum or tank 15 and the heat exchanger 10. In this embodiment the electrical energy from the thermoelectric generator 1 may be used to generate electrical power for other devices. The higher side temperature(s) and/or the lower side temperature(s) may be in direct contact, in direct contact, or in thermal communication with the thermoelectric generator.

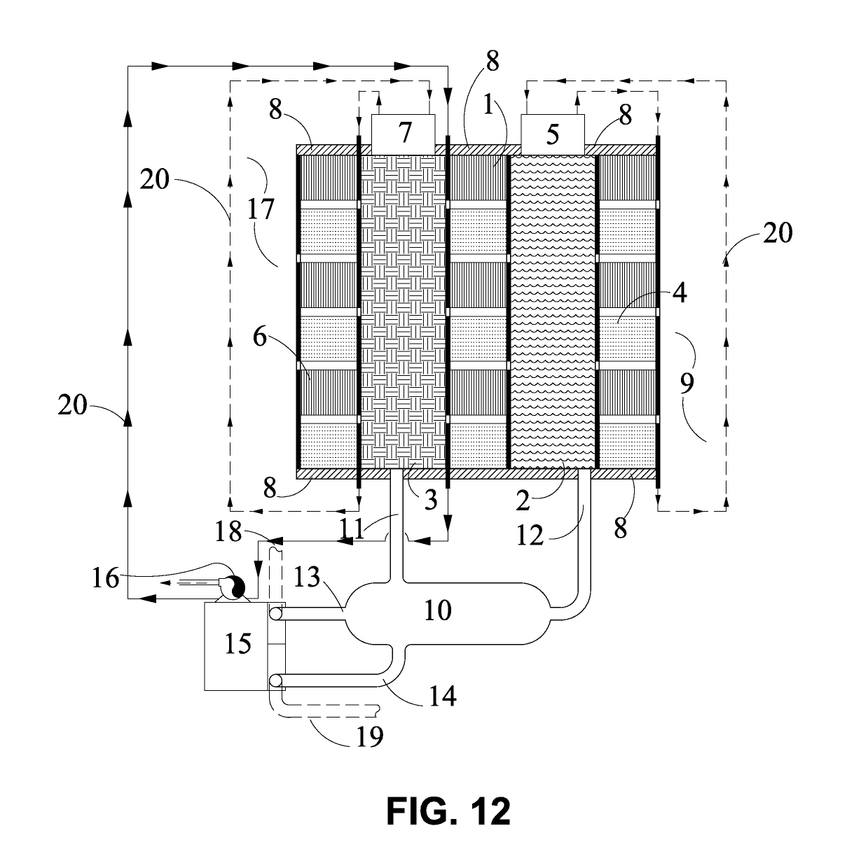

FIG. 12 is a schematic drawing of another exemplary embodiment of a thermoelectric energy generation system. FIG. 12 is similar to the embodiment illustrated in FIG. 11 but may not, if desired, power ancillary devices except for the pumps or fans 16, from the thermoelectric generator 1. The higher side temperature(s) and/or the lower side temperature(s) may be in direct contact, in direct contact, or in thermal communication with the thermoelectric generator.

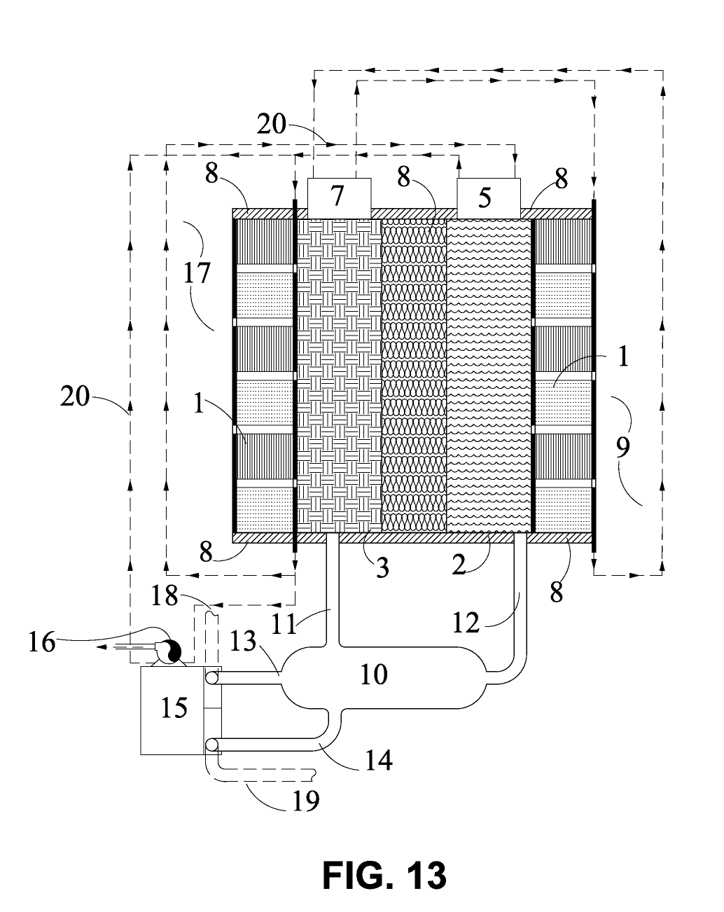

FIG. 13 is a schematic drawing of another exemplary embodiment of a thermoelectric generating, heating and cooling system. In this embodiment, there are no regenerators; there are two thermoelectric generators 1 one using high temperature storage 2 and the high side ambient temperature 9 to power the chiller 7, the other the thermoelectric generator 1 between the low side ambient temperature 17 and low temperature storage 3 to power the heater 5 and the pump or fan 16. The higher side temperature(s) and/or the lower side temperature(s) may be in direct contact, in direct contact, or in thermal communication with the thermoelectric generator.

Although many of the exemplary embodiments described above are single modifications to the exemplary embodiment of FIG. 2, it should be readily understood by a person of ordinary skill in the art that the same or similar variations could be made to, for example, FIG. 1. Additionally, the various exemplary modifications could be made in combination with each other to create additional exemplary embodiments.

FIG. 14 is an exploded view of an exemplary embodiment of a thermoelectric device that may be utilized in exemplary thermoelectric energy generation systems. In exemplary embodiments, a more efficient thermoelectric device may be used instead of a generic off the shelf device.

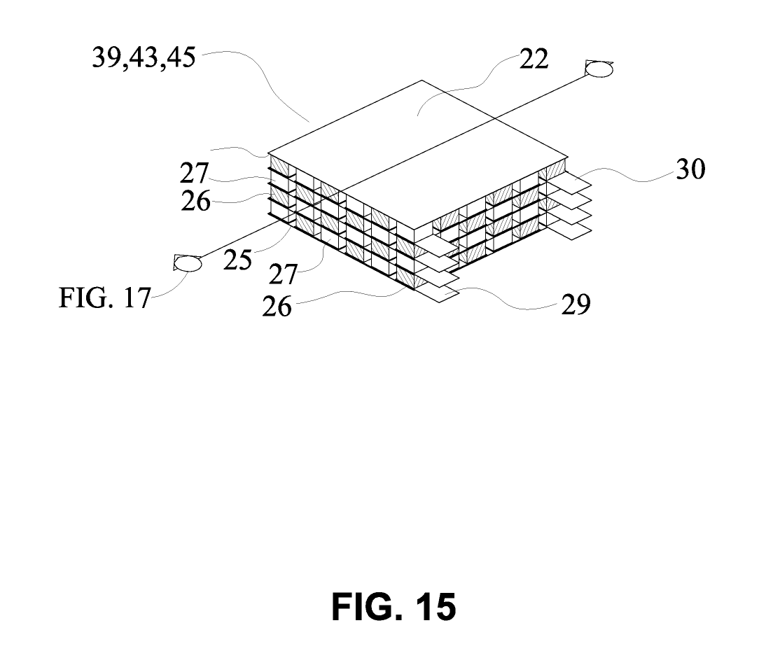

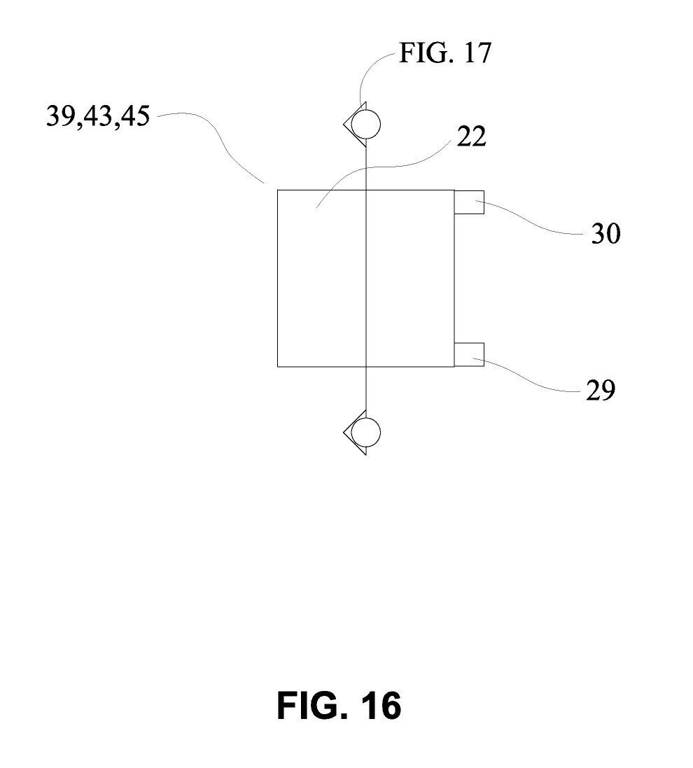

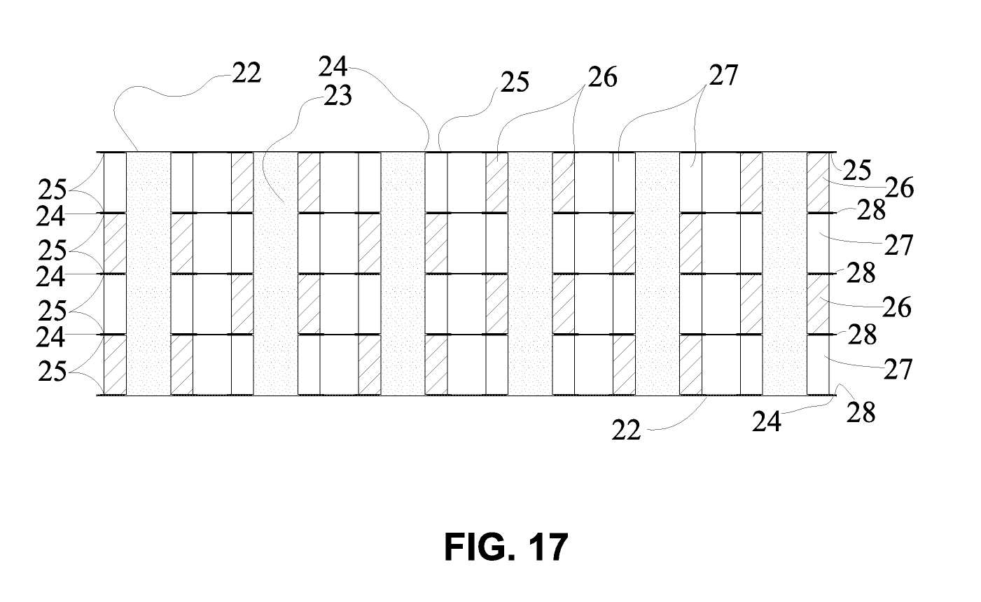

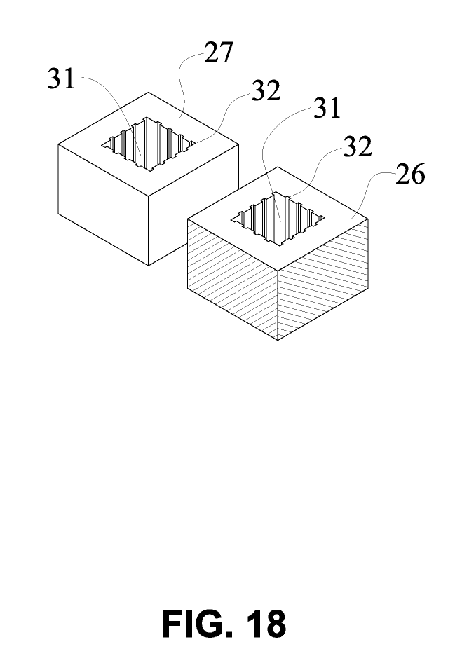

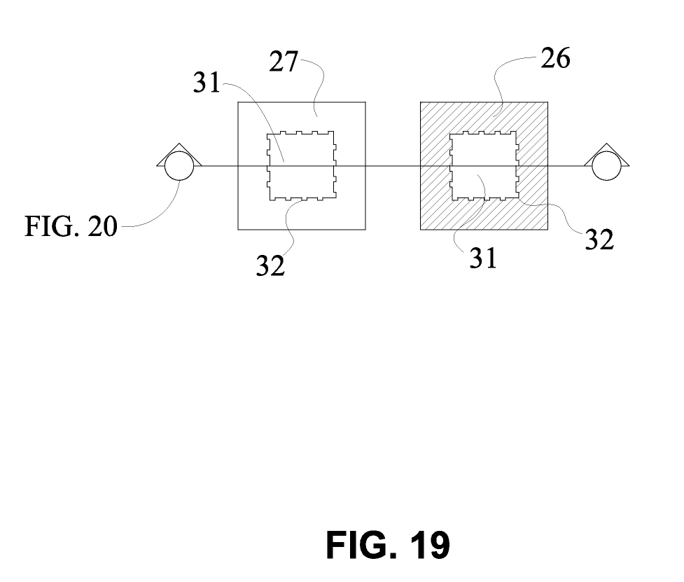

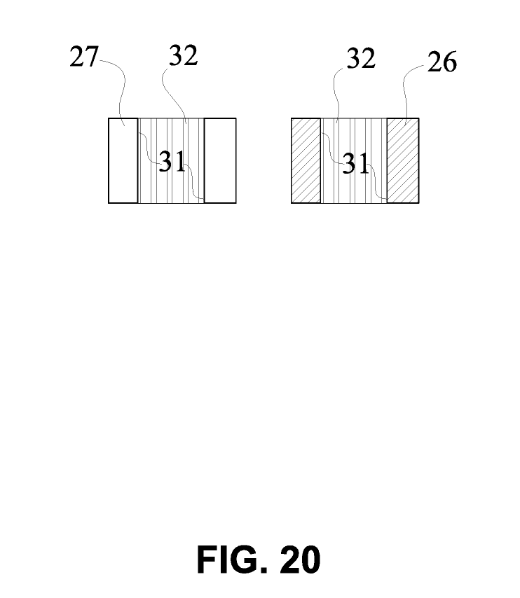

Additional details of the exemplary embodiment described in FIG. 14 can be found in FIGS. 15-20. FIG. 15 is an isometric view of an exemplary embodiment of a thermoelectric device that may be utilized in exemplary thermoelectric energy generation systems. FIG. 16 is a plan view of an exemplary embodiment of a thermoelectric device that may be utilized in exemplary thermoelectric energy generation systems. FIG. 17 is a cross sectional view of an exemplary embodiment of a thermoelectric device that may be utilized in exemplary thermoelectric energy generation systems. FIG. 18 is an isometric view of an exemplary embodiment of semiconductor posts that may be used in exemplary embodiments of thermoelectric devices. FIG. 19 is a plan view of an exemplary embodiment of semiconductor posts that may be used in exemplary embodiments of thermoelectric devices. FIG. 20 is a cross-sectional view of an exemplary embodiment of semiconductor posts that may be used in exemplary embodiments of thermoelectric devices;

The thermoelectric device 39,43,45 may comprise vacuum seal foils 22 that seal both ends of the module to create evacuated, or sustainably evacuated, chambers. The chambers may contain an amount of heat pipe working fluid 23, (e.g. water, acetone, butane, or other suitable materials). When the vacuum seal foils 22 are vacuum sealed onto the two outermost thermally conductive thermoplastic elastomer electrical insulating skins 24 that have cutouts to match chambers is attached, using thermally conductive but electrically insulating epoxy, electrical conductor layer 25 and electrical input/output (I/O) layer 28 which are slightly smaller than the voided areas 31 that have wicking grooves 32, to allow for universal orientation of module, in semiconductor posts 26, 27 that are attached, using thermally and electrically conductive epoxy, to the electrical conductor layers 25 and electrical input/output layers 28. By effectively adding an internal heat pipe thru the semiconductor posts, various benefits may be realized. For example, in exemplary embodiments, less mass in the posts leads to less thermal resistivity which adds efficiency; holes in the posts add surface area allowing more electrons to flow; and/or heat pipe latent energy may reduce the thermal resistivity of the posts, which adds efficiency. For example, if a hole is placed in each post reducing its thermal resistance by about 30% and also expanding the surface area to allow more electron flow of about 40%, doing so may increase efficiency of the thermoelectric module up to 82 percent. Certain embodiments of thermal electric devices disclosed herein may have an efficiency of between 9 to 15 percent of converting heat energy into electrical energy. However, that efficiency is based upon having to generate the heat from a fuel, not from a harvest. Other efficiency ranges are also contemplated.

In exemplary embodiments, individual semiconductor posts 26, 27 may be arranged in series electrically and in parallel thermally, beginning with the top or “hot” side layer. The series begins with a layer commencing with a positive electrical conductor I/O tab 29 on the right bottom of the layer, when viewed from the top, connecting to a semiconductor n-type post 26, alternating between semiconductor post types 26, 27 until ending with a semiconductor p-type post 27 that is connected to a negative electrical conductor I/O tab 30 on the bottom left, when viewed from the top. The I/O tab 30 may be connected to the next layer's positive electrical conductor I/O tab 29 on the bottom left of this layer, when viewed from the top, that connects to a semiconductor n-type post 26, alternating between semiconductor post types 27, 26 until ending with a semiconductor post p-type 27 that is connected to a negative electrical conductor I/O tab 30 on the bottom right of that layer. This structure may continue alternating layer by layer, until a desired number of layers is achieved. In exemplary embodiments, the bottom-most layer ends with a semiconductor p-type post 27 that is connected to a negative electrical conductor I/O tab 30 on the bottom right of the stack. The final electrical input/output (I/O) layer 28 may be attached, using e.g., thermal and electrically conductive epoxy, to a final, bottom or “cold” side, thermally conductive thermoplastic elastomer electrical insulating skin 24 that is sealed using vacuum seal foil 22. In certain embodiments, the number of layers may be between 2-5, 5-10, 10-50, 40-100, etc. depending upon the thermal difference between the high and low temperatures. The number of layers may vary significantly depending on the configuration of the particular embodiment.

In exemplary embodiments, these exemplary modules may be used in the systems in a number of different manners or combinations thereof. For example, the thermoelectric device may be used as an energy converter, in configurations such as (i) a thermoelectric generator module stack 39, where a high thermal energy is applied to the top side and a low thermal energy is applied to the bottom side, a positive polarity output electrical flow 47 is achieved, (ii) as a thermoelectric heater module stack 43, when a positive polarity input electrical flow from harvest source 44 is applied and (iii), as a thermoelectric chiller module stack 45, when a negative polarity input electrical flow from harvest source 46 is applied.

FIG. 21 is a schematic drawing of another exemplary embodiment of a thermoelectric energy generation system. The exemplary embodiment of FIG. 21 uses a thermoelectric generator 39 which may, in exemplary embodiments, be of scalable size and number to achieve the desired positive polarity output electrical flow 47. The thermoelectric generator 39 may be attached on the “hot” side, using thermally conductive but electrically insulating epoxy, to the flat and smooth surface of a high temperature output thermally conductive heat pipe casing 38 and may be attached on the “cold” side, using thermally conductive but electrically insulating epoxy, to the flat and smooth surface of a low temperature output thermally conductive heat pipe casing 40. The substantially complete adhesion of these casings, avoiding, or substantially reducing, micro voids may, in some embodiments, be beneficial to the performance of the energy conversion. Both the high temperature output thermally conductive heat pipe casing 38 and the low temperature output thermally conductive heat pipe casing 40 may extend into a stored thermal energy mass in the shape of hollow tubes each of which may have a sintered layer 37 that acts as an interior wick for the heat pipe working fluid 36. The heat pipes may be designed using well-known methods of thermodynamics and may be purchased from a number of sources in the heat transfer industry. The high temperature output thermally conductive heat pipe casing 38 tubes may extend into a latent heat thermal energy mass of high temperature phase change material 34 with a high density energy storage that stores heat within a narrow temperature range and a latent heat of >180 J/g. The low temperature output thermally conductive heat pipe casing 40 tubes may extend into a latent heat thermal energy mass of low temperature phase change material 42 with a high density energy storage that stores heat within a narrow temperature range and a latent heat of, for example, >180 J/g. In exemplary embodiments, the phase change material may have combinations of the properties identified in Table 1:

TABLE 1
Phase Change Material Properties

| PEAK MELT | PEAK MELT | | | LATENT | LATENT | SPEC. HEAT | | SPEC. HEAT | |
|---|---|---|---|---|---|---|---|---|---|
| TEMPERATURE | TEMPERATURE | DENSITY | DENSITY | HEAT | HEAT | (J/g ° C.) | | (BTU/lb ° F.) | |
| (° C.) | (° F.) | (g/cm³) | (lb/ft³) | (J/g) | (BTU/lb) | SOLID | LIQUID | SOLID | LIQUID |
| −37 | −35 | 0.88 | 54.6 | 147 | 63 | 1.39 | 1.99 | 0.042 | 0.061 |
| −23.8 | −11 | −92 | 57.4 | 215 | 93 | | | 0.000 | 0.000 |
| −15 | 5 | 1.03 | 64.5 | 265 | 114 | 1.84 | 2.06 | 0.056 | 0.063 |
| −12 | 10 | 0.87 | 54.4 | 168 | 72 | 1.86 | 2.07 | 0.057 | 0.063 |
| −5 | 23 | 0.86 | 53.7 | 180 | 78 | 1.66 | 1.93 | 0.051 | 0.059 |
| 1 | 34 | 1.00 | 62.4 | 275 | 118 | 2.32 | 2.43 | 0.071 | 0.074 |
| 4 | 39 | 0.87 | 54.3 | 195 | 84 | 1.28 | 1.65 | 0.039 | 0.050 |
| 6 | 43 | | | | | | | | |
| 8 | 46 | 0.86 | 53.8 | 180 | 78 | 1.85 | 2.15 | 0.056 | 0.066 |
| 12 | 54 | 0.86 | 53.7 | 185 | 80 | 1.76 | 2.25 | 0.054 | 0.069 |
| 15 | 59 | 0.86 | 53.8 | 165 | 71 | 2.25 | 2.56 | 0.069 | 0.078 |
| 18 | 64 | 0.86 | 53.4 | 189 | 81 | 1.47 | 1.74 | 0.045 | 0.053 |
| 20 | 68 | 0.86 | 53.8 | 190 | 82 | 2.59 | 2.89 | 0.079 | 0.088 |
| 23 | 73 | 0.83 | 51.9 | 203 | 87 | 1.84 | 1.99 | 0.056 | 0.061 |
| 24 | 75 | 0.86 | 53.7 | 189 | 81 | 2.85 | 3.04 | 0.087 | 0.093 |
| 27 | 81 | 0.86 | 53.9 | 200 | 86 | 2.46 | 2.63 | 0.075 | 0.080 |
| 28 | 82 | 0.86 | 53.7 | 205 | 88 | 2.34 | 2.54 | 0.071 | 0.077 |
| 29 | 84 | 0.85 | 53.2 | 189 | 81 | 1.77 | 1.94 | 0.054 | 0.059 |
| 30 | 86 | 0.89 | 55.7 | 163 | 70 | 1.58 | 1.62 | 0.048 | 0.049 |
| 33 | 91 | 0.85 | 52.9 | 185 | 80 | 2.34 | 2.53 | 0.071 | 0.077 |
| 37 | 99 | 0.84 | 52.4 | 222 | 96 | 1.0 | 1.09 | 0.031 | 0.033 |
| 40 | 104 | 0.85 | 53.1 | 198 | 85 | 1.98 | 2.13 | 0.060 | 0.065 |
| 43 | 109 | 0.88 | 55.1 | 180 | 78 | 1.87 | 1.94 | 0.057 | 0.059 |
| 48 | 118 | 0.82 | 51.1 | 245 | 106 | 2.10 | 2.27 | 0.064 | 0.069 |
| 50 | 122 | 0.86 | 53.8 | 200 | 86 | 1.82 | 1.94 | 0.056 | 0.059 |
| 56 | 133 | 0.81 | 50.7 | 237 | 102 | 1.47 | 2.71 | 0.075 | 0.083 |
| 61 | 142 | 0.84 | 52.4 | 199 | 86 | 1.99 | 2.16 | 0.061 | 0.066 |
| 68 | 154 | 0.87 | 54.3 | 198 | 85 | 1.85 | 1.91 | 0.056 | 0.058 |
| 103 | 217 | 1.22 | 76.2 | 157 | 68 | 2.09 | 2.28 | 0.064 | 0.069 |
| 133 | 271 | 1.21 | 75.5 | 230 | 99 | 1.57 | 1.95 | 0.048 | 0.059 |
| 142 | 288 | 1.27 | 79.4 | 180 | 78 | 1.61 | 1.76 | 0.049 | 0.054 |
| 151 | 304 | 1.36 | 84.9 | 182 | 78 | 2.06 | 2.17 | 0.063 | 0.066 |

In exemplary embodiments, the stored energy can be calculated using the following equation;

$$\frac{kW}{h} = \frac{( {cm}^{3} * \frac{g}{{cm}^{3}} ) * \frac{J}{g}}{3 , 600 , 000}$$

where stored latent heat energy (kW/h) equals the volume of phase change material (cm³) multiplied by the phase change material density (g/cm³); the sum of which is then multiplied by the phase change material latent heat storage capability (J/g) and then the total (J) is converted into kW/h by dividing by 3,600,000.

Both the high temperature phase change material 34 and/or the low temperature phase change material 42 may have additional heat pipes embedded to ensure their temperature is maintained or substantially maintained.

A high temperature input thermally conductive heat pipe casing 35 with the tube portion embedded into the high temperature phase change material 34 may include a sintered layer 37 designed to wick the heat pipe working fluid 36 and may also include a flat and smooth surface of the same high temperature output thermally conductive heat pipe casing 34. In exemplary embodiments, the heat pipe may extend beyond the insulating casket 33. Similarly, a low temperature input thermally conductive heat pipe casing 41 with the tube portion embedded into the low temperature phase change material 42 may include a sintered layer 37 designed to wick the heat pipe working fluid 36 and a flat and smooth surface of the same low temperature output thermally conductive heat pipe casing 41. In exemplary embodiments, the heat pipe may extend beyond the insulating casket 33 which may aid in conducting the thermal energy from a remote source into the device.

When determining the temperature for both the high temperature phase change material 34 and the low temperature phase change material 42, the local temperature, hot or cold, that naturally occurs and/or occurs as a secondary waste from a primary action, may be exploited. For example, if installing the system in a factory in the desert with a high average daytime temperature and/or where there are other sources of heat that occur as byproducts of work done at the factory during the day, that heat may be used to maintain and/or increase the high temperature of the high temperature phase change material 34 thereby making it easier to achieve and maintain a large thermal distance. In certain applications, multiple first and second temperatures may be available to be exploited which may permit systems that use multiple temperature differentials using multiple suitable phase change materials.

For example, FIG. 21 is a schematic drawing of another exemplary embodiment of a thermoelectric energy generation system. As shown in FIG. 21, thermoelectric heater module stacks 43 may attach to the high temperature input thermally conductive heat pipe casing 35 using thermally conductive but electrically insulating epoxy, to its flat and smooth outside surface. The heat may be generated by adding positive polarity input electrical flow from harvest sources 44. Also, thermoelectric chiller module stacks 45 are attached to the low temperature input thermally conductive heat pipe casing 41 using thermally conductive but electrically insulating epoxy, to its flat and smooth outside surface. The cooling may be generated by adding negative polarity input electrical flow from harvest source 46.

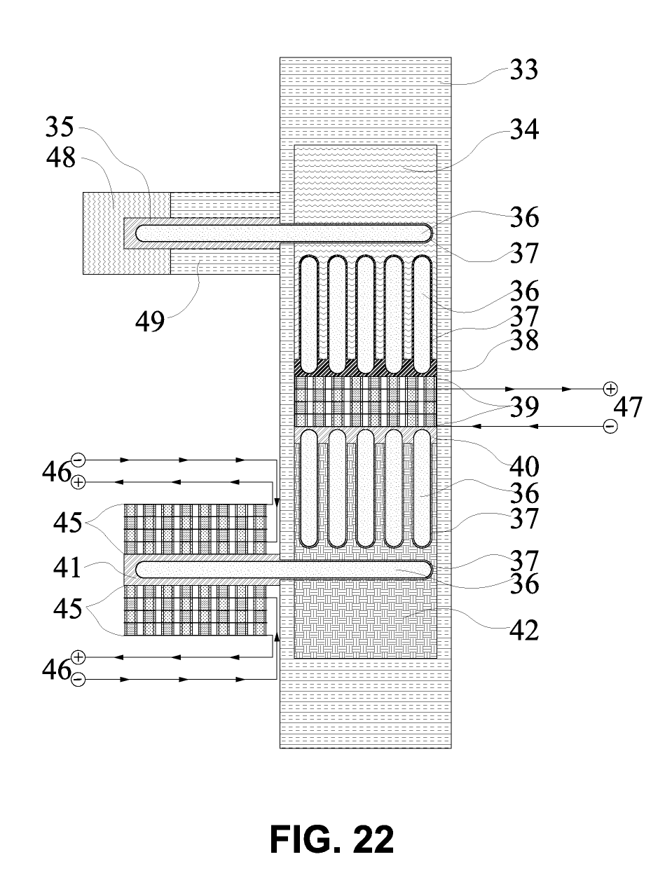

FIG. 22 is a schematic drawing of another exemplary embodiment of a thermoelectric energy generation system. Referring to FIG. 22, if there is a heat source 48 that can be harvested, the thermoelectric heater module stacks 43 referenced in FIG. 21 may be eliminated or reduced and the high temperature input thermally conductive heat pipe casing 35 can be attached to, and/or in thermal communication with, the waste source of high temperature thermal energy. The area of the high temperature input thermally conductive heat pipe casing 35 that is not connected to the heat source 48 may be sealed in a thermally non-conductive material 49.

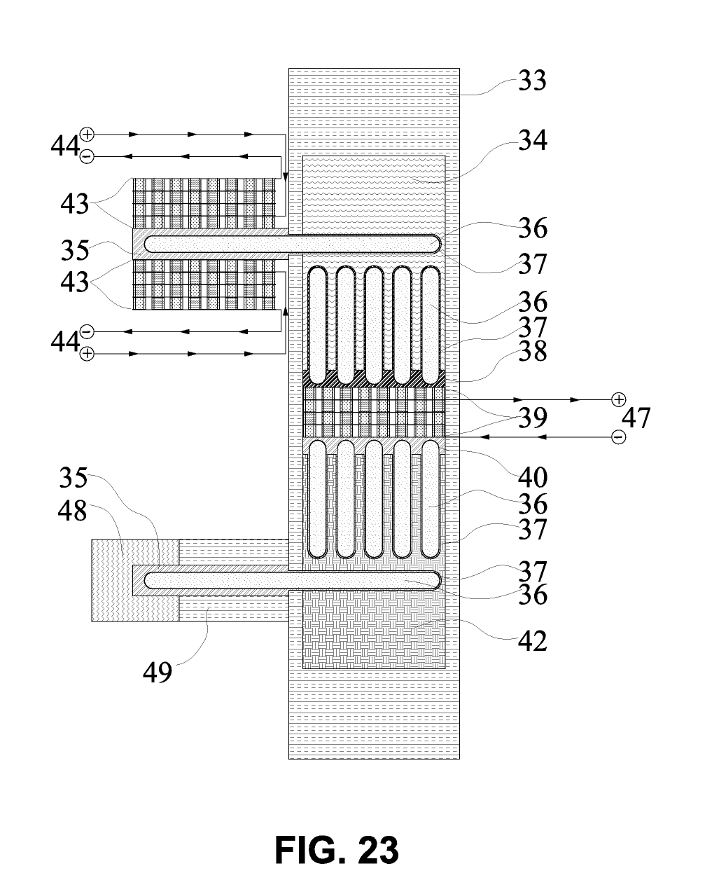

FIG. 23 is a schematic drawing of another exemplary embodiment of a thermoelectric energy generation system. Referring to FIG. 23, if there is a cold temperature source 50 that can be harvested, the thermoelectric chiller module stacks 45 referenced in FIG. 21 can be eliminated, or reduced, and the low temperature input thermally conductive heat pipe casing 41 can be attached to, and/or in thermal communication with, the waste source of low temperature thermal energy. The area of the low temperature input thermally conductive heat pipe casing 41 that is not connected to the cold temperature source 50 may be sealed in a thermally non-conductive material 49.

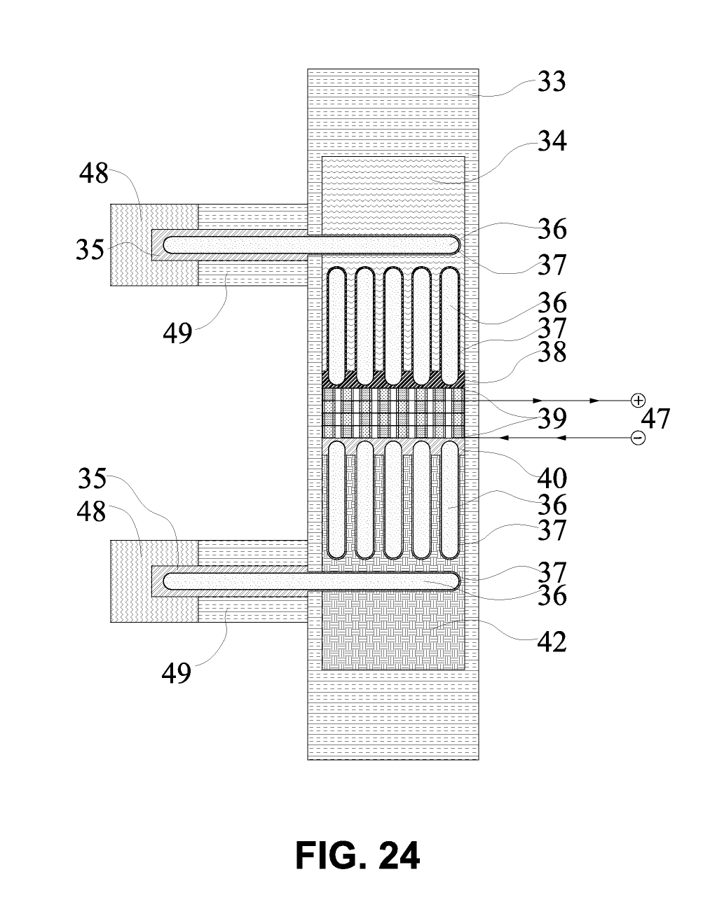

FIG. 24 is a schematic drawing of another exemplary embodiment of a thermoelectric energy generation system. Referring to FIG. 24, if there is a heat source 48 as well as a cold source 50 that can be harvested, the thermoelectric heater module stacks 43 as well as the thermoelectric chiller module stacks 45 can be eliminated or reduced and the high temperature input thermally conductive heat pipe casing 35 as well as the low temperature input thermally conductive heat pipe casing 41 can be attached to, and/or in thermal communication with, the waste source of high temperature thermal energy and the waste source of low temperature thermal energy respectively. The area of the high temperature input thermally conductive heat pipe casing 35 and the area of the low temperature input thermally conductive heat pipe casing 41 that is not connected to the cold temperature source 50 may be sealed in a thermally non-conductive material 49.

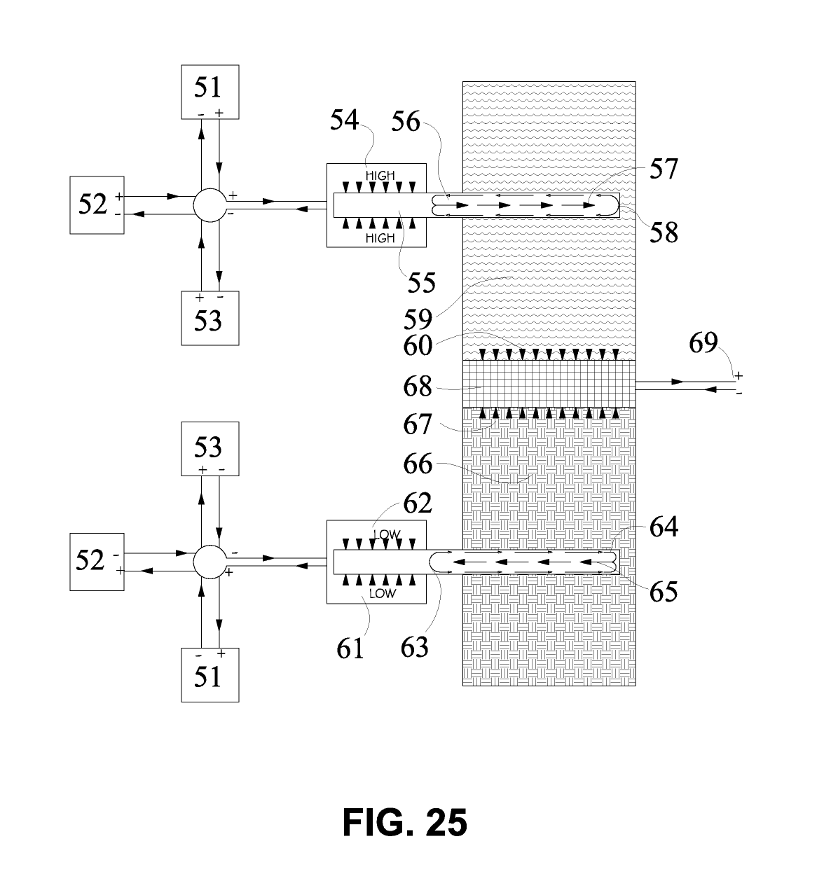

FIG. 25 is a schematic drawing of another exemplary embodiment of a thermoelectric energy generation system. Referring to FIG. 25, the need to harvest and convert additional energy to maintain the mass and thermal difference in order to achieve a constant stable electrical supply may exist to some degree in various applications. Energy harvesting using known methods such as harvested photovoltaic direct current electric energy 51, harvested piezoelectric direct current electric energy 52, and harvested electromagnetic energy 53, along with other types can power the thermoelectric heater 33. In this manner, the heater 54 may heat to boiling the working fluid into working fluid vapor 55 in the high temperature heat pipe 56 that transfers its heat as it travels a flow path 57 towards a lower temperature into the high temperature thermal storage 59 and in so doing cools and is wicked as the condensed working fluid return 58. In exemplary embodiments, this may be used to power the thermoelectric chiller 61 to cool to a liquid low temperature working fluid into chilled working fluid 62 in the low temperature heat pipe 63 that travels towards the low temperature thermal storage 66 along the outer heat pipe walls 64 and in doing so is heated, changing from a liquid to a vapor, and is wicked back towards the thermoelectric chiller 61, as shown as the heated working fluid 65. In exemplary embodiments, this process maintains a substantially high temperature transfer 60 and a low temperature transfer 67 in contact with opposing sides of the thermoelectric generator modules 68 generating a configurable, scalable, constant, and/or reliable renewable source of direct current electrical output.

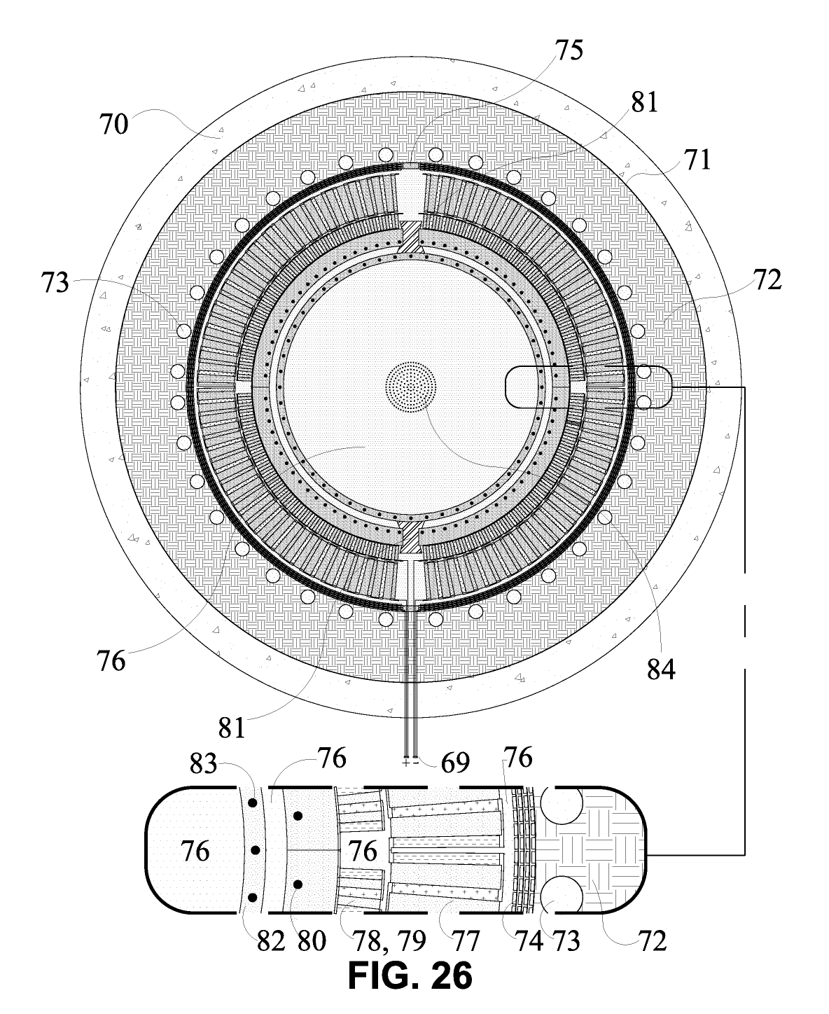

FIG. 26 is a schematic drawing of another exemplary embodiment of a thermoelectric energy generation system utilizing spent nuclear fuel rods as the harvested heat source. In FIG. 26 a nuclear spent fuel rod harvested energy converter absorbs thermal energy at multiple conversion energy conversion layers to generate electrical energy. In embodiments, this eliminates or substantially reduces the costly active water and air cooling methods currently in use as well as providing a quadruple redundancy safety casket. FIG. 26 shows multiple layers beginning with the outermost reinforced concrete 70 (e.g., 14,500 psi) outer wall with stainless steel interior liner 71. Exemplary embodiments may also comprise a lead loaded vinyl exterior liner coating on the outermost reinforced concrete outer wall 70 with a secondary reinforced 8,000 psi concrete outer wall having an outer protection layer of bituthene low temperature self-adhering, rubberized asphalt/polyethylene waterproofing membrane system of the standard type for subterranean structures. The outermost reinforced concrete outer wall 70 with stainless steel interior liner 71 encapsulates a large volume of low temperature phase change material 72 around the entire or substantial portion of the assembly including the top and bottom of the structure. The phase change material may be integrated with heat pipes (e.g., Cu heat pipes) with low temperature working fluid (e.g., Ammonia, Acetone) 73, that extend above and below the transfer band through the low temperature phase change material 72, passing through the outermost reinforced concrete 70 outer wall and stainless steel interior liner 71 and into the surrounding fill material (e.g., earth, sand, ash and/or clay) in order to maintain the coldest possible (or at least a cold) temperature at the thermoelectric cold transfer location for the first thermoelectric layer. The thermoelectric layer may be comprised of multiple layers of low temperature thermoelectric generator module stacks 74 e.g., of the type described in FIG. 14, that are connected with a SiC ceramic outer seal plug 75, creating the outer encapsulated chamber. In exemplary embodiments, He gas 76 may be added and that may make up the “hot” side of the first thermoelectric layer and the “cool” side of the second thermoelectric layer comprised of a liquid to vapor thermoelectric ring 77 of SiC separated alternating chambers of HgCdTe:B and HgCdTe:P. In exemplary embodiments, this may be separated by a narrow vacant area within the outer evacuated chamber (which may include He gas 76), that makes up the “hot” side of the second thermoelectric layer and the “cool” side of the third and final thermoelectric layer comprised of a high temperature thermoelectric ring 78 of separated alternating posts of SiC:Se and SiC:Sb 79, that is thermally bonded to the secondary SiC absorption wall with integrated sintered heat pipes using liquid CO2 for high temperature working fluid 80, that may extend above and below the transfer band by passing through a sealed lid and floor of SiC ceramic plates, then, through a separated upper and lower area of low temperature phase change material 72, where they combine with each other in non-adjacent groups of four, penetrate the upper casing into a top cavity constructed in the same manner as the outermost reinforced concrete 70 outer wall with a stainless steel interior liner 71 and/or a lead loaded vinyl exterior liner coated with a secondary reinforced 8,000 psi concrete wall having an outer protection layer of bituthene low temperature self-adhering, rubberized asphalt/polyethylene waterproofing membrane system of the standard type for subterranean structures, to enable different working fluids to be used as the fuel rods at the center cool, in order to extend the maximum electrical generation. The chamber may be designed with dual protection hatches to remove, add or replace fuel rods using standard methods. In embodiments, this may encapsulate the middle evacuated chamber, connected with vertical titanium seal plugs 81, encapsulating the primary SiC absorption wall 82 with integrated heat pipes that use liquid carbon dioxide working fluid 83, that may extend above and below the transfer band by passing through a sealed lid and floor of SiC ceramic plates, then, through a separated upper and lower area of low temperature phase change material 72, where they combine with each other in non-adjacent groups of four, penetrate the upper casing into a top cavity constructed in the same manner as the outermost reinforced concrete 70 wall with a stainless steel interior liner 71 and/or a lead loaded vinyl exterior liner coated with a secondary reinforced 8,000 psi concrete wall having an outer protection layer of bituthene low temperature self-adhering, rubberized asphalt/polyethylene waterproofing membrane system of the standard type for subterranean structures, to enable different working fluids to be used as the fuel rods at the center cool, in order to extend the maximum electrical generation, forming a large area inner evacuated chamber with He gas 76 added, to evenly disperse heat radiation of the spent nuclear fuel rods 84 housed within. In exemplary embodiments, additional electrical energy may be harvested in the following manner. The primary SiC absorption wall 82 may include Alpha Voltaic Conversion Layer SiC tiles with deep wells coated with Indium Gallium Phosphide (InGaP) designed to take advantage of the presence of alpha radiation and/or Beta Voltaic Conversion Layer SiC tiles with deep wells coated with Tritium (T) designed to take advantage of the presence of beta radiation and/or Thermophotovoltaic Conversion Layer of SiC thermal emitters and Gallium Antimonide (GaSb) photovoltaic diode cells to take advantage of radioactive decay thermal energy.

FIG. 27 is a schematic drawing of another exemplary embodiment of a thermoelectric energy generation. As seen in FIG. 27, the device includes high temperature heat plates 85 with integrated heat pipes and low temperature heat plates 86 with integrated heat pipes, alternating on opposing sides of thermoelectric generator modules 68, bonded together with thermally conductive adhesive, making up the thermoelectric generator core 87. The ends of the high temperature heat plates 85 that do not have thermoelectric generator modules 68 attached to them are embedded in the high temperature phase change material 34 in order to maintain a high temperature to the desired “hot” side of each thermoelectric generator module 68. The ends of the low temperature heat plates 86 that do not have thermoelectric generator modules 68 attached to them are embedded in the low temperature phase change material 42 in order to maintain a low temperature to the desired “cold” side of each thermoelectric generator module 68. The device also includes a Ni-chrome coil heater 88 that is embedded in the high temperature phase change material 34 that may be powered by additional thermoelectric generator modules 68, with their “cold side” connected to the low temperature phase change material 42 and their “hot side connected to a conductive connection mount 91 that may be attached to any conductive surface, harvesting high side ambient temperature 9 to convert a thermal difference into electrical energy. Both the high temperature phase change material 34 and the low temperature phase change material 42, are encapsulated in a thermally insulated outer casing 92. Additionally, the device includes thermoelectric chiller modules 90 that are embedded in the low temperature phase change material 42 that may be powered by additional thermoelectric generator modules 68, with their “hot” side connected to the high temperature phase change material 34 and their “cold” side connected to a conductive connection mount 91 that may be attached to any conductive surface, harvesting low side ambient temperature 17, to convert a thermal difference into electrical energy. The conductive connection mounts 91 use the thermally conductive outer shell strap 89 to maintain positive thermal connections to the additional thermoelectric generator modules 68. An alternative to this embodiment would utilize the conductive connection mount 91 to connect the device to outside wasted or ambient thermal source(s). The electrical energy generated by the thermoelectric generator core 87 may be drawn in configurable outputs of desired voltages and amps using the integrated voltage/current pin-out board 93.

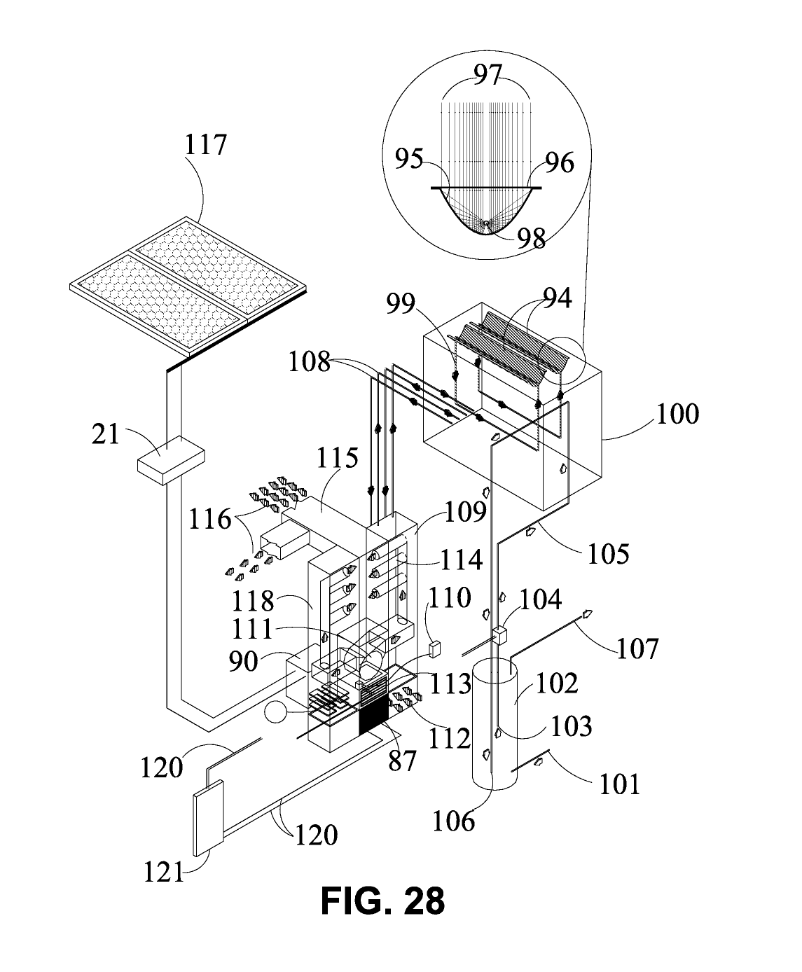

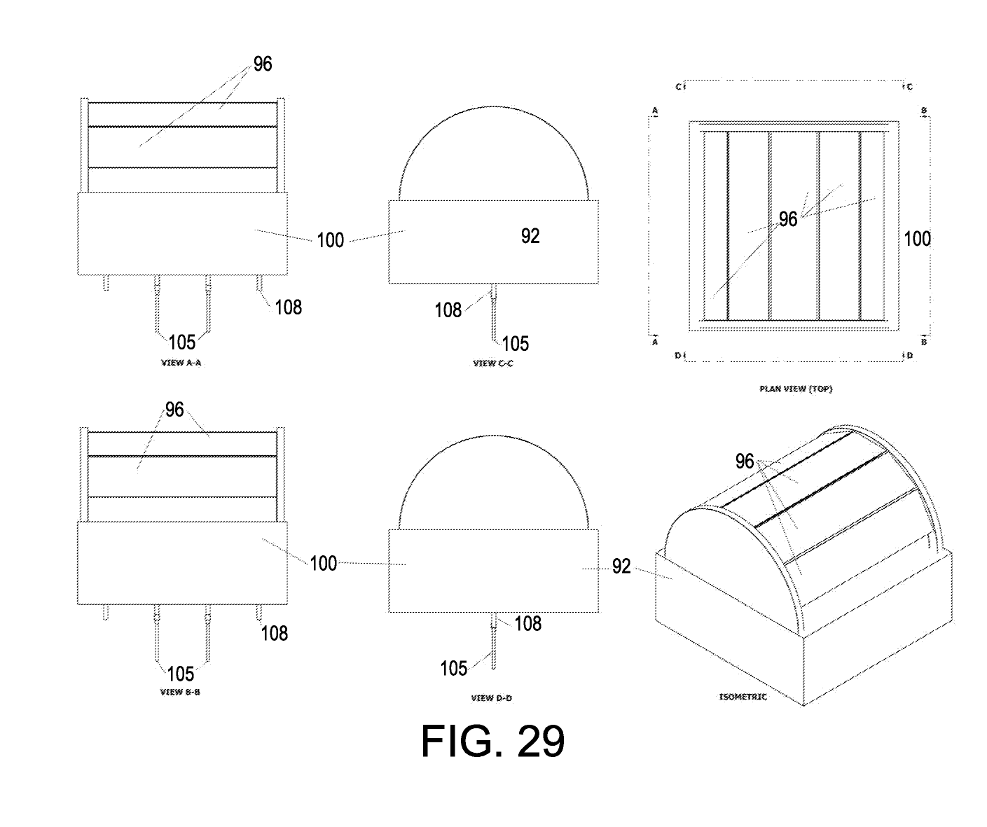

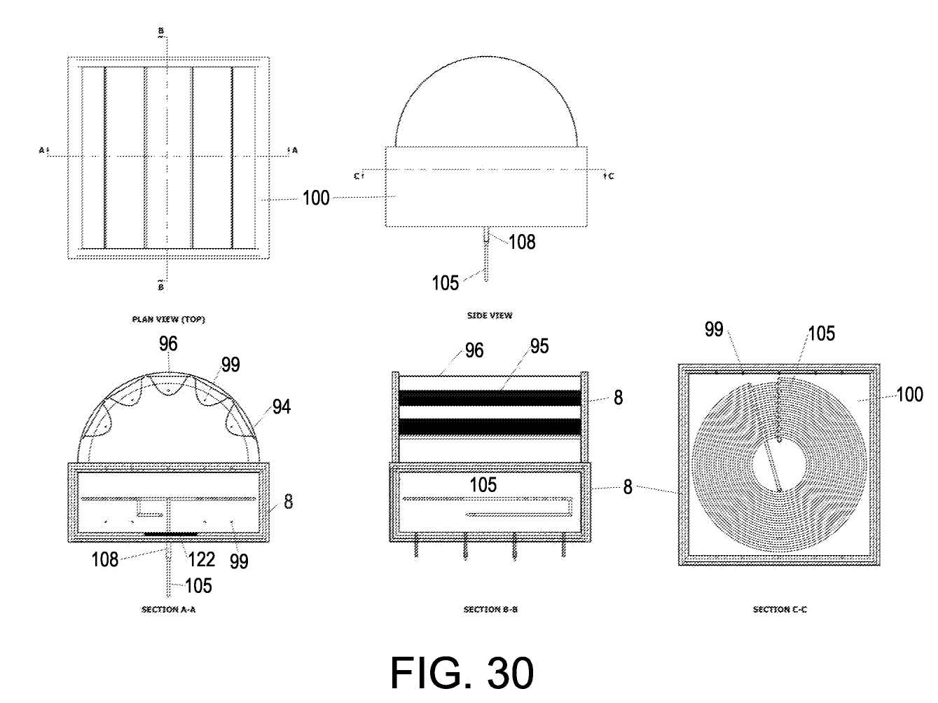

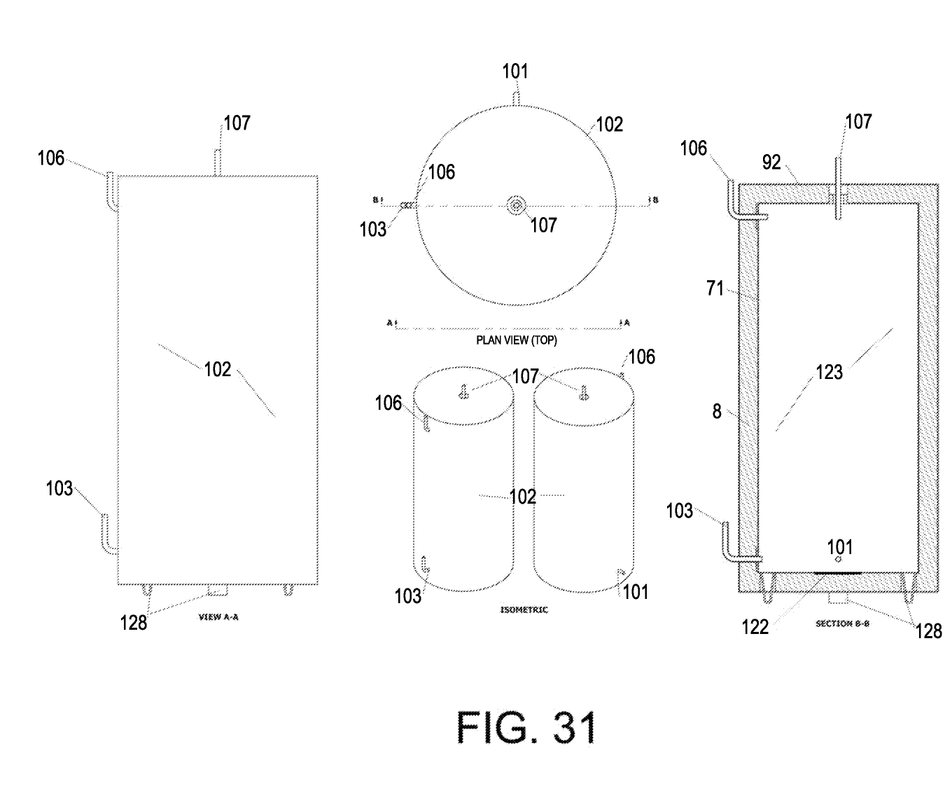

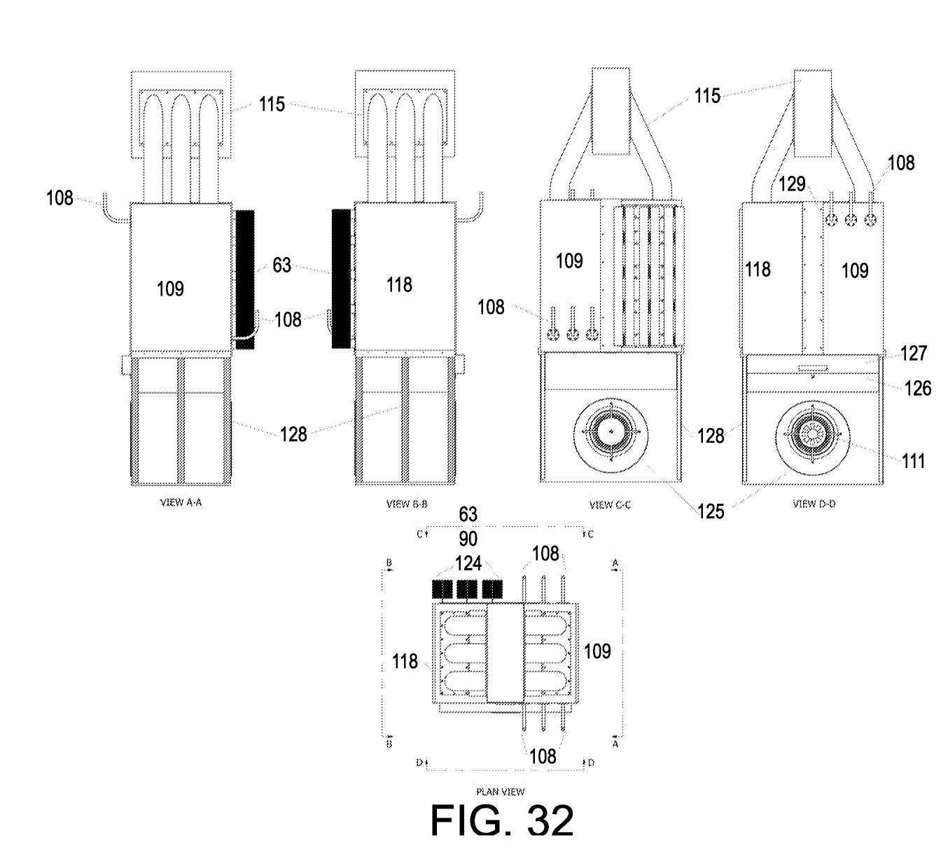

FIG. 28 is a schematic diagram of a solar thermal and photovoltaic energy harvesting system to provide buildings or other structures with thermoelectric electricity, hot water, comfort heating, comfort cooling or combinations thereof. Referring to FIG. 28, one or more parabolic trough(s) 94, further described in FIGS. 29 and 30, with a reflective surface 95, that faces the sun that may be enclosed by glass panels 96 that may be coated with one-way mirror on its outward surface, so as to allow the sunlight and heat in, while not allowing it out (or at least reducing the loss), collects the sun's rays 97 and focusing the sun's heat onto a pipe 98 filled with an oil that flows through the pipe in a convection loop 99 to heat a reservoir of organic phase change material 100 that becomes a liquid at 133° C. The heated reservoir of organic phase change material 100 is insulated with high R-value insulation so as to maintain, or substantially maintain, heat during times when there is little or no sunlight. To provide water heating, a cold waterline 101 supplies and keeps a water storage tank 102, that is further described in FIG. 31, filled so that a heat loop inlet 103 draws water from the water storage tank 102, by using a water pump 104 when electrically powered. The water is pumped through a waterline loop 105 that passes through the heated reservoir of organic phase change material 100 in a single or multiple loop which heats the water as it flows through the heated reservoir of organic phase change material 100 and then back down into the water storage tank 102 where it exits a heat loop outlet 106. The water storage tank 102 is insulated with high R-value insulation so as to maintain, or substantially maintain, the heated water that is distributed throughout the building through a hot water supply line(s) 107. To provide comfort heating, insulated transfer pipes 108 flow the liquid phase change material that is stored in the reservoir of organic phase change material 100 and the liquid phase change material stored in the secondary reservoir of organic phase change material 109 by convection in loops. A temperature shut-off valve may be placed in the loop to stop the flow at times when there is little or no sunlight. The secondary reservoir of organic phase change material 109 is insulated with high R-value insulation so as to maintain, or substantially maintain, the heated liquid organic phase change material. When heated air is desired, a thermostat or control switch 110 starts a blower 111 that is electrically powered and draws air 112 from the conditioned space through a filtered return air grill 113 and blows the air through heat ducts 114 that are made of thermally-conductive material and run through the secondary reservoir of organic phase change material 109 heating the air as it passes, after which it blows through an insulated plenum 115 and into insulated distribution ducts, blowing into the desired conditioned area 116. To provide comfort cooling, a photovoltaic panel(s) 117 or other renewable energy source such as wind or thermoelectric generates electrical energy which is stored in capacitor arrays 21 to provide a stable output to thermoelectric chiller modules 90 attached to low temperature heat plates 86 that chill organic phase change material that becomes a solid at −15° C. in a tertiary reservoir of organic phase change material 118. When cooled air is desired, a thermostat or control switch 110 starts a blower 111 that is electrically powered and which draws air 112 from the conditioned space through a filtered return air grill 113 and blows the air through chilling ducts 119 that are made of thermally conductive material and run through the tertiary reservoir of organic phase change material 118, cooling the air as it passes, after which it blows through an insulated plenum 115 and into insulated distribution ducts, blowing into the desired conditioned area 116. Further details for comfort heating and cooling are described in FIGS. 32-35. For electric power generation, a thermoelectric generator core 87 as described in FIG. 27, is set between the chilled tertiary reservoir of organic phase change material 118 and the heated secondary reservoir of organic phase change material 109, in order to maintain a temperature differential sufficient enough to generate electrical energy that may be connected via electrical wiring 120 to a DC electrical sub-panel 121 where the electricity can be distributed to electrical loads via electrical wiring 120.

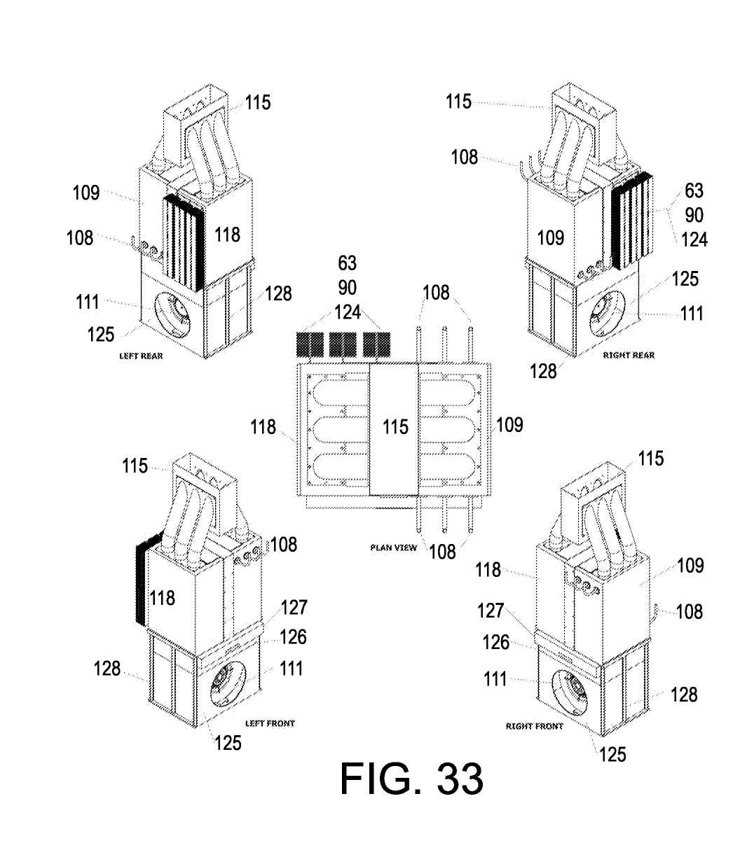

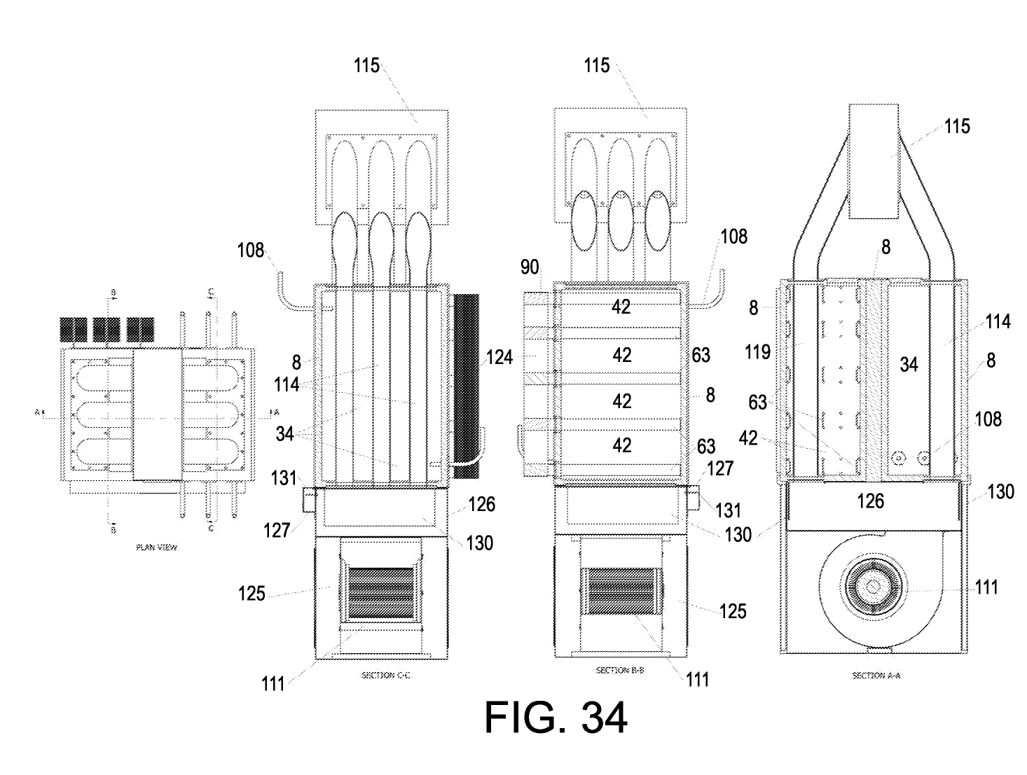

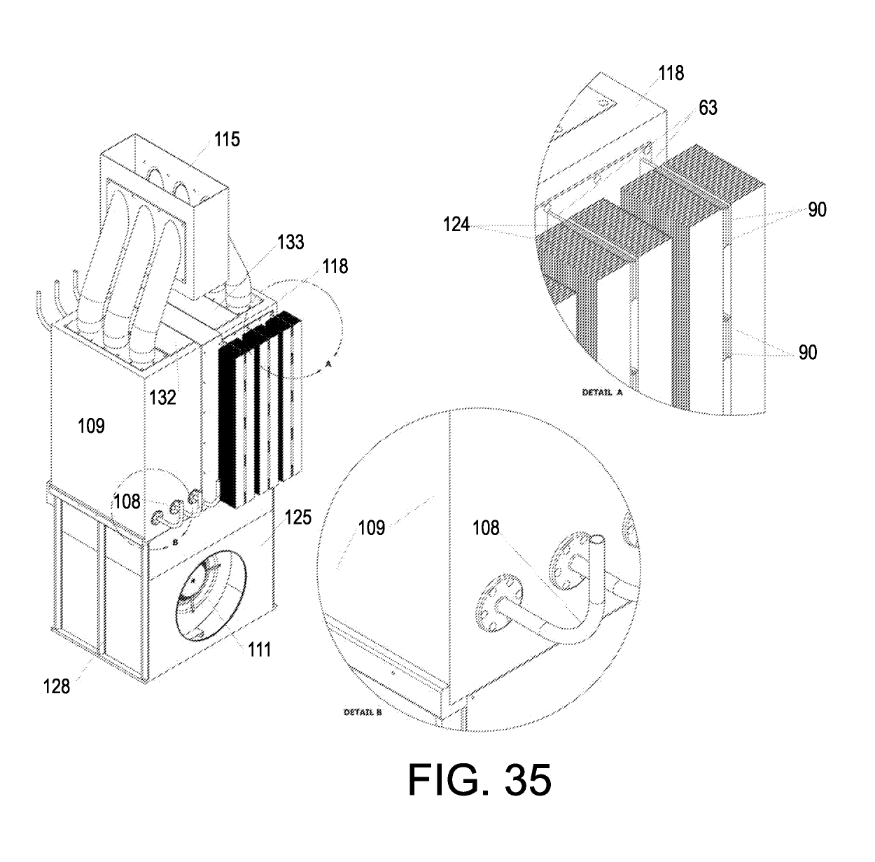

Additional details of the exemplary embodiment described in FIG. 28 can be found in FIGS. 29-35. FIG. 29 is a plan view and corresponding elevation and isometric views of a solar thermal collection system of an exemplary embodiment of a thermoelectric device that may be utilized in exemplary thermoelectric energy generation, hot water heating, comfort heating, cooling systems or combinations thereof. FIG. 30 is another plan view with corresponding section views of a solar thermal collection system of an exemplary embodiment of a thermoelectric device that may be utilized in exemplary thermoelectric energy generation, hot water heating, comfort heating, cooling systems or combinations thereof. FIG. 31 is a plan view and corresponding elevation, section and isometric views of a solar thermal hot water tank of an exemplary embodiment of a thermoelectric device that may be utilized in exemplary hot water heating systems. FIG. 32 is a plan view and corresponding elevation views of a thermoelectric comfort heating and/or comfort cooling system of an exemplary embodiment of a thermoelectric device that may be utilized in exemplary thermoelectric energy generation, comfort heating and/or cooling systems. FIG. 33 is another plan view and corresponding isometric views of a thermoelectric comfort heating and/or comfort cooling system of an exemplary embodiment of a thermoelectric device that may be utilized in exemplary thermoelectric energy generation, comfort heating and/or cooling systems. FIG. 34 is another plan view and corresponding section views of a thermoelectric comfort heating and/or comfort cooling system of an exemplary embodiment of a thermoelectric device that may be utilized in exemplary thermoelectric energy generation, comfort heating and/or cooling systems. FIG. 35 is an isometric view and corresponding detail views of a thermoelectric comfort heating and/or comfort cooling system of an exemplary embodiment of a thermoelectric device that may be utilized in exemplary thermoelectric energy generation, comfort heating and/or cooling systems.

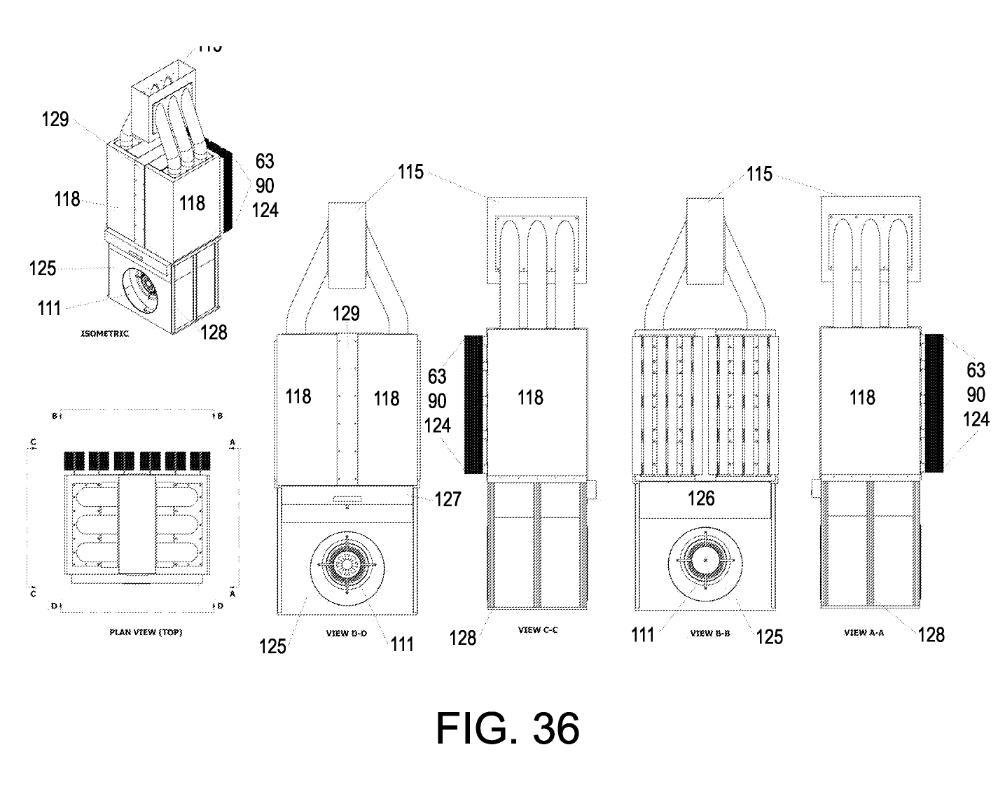

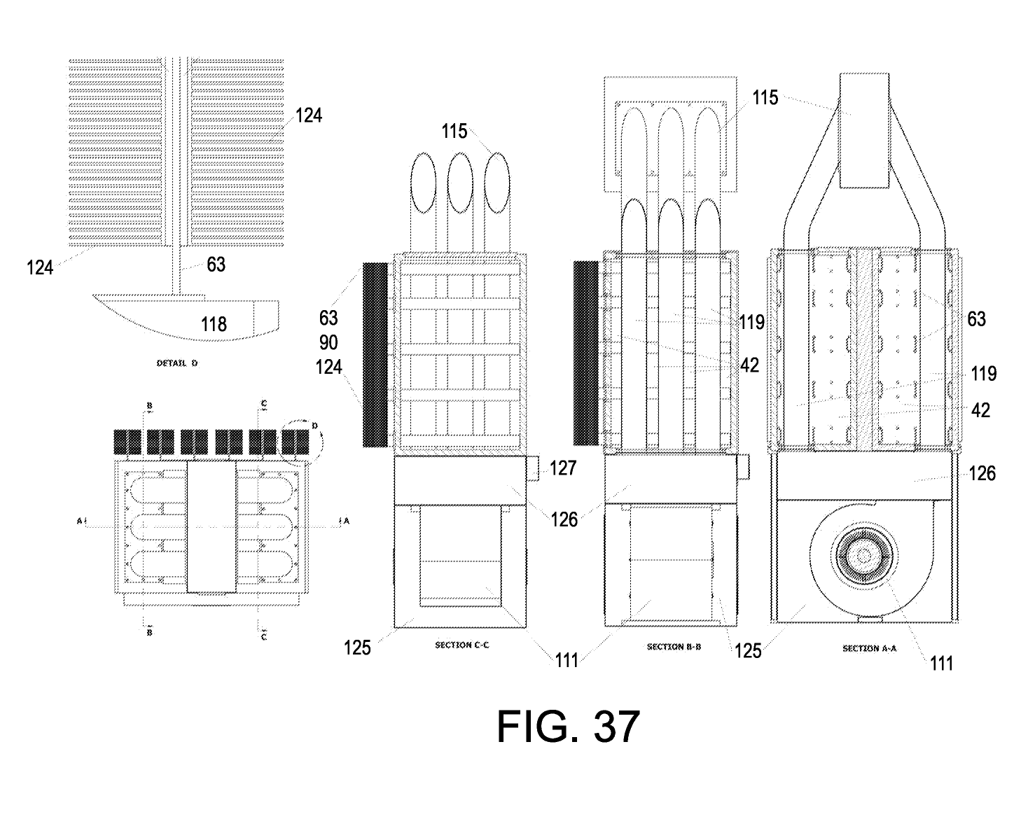

FIGS. 36 and 37 are a plan views and corresponding elevation, section, isometric, and detail views of an exemplary embodiment of a thermoelectric cooling system. An exemplary embodiment of a system, method and/or apparatus of a thermoelectric cooling system as described in FIGS. 36 and 37 where a photovoltaic panel(s) 117 or other renewable energy source such as wind or thermoelectric generates electrical energy where it is stored in capacitor arrays 21 or building grid power converted to DC power to provide a stable output to thermoelectric chiller modules 90 attached to low temperature heat plates 86 that chill organic phase change material that becomes a solid at −15° C. in a tertiary reservoir of organic phase change material 118. When cooled air is desired, a thermostat or control switch 110 starts a blower 111 that is electrically powered, which draws air 112 from the conditioned space through a filtered return air grill 113 and blows the air through chilling ducts 119 that are made of thermally conductive material and run through the tertiary reservoir of organic phase change material 118, cooling the air as it passes, after which it blows through an insulated plenum 115 and into insulated distribution ducts, blowing into the desired conditioned area 116.

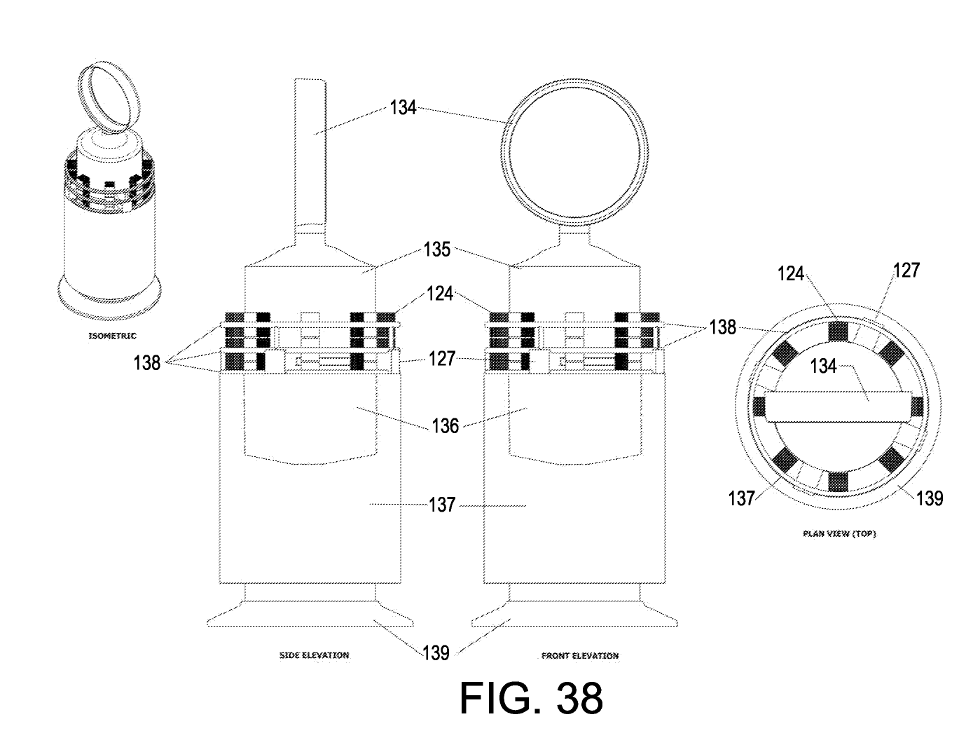

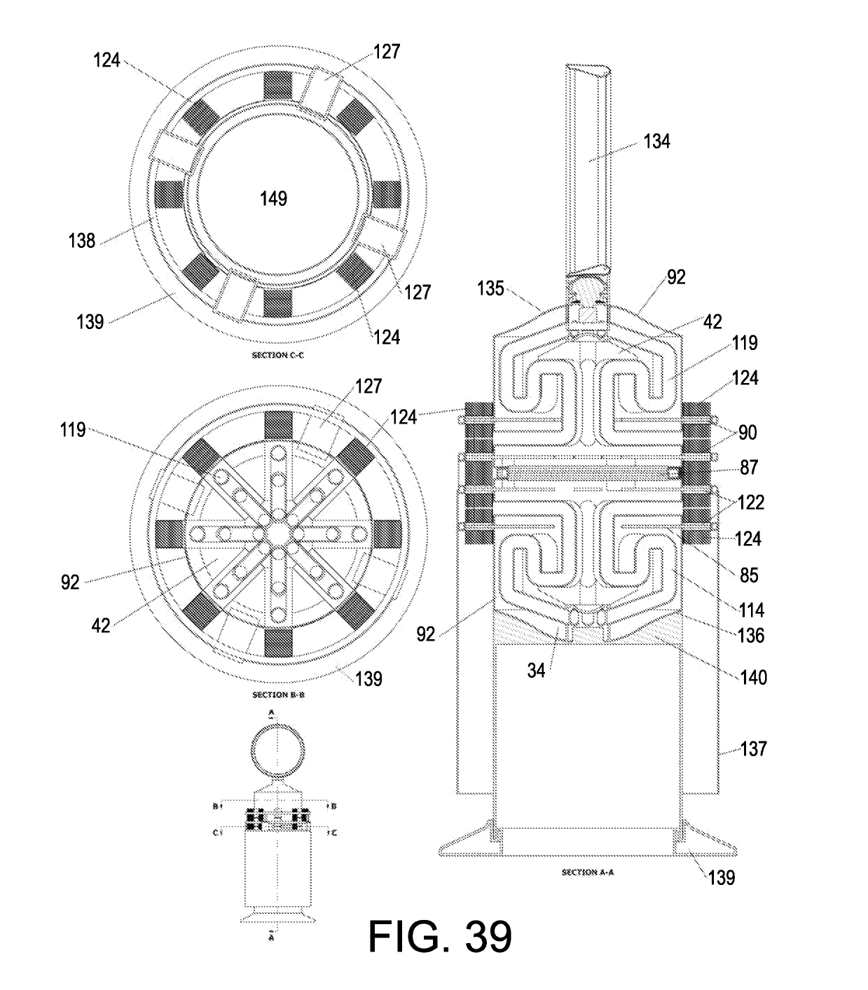

FIG. 38 and FIG. 39 are plan views with corresponding elevation, section and isometric views of an exemplary embodiment of a portable thermoelectric heating, cooling and/or electrical generation system. Referring to FIG. 38, a Dyson air multiplier 134, fan or similar-type fan unit, is set in a housing, designed to accommodate the Dyson air multiplier's 134 air input openings, of a removable chill reservoir 135 designed to provide suitable airflow for the air input openings of the a Dyson air multiplier 134, fan or similar-type fan unit when it is in cooling mode. Additionally, the same Dyson air multiplier 134, fan or similar type fan unit, may also be set in a housing, designed to accommodate the Dyson air multiplier's 134 air input openings, of a removable heat reservoir when it is in heating mode. A control box 127 along with capacitor array 21 wiring chases 138, heat sinks 124 and a thermoelectric generator core 87 is at the center of the unit with the removable chill reservoir 135 on one side and the removable heat reservoir 136 on the other side of the thermoelectric generator core 87. This portion of the system may be placed with either side (hot or cold) up within its base 139 that is wrapped with a photovoltaic skirt 137 that supplies electrical power to the system's heating, cooling and air movement needs. Additionally, as described in FIG. 39, a Dyson air multiplier 134, fan or similar-type fan unit, is set in a housing, designed to accommodate the Dyson air multiplier's 134 air input openings, of a removable chill reservoir 135 filled with low temperature phase change material 42 with integrated chilling ducts 119 that are designed to provide suitable airflow for the air input openings of the a Dyson air multiplier 134, fan or similar-type fan unit when it is in cooling mode. During the cooling operation the Dyson air multiplier 134, fan or similar type fan draws air from the local environment through the integrated chilling ducts 119 where it is cooled as it rejects heat into the low temperature phase change material 42 and blows the cooled air back out into the local environment. The low temperature phase change material 42 is kept at the desired temperature by using power obtained by the photovoltaic skirt 137, conditioned and stored until needed in the capacitor array 21, to run thermoelectric chiller modules 90 placed on both sides of low temperature heat plates 86, with the thermoelectric chiller modules' 90 “cold” side facing into the low temperature heat plates 86, and their “hot” side connected to heat sinks 124, that are partially embedded and sealed around their exit of the removable chill reservoir 135 filled with low temperature phase change material 42. Additionally, the same Dyson air multiplier 134, fan or similar-type fan unit, is set in a housing designed to accommodate the Dyson air multiplier's 134 air input openings, of a removable heat reservoir 136 filled with high temperature phase change material 34 with integrated heating ducts 114 that are designed to provide suitable airflow for the air input openings of the a Dyson air multiplier 134 or similar type fan unit when it is in heating mode. During the heating operation the Dyson air multiplier 134, fan or similar type fan draws air from the local environment through the integrated heat ducts 114 where it is heated as it draws heat from the high temperature phase change material 34 and blows the heated air back out into the local environment. The high temperature phase change material 34 is kept at the desired temperature by using power obtained by the photovoltaic skirt 137, conditioned and stored until needed in the capacitor array 21, to run thermoelectric heaters 122 placed on both sides of high temperature heat plates 85, with the thermoelectric heater's 122 “hot” side facing into the high temperature heat pipes 85 and “cold” side connected to heat sinks 124 that are partially embedded and sealed around their exit of the removable heat reservoir 136 filled with high temperature phase change material 34. As a result of a substantial thermal difference held between the removable heat reservoir 136 and the removable chill reservoir 135 the thermoelectric generator core 87 being in direct contact of each reservoir's thermally conductive skin 149 generates electrical energy for use as needed or stored in the capacitor array 21 for later use.

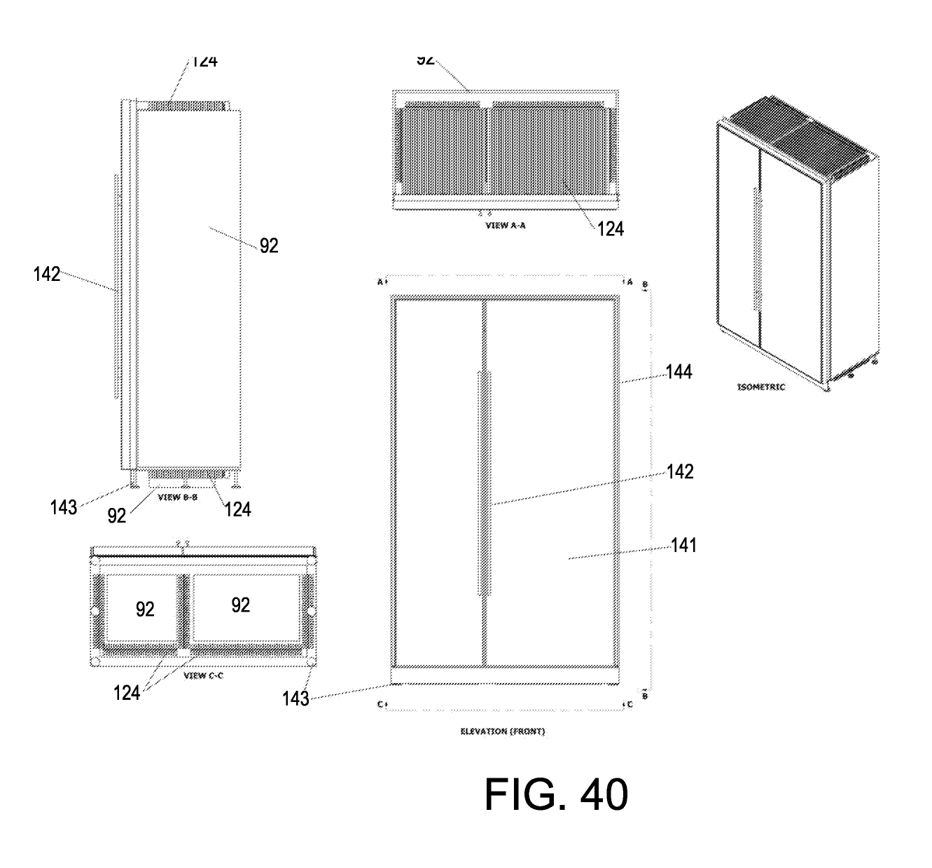

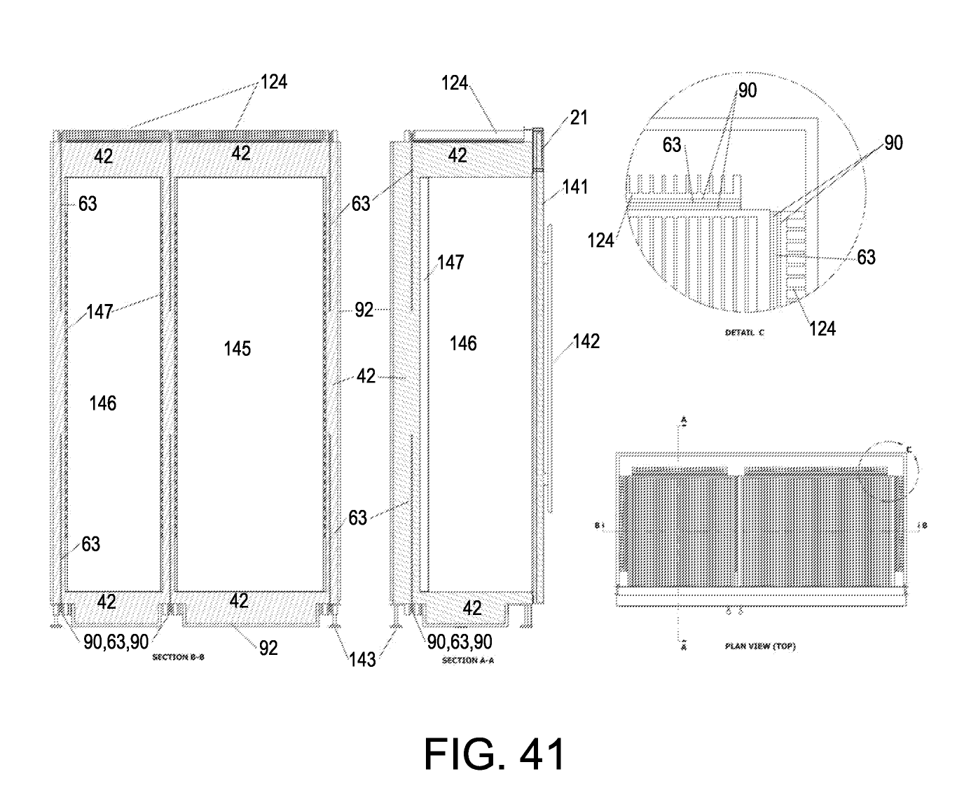

FIGS. 40 and 41 are an elevation view and corresponding other elevation, plan, section, detail and isometric views of an exemplary embodiment of a thermoelectric solid-state refrigeration system. Referring to FIG. 40, a refrigerator chamber 145 and freezer chamber 145 would maintain a low temperature to refrigerate and/or freeze stored food or other perishables are lined with thermally conductive skin 149 facing the inner chambers and thermally insulated outer casing 92 facing outward into ambient temperature. The cavity created between the thermally conductive skin 149 and the thermally insulated outer casing 92 may be filled with low temperature phase change material 42. An additional layer of an insulating barrier 8, such as rigid foam insulation, may be used to further maintain the cavities' temperatures. To bring the refrigerator chamber 145 and freezer chamber 146 to desired temperatures and to maintain those temperatures, low temperature heat pipes 63 may be embedded into the low temperature phase change material 42 with a portion protruding beyond the thermally-insulated outer casing 92 to fit and attach thermoelectric chiller modules 90 with their “cold” side to the low temperature heat pipes 63 and their “hot” side attached to a heat sink 124. The thermoelectric chiller modules 90 may be powered using any DC power source available. While not being powered to chill, the thermoelectric chiller modules 90 may have a thermal difference between their “cold” side and “hot” side effectively making them thermoelectric generators 1 as they slowly leak the heat from the outer ambient temperature into the low temperature phase change material 42. This electrical energy may be stored in a capacitor array 21 to aid in the re-chilling or power lights when the insulated door 141 of either the refrigerator chamber 145 or freezer chamber 146 is opened. The system may also include adjustable feet 143 for leveling purposes, door handles 142, door panel frames 144 with appropriate opening hardware and shelve and bin racks 147 for storage purposes.

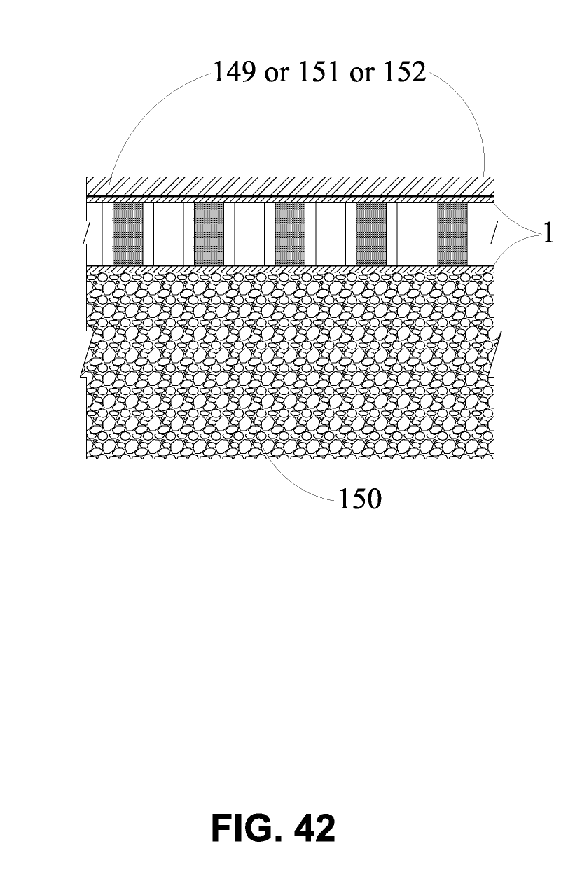

FIG. 42 is a schematic section view of an exemplary embodiment of a thermoelectric harvesting configuration. An exemplary embodiment of a system, method and/or apparatus of thermoelectric energy conversion as described in FIG. 27, used to power electric motor(s) in vehicles may have a thermal regeneration system using a thermoelectric harvesting configuration as shown in FIG. 42, comprised of thermoelectric generators 1 attached to, and/or in thermal communication with, the underside of the outer thermally conductive skin 149 that makes up a vehicle's outer shell, which is exposed to the elemental and atmospheric temperature differences relative to location and time of day and/or year and absorb or reject thermal energy. The opposite side of the thermoelectric generators 1 may be connected to, and/or in thermal communication with, a thermally conductive foam 150 such as aluminum foam or carbon foam that may act as a thermal absorber/rejecter that is shielded, simply by orientation, to the elemental and atmospheric temperature differences relative to location and time of day and/or year, causing a thermal difference between the two sides of the thermoelectric generators 1 and generating electrical energy. The electrical harvest will vary based on location, weather and/or speed, at which the vehicle was moving. For certain embodiments, another harvesting opportunity for the thermal regeneration system may be available from the heat caused by friction in the braking system. As shown in FIG. 42, thermoelectric generators 1 attached to, and/or in thermal communication with, the backside braking discs 151 absorb heat as a driver uses the brakes to slow or come to a stop. The opposite side of the thermoelectric generators 1 may be connected to, and/or in thermal communication with, a thermally conductive foam 150 such as aluminum foam or carbon foam that may act as a thermal absorber/rejecter, causing a thermal difference between the two sides of the thermoelectric generators 1 and generating electrical energy. Another harvesting opportunity for the thermal regeneration system may be available from the comfort heating system waste, as shown in FIG. 42, thermoelectric generators 1 attached to, and/or in thermal communication with, the areas that typically “leak” heat intended for the vehicle occupants, such as duct walls and vent plates 152 absorb the waste thermal energy. The opposite side of the thermoelectric generators 1 may be connected to, and/or in thermal communication with, a thermally conductive foam 150 such as aluminum foam or carbon foam that would act as a thermal rejecter, causing a thermal difference between the two sides of the thermoelectric generators 1 and generating electrical energy. Another harvesting opportunity for the thermal regeneration system may be available from the comfort cooling system waste, as shown in FIG. 42, thermoelectric generators 1 attached to, and/or in thermal communication with, the areas that typically “leak” chilling intended for the vehicle occupants, such as duct walls and vent plates 152 rejecting the waste thermal energy. The opposite side of the thermoelectric generators 1 may be connected to, and/or in thermal communication with, a thermally conductive foam 150 such as aluminum foam or carbon foam that would act as a thermal absorber, causing a thermal difference between the two sides of the thermoelectric generators 1 and generating electrical energy.

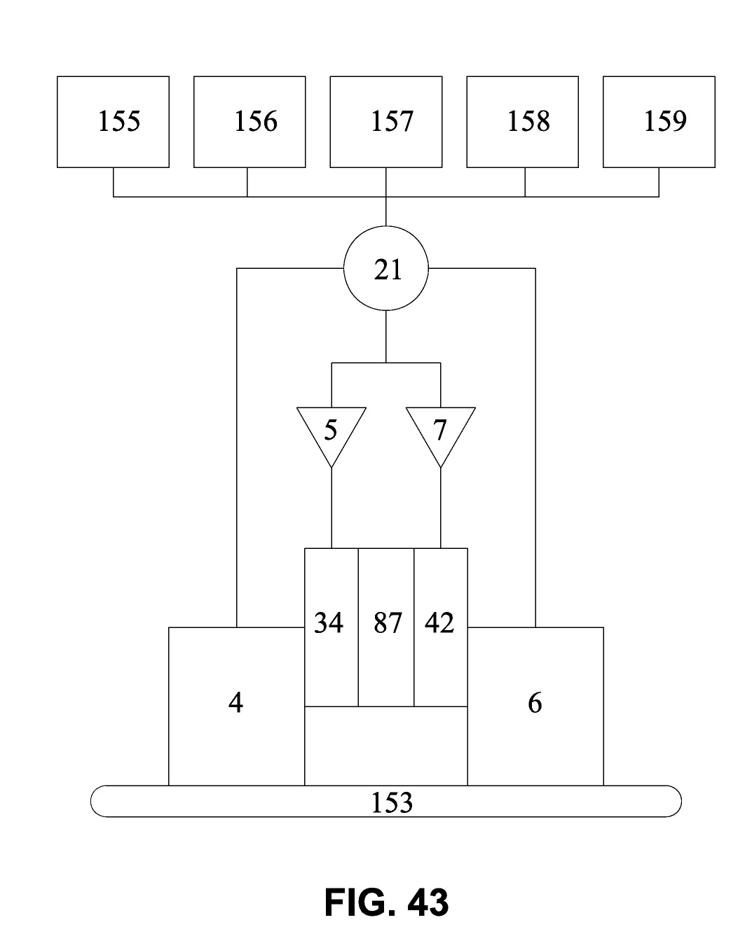

FIG. 43 is a block diagram of an exemplary embodiment of a thermoelectric generating system utilizing multiple thermal regeneration methods for use in land vehicles. Now referring to FIG. 43, the thermoelectric generator core 87 of the thermoelectric generator described in FIG. 27 uses the thermal differences stored in two thermally separated tanks of Organic Phase Change Materials (OPCM's) 34 and 42 to generate electrical energy sufficient to power, or to supplement the power of, the vehicles' electric motor. To regenerate those thermal energy tanks, whether or not the vehicle is being operated, the following regeneration embodiment may be employed. First the electrical energy generated by the thermoelectric generator's regeneration thermoelectric generator(s) 4 and 5 attached to, and/or in thermal communication with, the outside of the two thermally separated tanks of OPCM's 34 and 42 on one side and to heat pipe plates 153 attached to the mass of the vehicles' chassis 154, absorbing or rejecting thermal energy from the other side as well as the electrical energy from the harvesting methods disclosed herein; harvest from outside skin 155, harvest from braking 156, harvest from waste comfort heat 157, harvest from waste comfort chilling 158, and harvest from braking impulse energy 159 are connected electrically to pass electrical current yielded, without polarity bias, into capacitor arrays 21. The capacitor arrays 21 may be designed to use the stored harvested electrical energy described herein to run either a heater 5 or a cooler 7 in order to keep the two thermally separated tanks of OPCM's 2 and 3, one with a designed high phase change temperature and one with a designed low phase change temperature, at their desired temperatures as shown in FIG. 27.

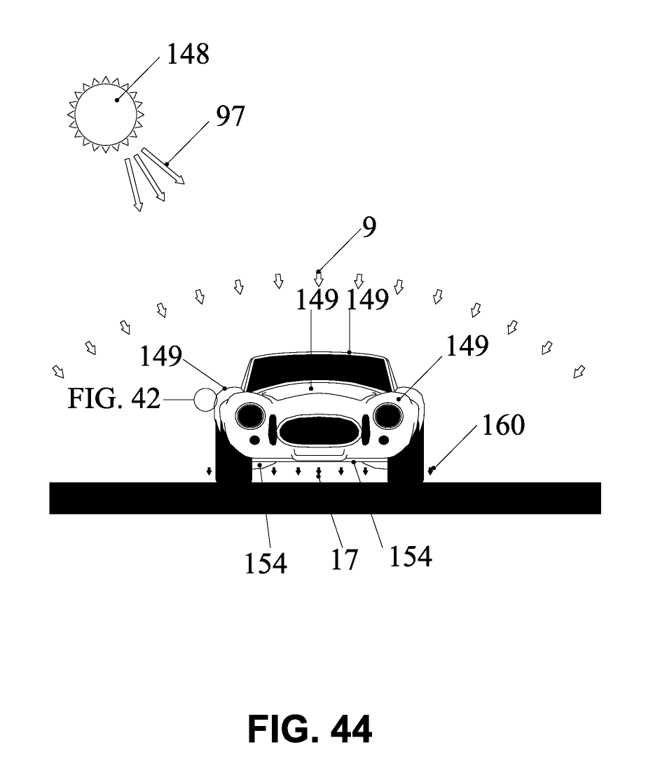

FIG. 44 is a schematic diagram of an exemplary embodiment of a thermoelectric regenerating system thermal energy harvester, for use in land vehicles during sunlight and in warm to hot temperatures. Now referring to FIG. 44, a thermoelectric generator as described in FIG. 27 used to power a vehicle may utilize the atmospheric conditions of the vehicle's location to harvest thermal energy to power a thermoelectric regenerating system previously described in FIG. 43. Heat from the sun 148 and the sun's radiation 97 create a high side ambient temperature 9 that transfers heat energy to the thermally conductive skin 149 of a thermoelectric harvesting configuration as described in FIG. 42. The vehicles' chassis 154 rejects heat energy into the low side ambient temperature away from the thermally conductive skin 149, as shown in FIG. 42, shown by filled arrows as the heat rejection direction 160.

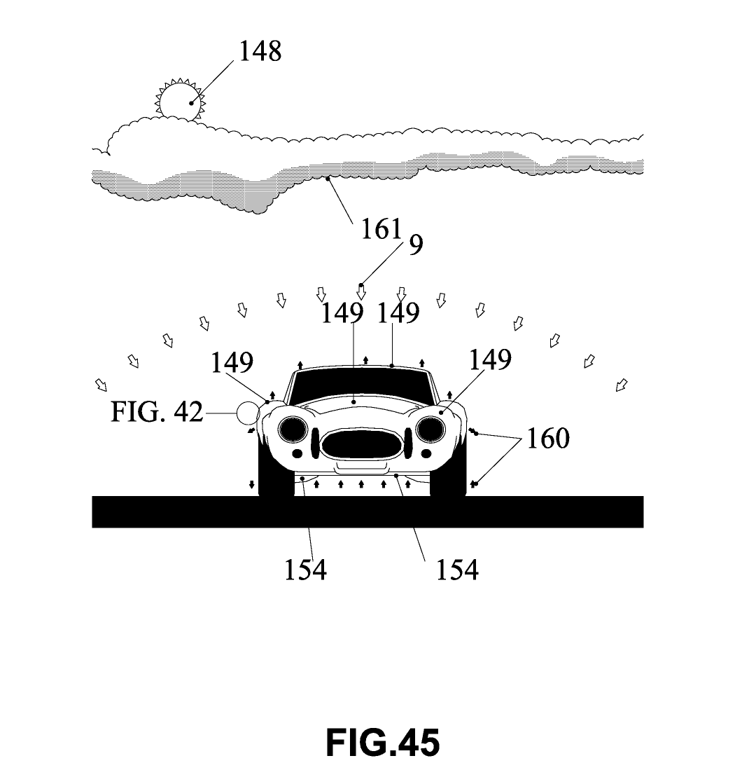

FIG. 45 is a schematic diagram of an exemplary embodiment of a thermoelectric regenerating system thermal energy harvester, for use in land vehicles during days without sunlight, night and in cold to freezing temperatures. Now referring to FIG. 45, a thermoelectric generator as described in FIG. 27 used to power a vehicle may utilize the atmospheric conditions of the vehicle's location to harvest thermal energy to power a thermoelectric regenerating system previously described in FIG. 43. Heat from the vehicles interior escapes into ambient temperature 9 as it passes through the thermally conductive foam 150 the thermoelectric generators 1 and the thermally conductive skin 149 of a thermoelectric harvesting configuration as described in FIG. 42. The vehicles' chassis 154 draws heat energy from the road into the thermally conductive foam 150, as shown in FIG. 42, shown by filled arrows as the heat rejection direction 160.

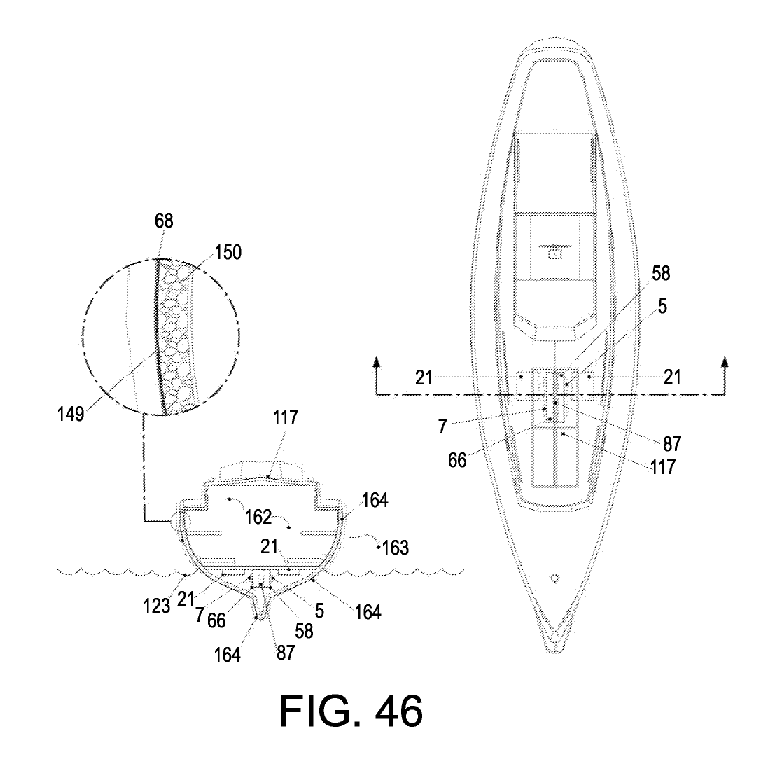

FIG. 46 is a schematic diagram of an exemplary embodiment of a thermoelectric generating system for use in marine vessels. Referring to FIG. 46, to be used to recharge, marine vessels may have at least two thermoelectric regeneration systems to maintain storage of a defined thermal capacity. The first thermoelectric regeneration system comprised of thermoelectric modules 68 that have one side attached to, and/or in thermal communication with, a thermally conductive skin 149 and the other side attached to, and/or in thermal communication with, a thermally conductive foam 150 such as aluminum foam or carbon foam that would act as a thermal absorber/rejecter, rejecting heat from the vessel interior ambient temperature 162 into the body of water 123 in which the vessel is floating. The electrical energy produced by the thermoelectric modules 68 due to this thermal difference may be stored, without polarity bias, in capacitor arrays 21 to power heaters 5 and/or chillers 7 to regenerate, when needed, the high temperature thermal storage 58 and the low temperature thermal storage 66 of the thermoelectric generator core 87 of the thermoelectric generator described in FIG. 27, in order to have a thermal difference for thermoelectric energy generation for use in powering the vessel. This thermally conductive skin 149 is designed to begin below the vessel's waterline 123. The second thermoelectric regeneration system comprised of thermoelectric modules 68 that have one side attached to, and/or in thermal communication with, a thermally conductive skin 149 and the other side attached to, and/or in thermal communication with, a thermally conductive foam 150 such as aluminum foam or carbon foam that would act as a thermal absorber/rejecter, rejecting heat from the vessel interior ambient temperature 162 into the outside vessel ambient temperature 163. The electrical energy produced by the thermoelectric modules 68 due to this thermal difference, without polarity bias, may be stored in capacitor arrays 21 to power heaters 5 and/or chillers 7 to regenerate, when needed, the high temperature thermal storage 58 and the low temperature thermal storage 66 of the thermoelectric generator core 87 of the thermoelectric generator described in FIG. 27, in order to have a thermal difference for thermoelectric energy generation for use in powering the vessel. Additionally, photovoltaic panels 117 may be added to the system to power heaters 5 and/or chillers 7 to regenerate, when needed, the high temperature thermal storage 58 and the low temperature thermal storage 66 of the thermoelectric generator core 87 of the thermoelectric generator described in FIG. 27, in order to have a thermal difference for thermoelectric energy generation for use in powering the vessel if the vessel is in water and atmospheric temperatures with little or no thermal difference.

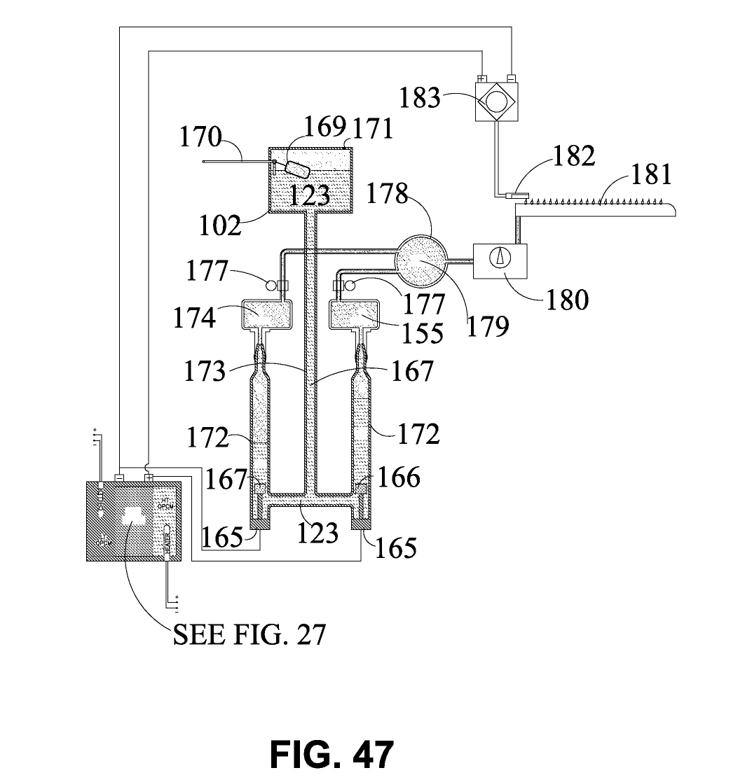

FIG. 47 is a schematic diagram of an exemplary embodiment of a thermoelectric generating system for use for the production of hydrogen gas from water by means of electrolysis. Referring to FIG. 47, electrical energy from the thermoelectric generator 1 as described in FIG. 27 is sent to the electrolysis terminals 165. The positive lead connected to the anode 166 and the negative lead to the cathode 167 that are submerged in a water solution 168 that is best for the process of electrolysis. The water solution 168, contained in a water storage tank 102 that may have a refill apparatus such as a float valve 169, water inlet 170, and air or compound inlet 171, is fed to the electrolysis chambers 172 by way of a common inlet 173. When an electrical charge is applied the water molecules are split into hydrogen 174 and oxygen 175 gas that is captured in gas tanks 176. The extracted gas may then be directed through a regulator 177, into a mixing chamber 178 where it mixes into the desired burn fuel 179. The burn fuel 179 is piped through an oven or fireplace valve 180 of the oven or fireplace burner 181, and may be ignited, using a glow plug 182 switched on by an oven or fireplace control switch 183 or other conventional methods.

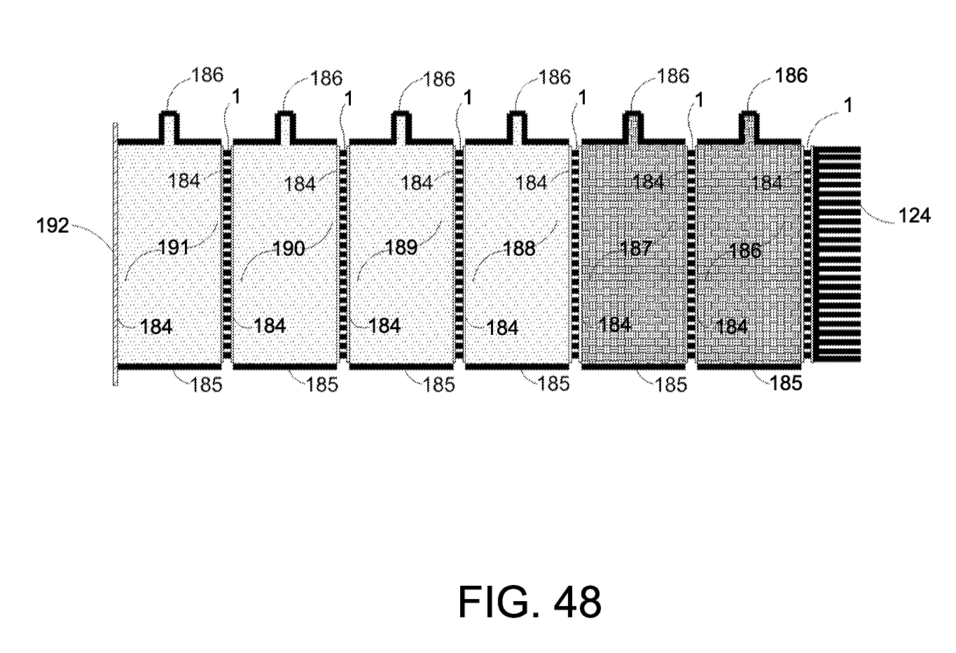

FIG. 48 is a schematic section of an exemplary embodiment of a thermoelectric solid-state chiller system for the purposes of cooling nitrogen gas into a liquid from average ambient temperatures. In certain aspects, this may be done silently or with reduced noise and/or vibration. Referring to FIG. 48, to be used with reduced or little noise and/or with little or reduced vibration chill a chamber of nitrogen from a gas to a liquid state comprised of a thermoelectric generator 1 capable of rejecting a heat differential of a minimum of twenty eight degrees Celsius, having its “hot” side attached to, and/or in thermal communication with, a heat sink 124 and the thermoelectric generator's 1 cold side attached to, and/or in thermal communication with, a sealed (or substantially sealed) thermally conductive membrane 184 of a first thermal chamber 185 that has four other sides insulated, one of those sides having a filler cap 186 allowing the first thermal chamber 185 to be filled with an organic phase change material 187 that becomes frozen at four degrees Celsius, and the sixth side being a sealed (or substantially sealed) thermally conductive membrane 184. The first thermal chamber's 185 sixth side sealed (or substantially sealed) thermally conductive membrane 184 is attached to, and/or in thermal communication with, the “hot” side of a separate thermoelectric generator 1 capable of rejecting a heat differential of a minimum of forty one degrees Celsius and the thermoelectric generator's 1 “cold” side is attached to, and/or in thermal communication with, a sealed (or substantially sealed) thermally conductive membrane 184 of a second thermal chamber 185 having four other sides insulated, one of those sides having a filler cap 186 allowing the second thermal chamber 185 to be filled with an organic phase change material 187 that becomes frozen at minus thirty seven degrees Celsius and the sixth side being a sealed (or substantially sealed) thermally conductive membrane 184. The second thermal chamber's 185 sixth side sealed (or substantially sealed) thermally conductive membrane 184 is attached to, and/or in thermal communication with, the “hot” side of a separate thermoelectric generator 1 capable of rejecting a heat differential of a minimum of seventy degrees Celsius and the thermoelectric generators 1 cold side is attached to, and/or in thermal communication with, a sealed (or substantially sealed) thermally conductive membrane 184 of a third thermal chamber 185 that has four other sides insulated, one of those sides having a filler cap 186 allowing the third thermal chamber 185 to be filled with xenon gas 188 that becomes liquid at minus one hundred and seven degrees Celsius and the sixth side being a sealed (or substantially sealed) thermally conductive membrane 184. The third thermal chamber's 185 sixth side sealed (or substantially sealed) thermally conductive membrane 184 is attached to, and/or in thermal communication with, the “hot” side of a separate thermoelectric generator 1 capable of rejecting a heat differential of a minimum of forty five degrees Celsius and the thermoelectric generator's 1 “cold” side attached to, and/or in thermal communication with, a sealed (or substantially sealed) thermally conductive membrane 184 of a fourth thermal chamber 185 that has four other sides insulated, one of those sides having a filler cap 186 allowing the forth thermal chamber 185 to be filled with krypton gas 189 that becomes liquid at minus one hundred and fifty two degrees Celsius and the sixth side of the fourth thermal chamber 185 being a sealed (or substantially sealed) thermally conductive membrane 184. The fourth thermal chamber's 185 sixth side sealed (or substantially sealed) thermally conductive membrane 184 is attached to, and/or in thermal communication with, the “hot” side of a separate thermoelectric generator 1 capable of rejecting a heat differential of a minimum of thirty three degrees Celsius and the thermoelectric generator's 1 “cold” side attached to, and/or in thermal communication with, a sealed (or substantially sealed) thermally conductive membrane 184 of a fifth thermal chamber 185 that has four other sides insulated, one of those sides having a filler cap 186 allowing the fifth thermal chamber 185 to be filled with argon gas 190 that becomes liquid at minus one hundred and eighty five degrees Celsius and the sixth side being a sealed (or substantially sealed) thermally conductive membrane 184. The fifth thermal chamber's 185 sixth side sealed (or substantially sealed) thermally conductive membrane 184 is attached to, and/or in thermal communication with, the “hot” side of a separate thermoelectric generator 1 capable of rejecting a heat differential of a minimum of ten degrees Celsius and the thermoelectric generator's 1 “cold” side attached to, and/or in thermal communication with, a sealed (or substantially sealed) thermally conductive membrane 184 of a thermal sixth chamber 185 that has four other sides insulated, one of those sides having a filler cap 186 allowing the sixth thermal chamber 185 to be filled with nitrogen gas 191 that becomes liquid at minus one hundred and ninety five degrees Celsius and the sixth side being a sealed (or substantially sealed) thermally conductive membrane 184. The sixth thermal chamber's 185 sixth side sealed (or substantially sealed) thermally conductive membrane 184 is attached to a Chill Plate 192 that may be attached to desired object that requires chilling.

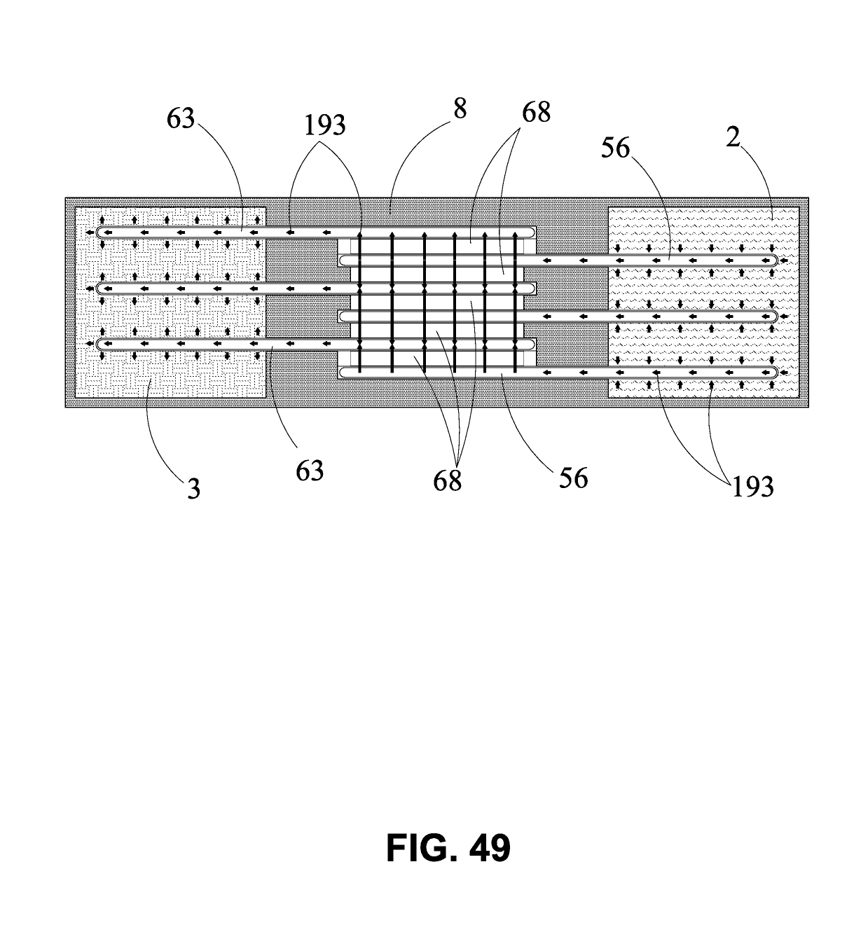

FIG. 49 is a schematic section of an exemplary embodiment of a thermoelectric generator with isolated, sufficiently isolated, and/or substantially isolated high and low temperature storage. Referring to FIG. 49, it is desirable for the efficiency of the thermoelectric system to maintain the high temperature storage 2 and the low temperature storage 3 with minimal leakage while allowing the thermal energy from the high temperature storage 2 to move in a heat flow direction 193 into a high temperature heat pipe 56 where it travels towards the cooler thermoelectric generator module 68, it than passes through the thermoelectric generator module 68, generating electrical energy, and is drawn to the cooler temperature of the low temperature heat pipe 63 on the thermoelectric generator's opposite side where it is drawn away towards the mass in the low temperature storage 3.

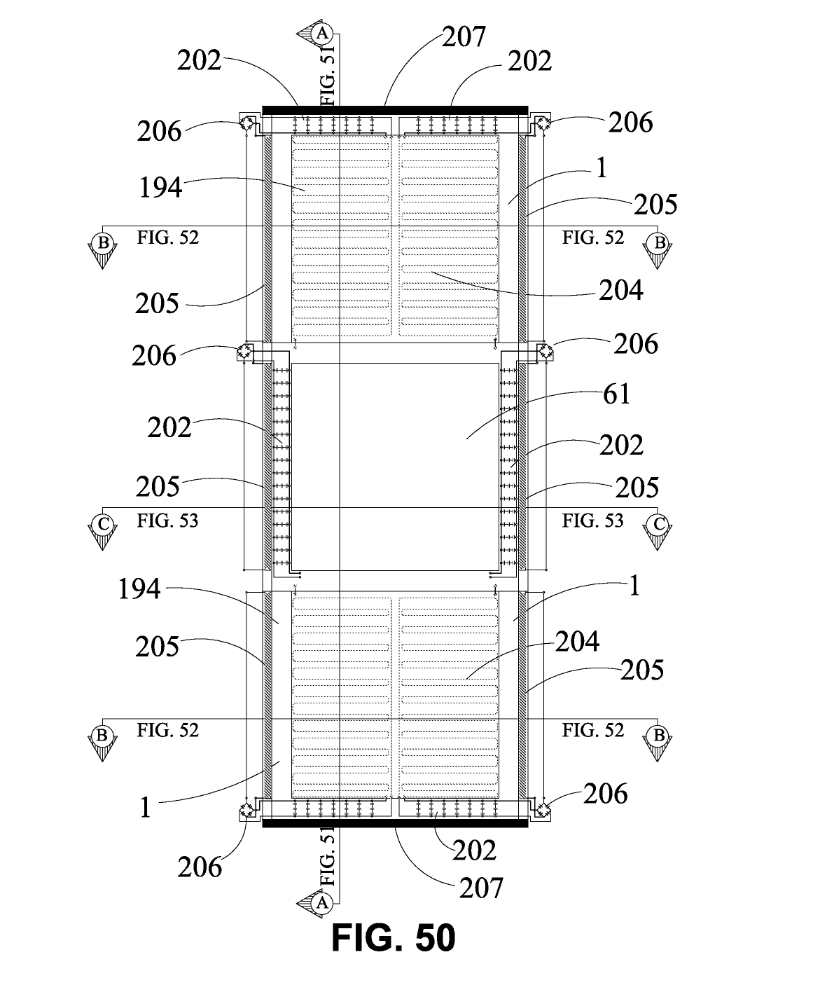

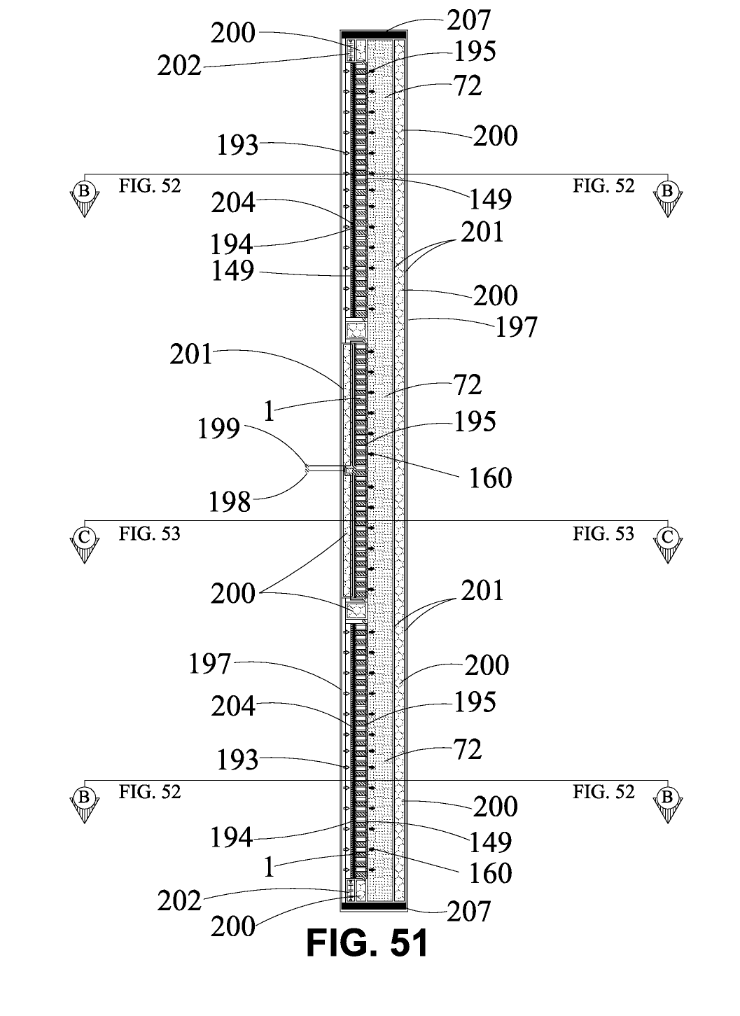

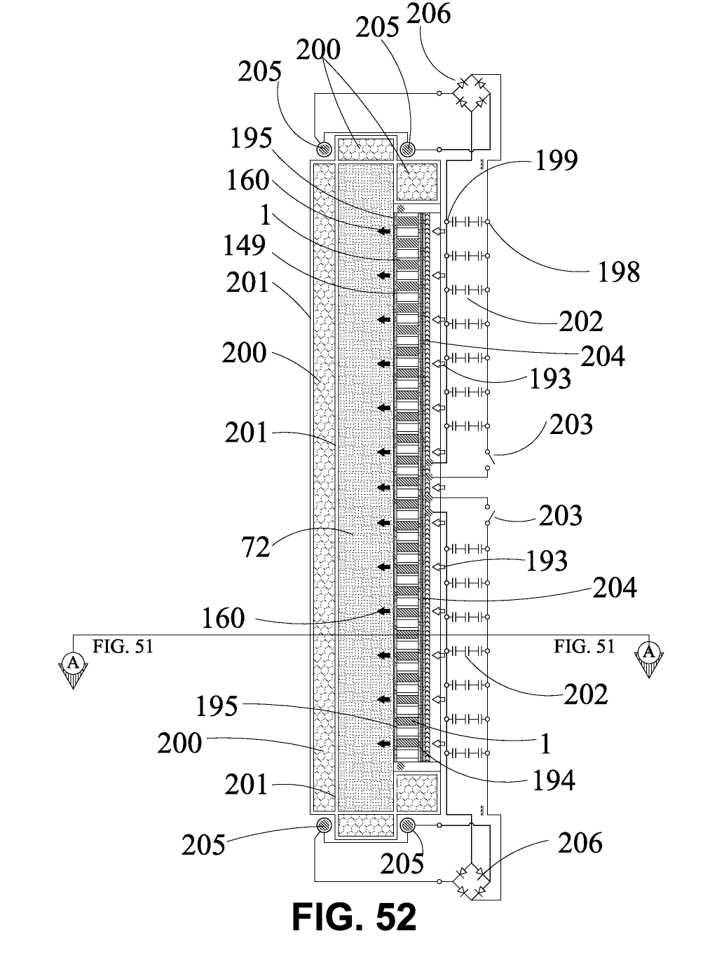

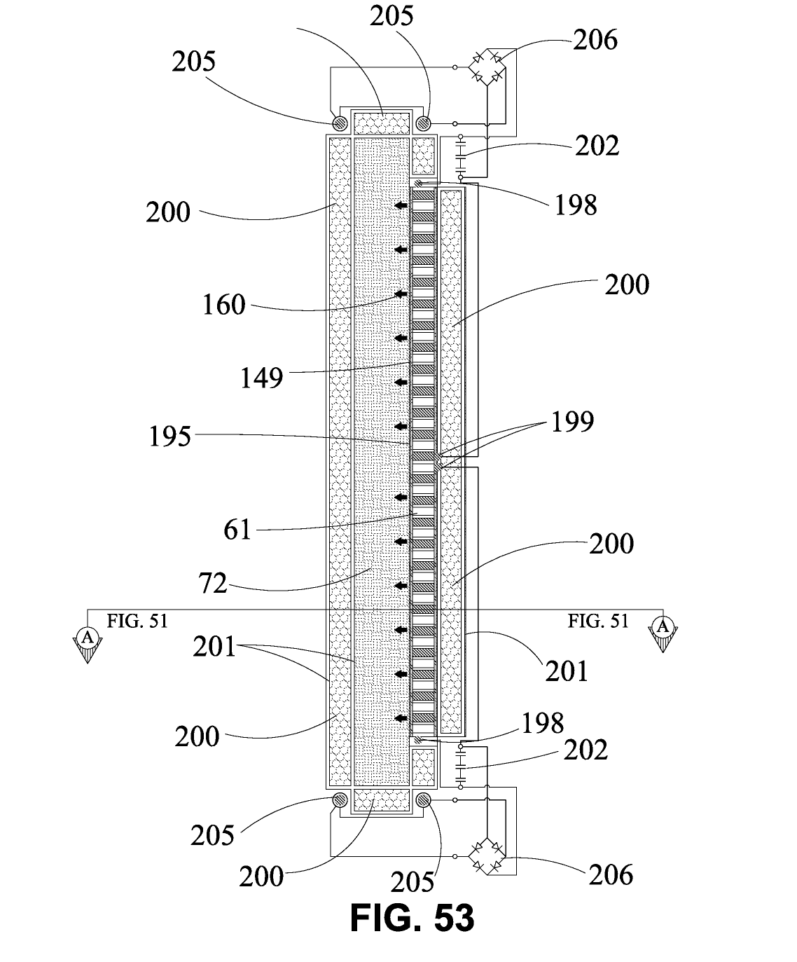

FIG. 50 is a schematic diagram of an exemplary embodiment of an electromagnetic and thermal energy harvesting power supply for use in mobile phones and/or handheld devices. FIG. 51 is a schematic diagram of an exemplary embodiment of cross-section A of the exemplary power supply of FIG. 50 for use in mobile phones, computing tablets, and/or handheld devices. FIG. 52 is a schematic diagram of an exemplary embodiment of cross-section B of the exemplary power supply of FIG. 50 for use in mobile phones, computing tablets, and/or handheld devices. FIG. 53 is a schematic diagram of an exemplary embodiment of cross-section C of the exemplary power supply of FIG. 50 for use in mobile phones and/or handheld devices. Referring to FIG. 50, a schematic diagram of an exemplary embodiment of an electromagnetic and thermal energy harvesting power supply for use in a device of choice (e.g., mobile phone, computing tablets, and/or handheld devices) is shown. In exemplary embodiments, the power supply may be used to power a device so long as the input power requirement of the device matches (or substantially matches) the output power of the described power supply. In certain embodiments, the thermal energy power supply may be combined with a battery to supplement the power provided by the battery and/or to recharge the battery. In exemplary embodiments, ambient electromagnetic radiation may be harvested using a series of enameled (or otherwise insulated) wire coil around an electrically conductive shaft (e.g., cylindrical ferrite cores 205) of differing sizes and wraps to match (or substantially match) multiple frequencies in order to harvest energy at multiple wavelengths and frequencies, where it is then converted to direct current using blocking diodes in a rectifying circuit 206 and used to fill ultra capacitor arrays 202 designed for an output power matching the input of thermoelectric chillers 33 and Nichrome coil heat elements 204. In exemplary embodiments, the coil may be implemented without a conductive shaft. The electromagnetic harvesting may be constant, if desired, regardless of whether the device of choice is being operated. Additionally, piezoelectric material 207 may be added to the outer housing 197 and the electric energy stored may be stored in the ultra capacitor arrays 202 designed for an output power matching the input of thermoelectric chillers 33 and Nichrome coil heat elements 204. The Nichrome coil heat elements 204 are in contact, and/or in thermal communication with, the thermoelectric generator substrate (“hot side”) 194 of thermoelectric generators 1. The thermoelectric chillers 33 are in contact, and/or in thermal communication, with low temperature phase change material 72 as shown in FIG. 51, which is a vertical cross-section schematic diagram of FIG. 50. As well as FIGS. 52 and 53, which are horizontal cross-section schematic diagrams of FIG. 50, keeping the thermoelectric device at a calculated constant (or substantially constant) temperature. Referring to FIGS. 51, 52 and 53, the thermoelectric generator substrate (“cold side”) 195 of the thermoelectric generators 1 is in contact, and/or in thermal communication, with the low temperature phase change material 72. The thermoelectric generator substrate (“hot side”) 194 of thermoelectric generators 1 are in contact, and/or in thermal communication, with the Nichrome coil heat elements 204 which cause a thermal difference between both sides of the thermoelectric generators 1 which converts the thermal energy into a calculable electrical energy that is capable of powering the device of choice. During times when the electrical device is in operation, the waste heat from one or more components may be routed to the thermoelectric generator substrate (“hot side”) 194 of thermoelectric generators 1 to provide passive cooling to those components and harvest the thermal energy. During times when the electrical device is not in operation, ambient temperature and the low temperature phase change material 72 cause a calculable thermal difference between both sides of the thermoelectric generators 1 which converts the thermal energy into a calculable electrical energy that is capable of powering the thermoelectric chillers 33 for the chilling of low temperature phase change material 33. The low temperature phase change material 33 is in contact with the thermoelectric generator's 1 and thermoelectric chiller's 33 low thermoelectric generator substrate (“cold side”) 195. The other areas of the low temperature phase change material 72 are typically insulated with e.g., low temperature phase change pellet insulation 200, separated with polypropylene case walls 201. The entire power supply may be then sealed in an outer housing 197 of choice, (e.g., fiberglass, plastic and/or metal).

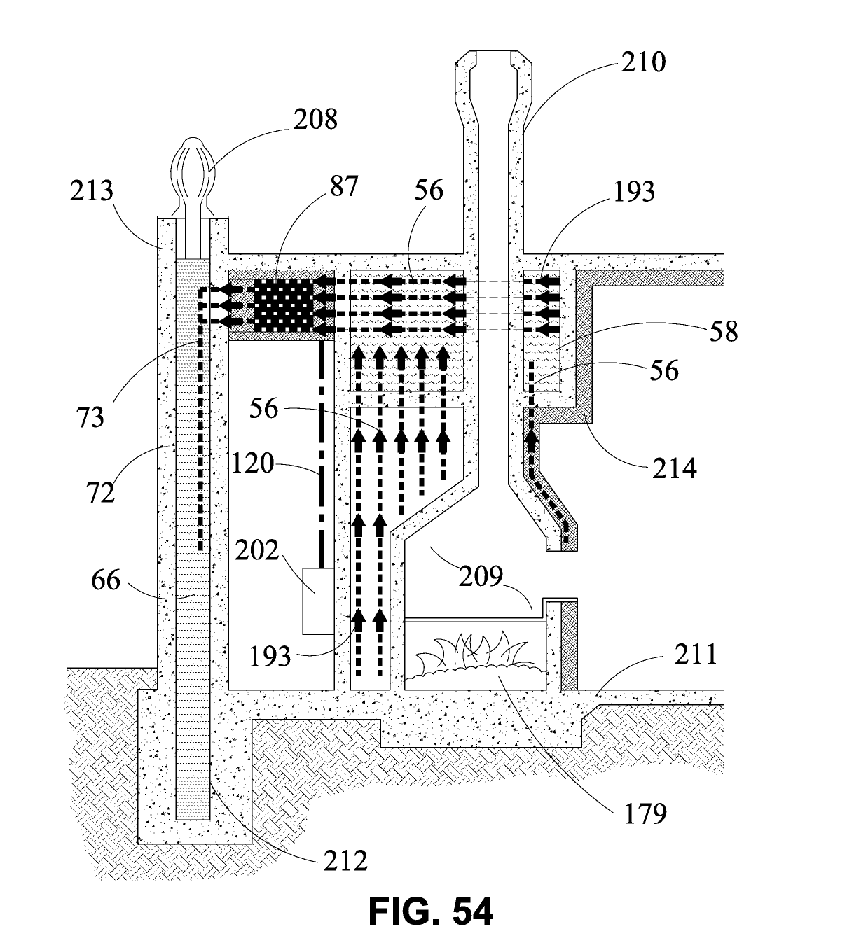

FIG. 54 is a schematic diagram of an exemplary embodiment of a thermoelectric harvesting device and generator that may be utilized in industrial facilities, that currently may use tremendous amounts of energy cooling and/or heating with little or no method of recycling and/or storing the wasted thermal energies, to capture the thermal energy, convert it to electrical energy for other uses; (e.g. for cooling in the factory). Referring to FIG. 54, heat energy from an industrial furnace 209 produced by burn fuel 179 for industrial purposes may be transferred as shown in a heat flow direction 193 via high temperature heat pipes 56 into high temperature thermal storage. The working side of the furnace may be layered with high temperature phase change insulation 214 to help prevent or reduce heat from radiating into the work-space. The heat energy continues through additional high temperature heat pipes 56 onto the hot sides of a thermoelectric generator core 87 where it passes through the thermoelectric modules in the thermoelectric generator core 87 generating electrical energy and as it passes into low temperature heat pipes being drawn away towards the mass in the low temperature thermal storage 66 of low temperature phase change material 72 stored inside a cooling stack 213 that may include a turbine ventilating cap 208 and a cooling well 212 that may be integrated into the facilities' foundation 211. The generated electrical energy may be transferred to an ultra capacitor array so as to smooth out the electrical output so it may be used when desired.

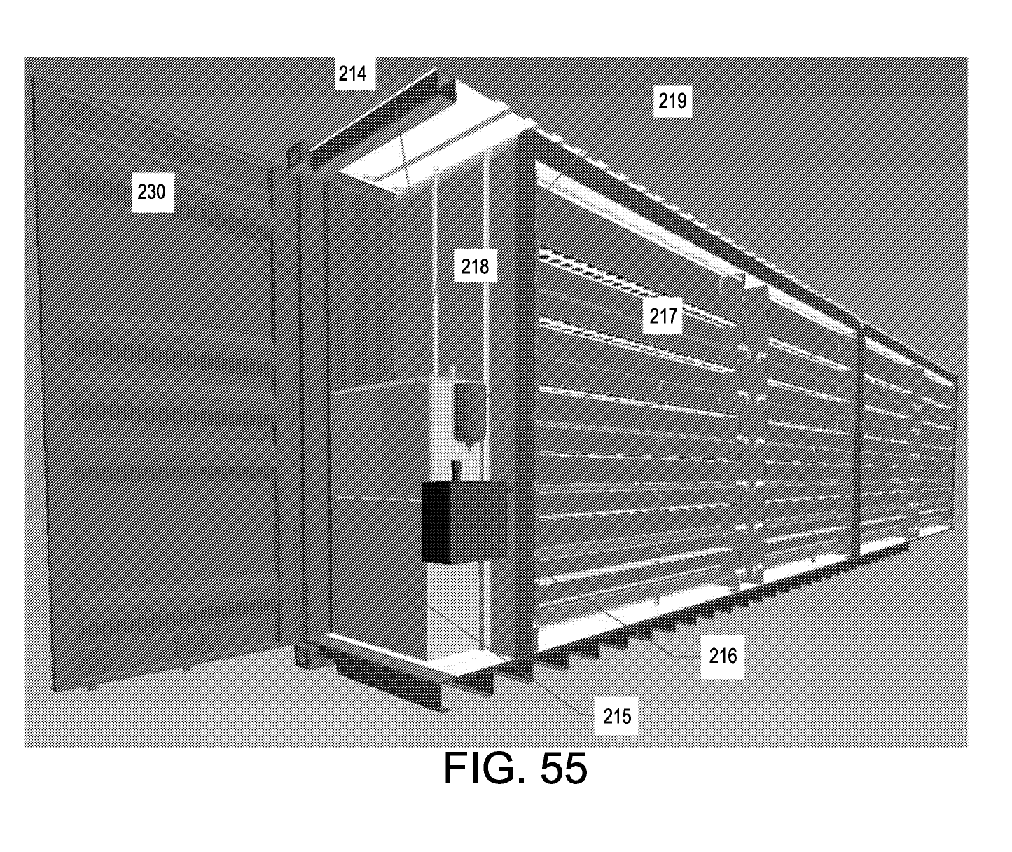

FIG. 55 is an isometric section of an exemplary embodiment of a thermoelectric generator, heater and cooler for use in urban vertical farming. Referring to FIG. 55, an exemplary embodiment of a thermoelectric generator, heater and/or cooler for use in a sealed solid-state urban vertical farm biosphere that is substantially isolated from the typical pests and environmental concerns of traditional farming. The grow chambers 219 may be housed for protection in a shipping container 230 and wrapped on the sides, or a portion of the sides, with phase change insulation 214 to insure there is no, or reduced, thermal transfer from the outside environment into the farm biosphere. Because of the three dimensional nature of the unit, a single forty foot shipping container may grow in excess of three acres of soybeans or strawberries with a possible fifteen growth cycles per year. In certain embodiments, a single forty foot shipping container may grow in excess of between 1 to 2, 2.5 to 4, 2.75 to 3.25, 3 to 5 acres of crops at least 1, 3, 5, 7, 9, 10, 12, 15, or greater growth cycles per year. The system utilizes an exemplary embodiment of a thermoelectric generator/heater/chiller 215, similar to the portable system described in FIGS. 38 and 39, without the Dyson air multiplier or the photovoltaic skirt. Instead of the Dyson air multiplier as described in FIGS. 38 and 39, to draw air through the hot or cold chambers for heating or cooling, a nitrogen and carbon dioxide gas tank pushes its compressed gas through the hot or cold chamber of the unit when the temperature needs adjusting, based upon sensors set for the specific species of the plant(s) being grown. Additionally, the farm biosphere uses aeroponic methods to deliver water and nutrients to the roots of the plants that are stored in a nutrient enriched water tank 218 and delivered through misting pipes 223 by compressed oxygen stored in an oxygen tank 217. The electrical energy generated by the thermoelectric generator/heater/chiller 215 is used to run the sensors, timers, solenoids and the highly efficient LED grow lights during the growth cycle. The thermoelectric generator/heater/chiller's 215 “hot” side and “cold” side may be regenerated by the thermal difference between the interior of the biosphere and outside ambient temperature and/or by use of other renewable energy sources that may be available at the location.

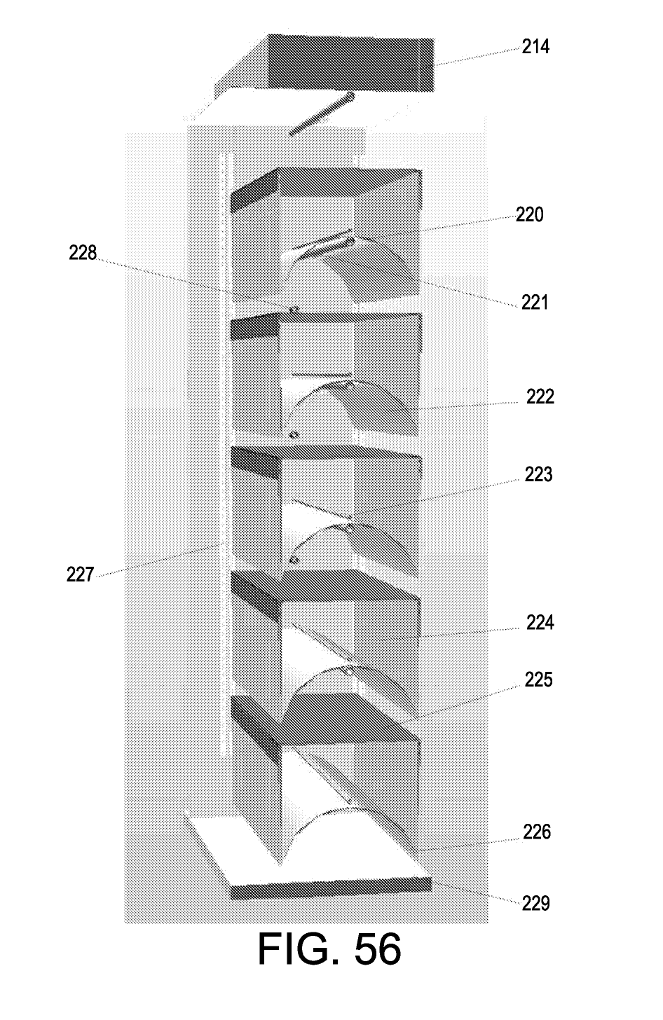

FIG. 56 is an isometric section of an exemplary embodiment of a thermoelectric generator, heater and/or cooler powered urban vertical farming grow cell. Referring to FIG. 56, the view shows five grow chambers 219, stacked by use of rack standards 227, in a grow cell that is substantially isolated from pests and/or thermal transfer by phase change insulation 214 and isolation flooring 229 that may be made of recycled plastic or other thermally non-conductive material, and also sealed with inward-facing mirrored film that was left out of the isometric section for clarity purposes. Each grow chamber has the following amenities; electrical conduit 220 to bring power to LED grow lights 221 that are designed to put out a light spectrum to similar to or substantially matching the natural lighting of the environment of the species that is being grown of where that species became a successful species; a reflective hood 222, to ensure that light from the LED grow lights 221 is directed on the plants; a misting pipe 223, with misting nozzles capable of delivering the nutrient enriched water, to the root chamber 224, in a mist, for example, of under five microns in size using less water than of a typical farm (for example, in certain applications 50%, 60%, 70%, 80%, 90%, 95%, 96%, or 98% less water than a typical outdoor farm); a drainage valley to collect the water that was not absorbed by the roots to be recycled; an atmospheric feed line 228 to deliver the heated or chilled gas from the nitrogen and carbon dioxide gas tank 216; and stabilizing fabric 225 that is stretched across the top of the root chamber 224 to hold the plants in place and to isolate the roots from the leafy portion of the plant. Using these methods an urban vertical farm may benefit from year-round crop production, in different climate zones, growing most varieties of crops at a cost reduction (for example, in certain applications a cost reduction of up to 80%, 70%, 60%, 50%, or 40%), while being more immune to weather related or other types of crop failures, due to droughts, floods, freezing and/or pests. This method may also enjoy the benefit of organic farming using no herbicides, pesticides or fertilizers and may greatly reduce the incidence of many infectious diseases or cross-contamination acquired at the agricultural interface.

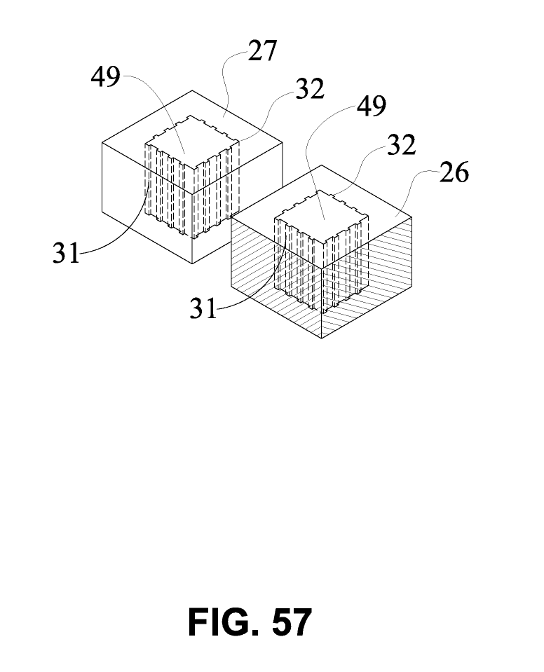

FIG. 57 is an isometric view of an exemplary embodiment of a thermoelectric device that may be utilized in certain thermoelectric energy generation systems. In this exemplary embodiment, a more efficient thermoelectric device may be used instead of a generic off-the-shelf device. FIG. 57 is similar to FIGS. 14-20 except that the evacuated chambers or voids 31 are filled with a thermally non-conductive material 49 instead of the working fluid 23 that is described in the aforementioned figures and also as described herein. Additionally, the areas around each post may also be filled with thermally non-conductive material 49. For example, the material may be a foam polymer, polystyrene, silica aerogel and/or argon gas. When the vacuum seal foils 22 are vacuum-sealed, or substantially vacuum-sealed, onto the two outermost thermally conductive thermoplastic elastomer electrical insulating skins 24 that may have cutouts to substantially match chambers or voids 31 is attached, using thermally conductive but electrically insulating epoxy, electrical conductor layer 25 and electrical input/output (I/O) layer 28 which may be slightly smaller than the voided areas 31 that have wicking grooves 32, which are now sufficiently filled, or substantially filled, with a thermally non-conductive material 49 and are now adding more surface area, in semiconductor posts 26, 27 that are attached to, using thermal and electrically conductive epoxy, the electrical conductor layers 25 and electrical input/output layers 28. By way of effectively blocking heat, or reducing heat, through the center and around the outside of the semiconductor posts various benefits may be realized. For example, in certain embodiments, less mass in the posts leads to less thermal resistivity which adds efficiency; holes in the posts add surface area allowing more electrons to flow; and/or forcing the heat to mainly pass only through the semiconductor material may have an increase in voltage. For example, if a hole is placed in each post reducing its thermal resistance by 30%, expanding the surface area to allow more electron flow of 40% and forcing most of the thermal energy through the semiconductor material increasing voltage by 5%, doing so may increase efficiency of the thermoelectric module up to, for example, 91%. In certain embodiments, the efficiency of the thermoelectric module may be at least 60%, 75%, 85%, 90%, or 91%. In certain embodiments, the efficiency of the thermoelectric module may be between 50% to 95%, 60% to 90%, 70% to 85%, 75% to 90%, 88% to 94% or 85% to 91%.

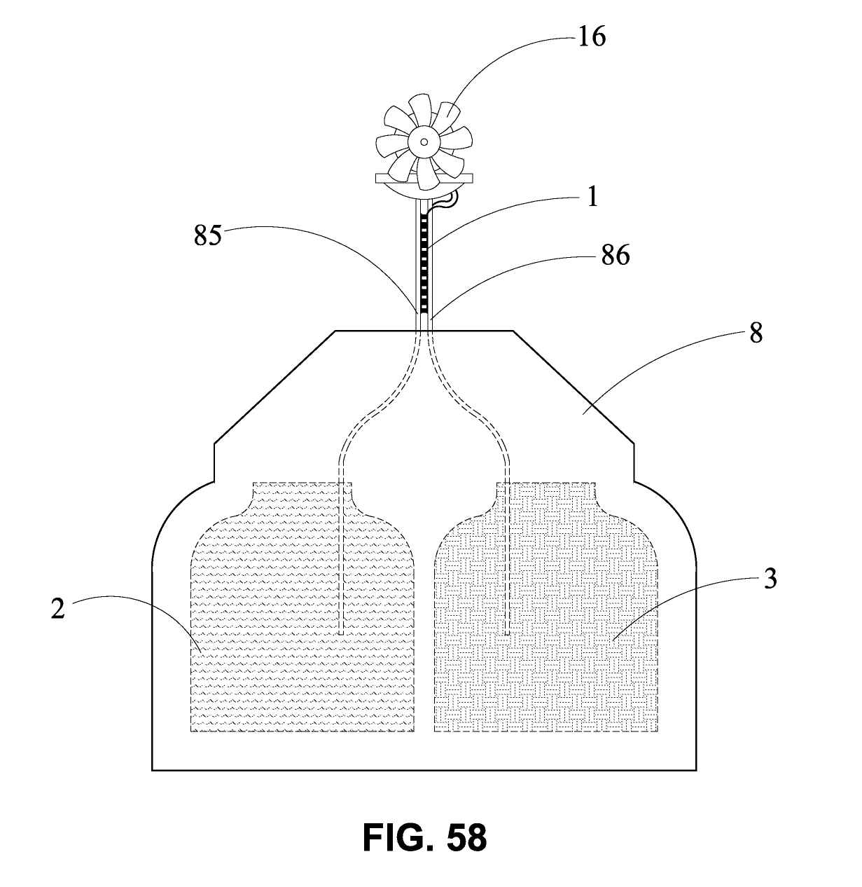

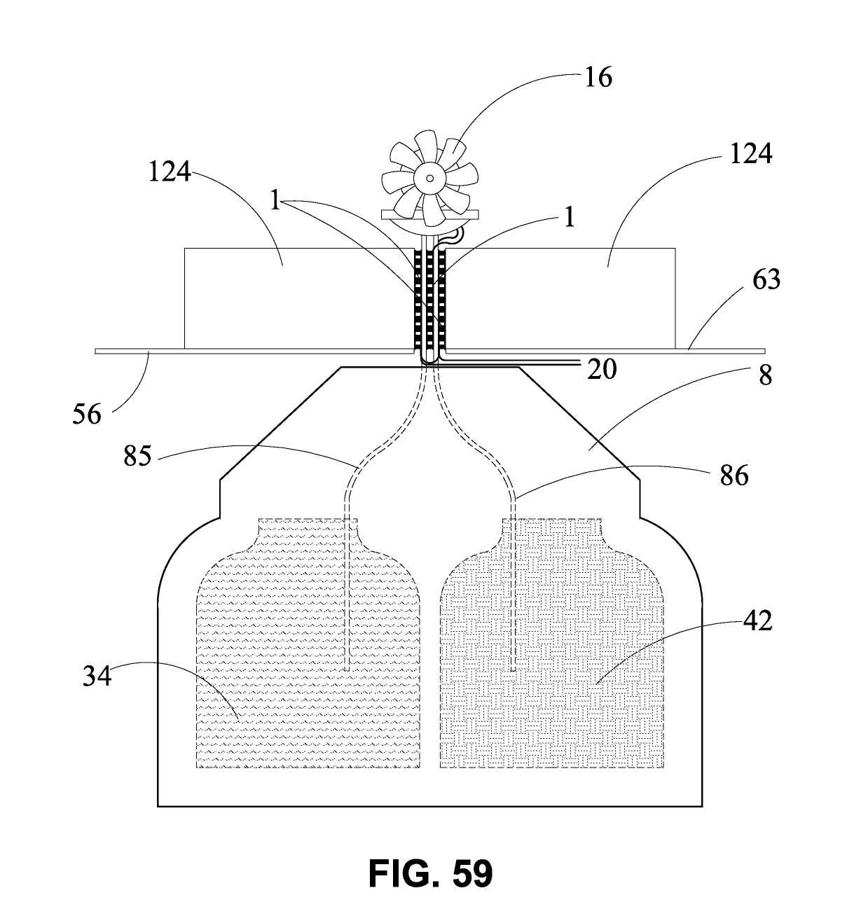

FIG. 58 is a schematic diagram of an apparatus built to test the thermoelectric energy generation using water and chemical based phase change materials. Two eight ounce containers, one filled with a high temperature phase change material 34 (boiling water at 100° C.) and the other filled with a low temperature phase change material 42 (liquid alcohol at −15° C.) were wrapped with a two inch thick insulating barrier 8 of foam insulation after a high temperature heat plate 85 was partially inserted in the high temperature phase change material 34 and a low temperature heat plate 86 was partially inserted in the low temperature phase change material 42. The heat plates 85 and 86 were formed in a way that they were capable of sandwiching a thermoelectric generator 1 that was electrically connected to power a fan 16. The fan was capable of running at a low power level of 0.5 Watts. The test commenced with the thermoelectric generator 1 receiving a thermal difference of 115° C. and when turned on ran continuously, but slowing down as the temperature between the two phase change materials 34 and 42 stabilized, finally stopping after a total duration of twenty three minutes. FIG. 59 is a schematic diagram of the same apparatus built for FIG. 58. However, it was modified to test the thermoelectric energy generation using organic phase change materials. Two eight ounce containers, one filled with a high temperature phase change material 34 (OPCM 55° C.) and the other filled with a low temperature phase change material 42 (OPCM −15° C.) were wrapped with a two inch thick insulating barrier 8 of foam insulation after a high temperature heat plate 85 was partially inserted in the high temperature phase change material 34 and a low temperature heat plate 86 was partially inserted in the low temperature phase change material 42. The heat plates 85 and 86 were formed in a way that they were capable of sandwiching a thermoelectric generator 1 that was electrically connected to power a fan 16. The fan was capable of running at a low power level of 0.5 Watts. Additional burdens were added to this test, the first was the addition of two additional thermoelectric generators 1 attached the outside of the heat plates 85 and 86 electrically connected in series and hooked up to a multimeter to test voltage output. Large aluminum heat sinks 124 were connected to the outside of each thermoelectric generator 1 to draw or reject heat energy through these additional thermoelectric generators 1. Finally, a high temperature heat pipe 56 was added to the heat sink 124 on the high temperature side and a low temperature heat pipe 63 was added to the heat sink 124 on the low temperature side. This was done to increase the rate at which the two containers would equalize in temperature due to some preliminary testing that showed the organic phase change materials resistance to thermal change as being strong. The test commenced with the thermoelectric generator 1 receiving a thermal difference of 70° C. and when turned on ran continuously, but slowing down as the temperature between the two phase change materials 34 and 42 stabilized, finally stopping after a total duration of five hours and forty five minutes. Additionally, the two added thermoelectric generators 1, connected in series and connected to the multimeter, had an output voltage of over two volts that decreased slowly over the course of the five hours and forty-five minutes. Test conclusion: With the lower thermal difference (45° C. less), the added load of two additional thermoelectric generators and an increase in equalization efficiency by the added heat sinks and heat pipes, the organic phase change material outperformed the water and chemical based phase change material by about fifteen fold. The amount of energy spent to bring each phase change material to their start of test temperature was carefully watched to be equal, which is the reason for the high temperature organic phase change material beginning the test at the temperature of 55° C. instead of beginning the test at the temperature of 100° C. as the water did.

In exemplary embodiments, another application for the technology may be to inject Nano-radios and transmitters made from single and/or multi-walled carbon nanotubes filled with phase change material of a slightly lower temperature than the human body, a Nano-scale thermoelectric device set in between the phase change material and the body so as to generate very small but needed electrical energy for medical applications (e.g., medicine delivery at cell level, growth disruptors for cancer cells, embedded micro-system analyzers and transmitters).

In exemplary embodiments, the device may be used in mobile devices (cell phones, computers, displays, etc.) to harvest heat as well as ambient temperature and may also harvest ambient electromagnetic radiation and vibrations to store as opposing thermal energies using phase change materials and then converting through the thermoelectric methods described it the embodiments.

In exemplary embodiments, the device may also be used in mobile devices (cell phones, computers, displays, etc.) using the harvested heat as well as ambient temperature and may also harvest ambient electromagnetic radiation and vibrations to store as opposing thermal energies using phase change materials and then converting through the thermoelectric methods to chill the electronics for longer life and better efficiencies as described in exemplary embodiments.

In exemplary embodiments, the device could be used in electric toys to power them and using the harvested heat as well as ambient temperature and may also harvest ambient electromagnetic radiation and vibrations to store as opposing thermal energies using phase change materials and then converting through the thermoelectric methods described it exemplary embodiments.

In exemplary embodiments, the device may be used to power hand tools (e.g., drills, routers, saws, or other typical battery or mains operated devices). The harvested heat as well as ambient temperature also may harvest ambient electromagnetic radiation and vibrations to store as opposing thermal energies using phase change materials and then converting through the thermoelectric methods described in the embodiments and/or to chill the electronics for longer life and better efficiencies as described in the embodiments.

In exemplary embodiments, the device could be used for emergency, security and surveillance systems that may benefit from not having to be hard wired or need batteries.

In exemplary embodiments, the device could be used for health care applications such as pacemakers, hearing aids, insulin injection apparatuses as well as monitoring and ambulatory equipment that may benefit from having a constant source of electrical energy.

In exemplary embodiments, the device could be used for appliances (refrigeration, heating, cleaning) to power the device and provide the necessary temperatures needed to complete the task the appliance was designed for and achieved by the methods explained in the exemplary embodiments.

In exemplary embodiments, vehicles (e.g., automobiles, aircraft, ships, boats, trains, satellites, deployment vehicles, motorcycles and other powered methods of transportation), could use the methods/devices to power the vehicle and/or its ancillary systems for long to unlimited range without the need to stop for refueling. It may be of even further benefit to the transportation industry to use the body or skin as the thermoelectric transfer point since vehicles such as ships and aircraft typically travel through colder atmospheres.

In buildings whether residential, commercial or industrial this conversion method and device would allow for immediate off-grid use and also provide the heating and cooling of the occupants and water needs by the harvest of wasted energies, conversion to thermal energy and stored as thermal energy and then used on demand when converted into electrical energy.

In exemplary embodiments, technology and/or computing centers are typically high-energy users, using the methods in the embodiments would allow for immediate off-grid use and also provide the cooling of the center's equipment.

In exemplary embodiments, lighting could be wireless if a small generator, using the harvesting, storage and conversion methods in the embodiments, was attached to individual or circuits of fixtures.

In exemplary embodiments, urban farming may be realized using this conversion method and would allow for immediate off-grid use and also provide the heating and cooling of the agriculture air-conditioning and water needs by the harvest of wasted energies, conversion to thermal energy and stored as thermal energy and then used on-demand when converted into electrical energy.

Water can be easily harvested in dry climates when there is a low cost, clean energy solution that allows high volume intake of air and compresses it into condensation chambers to extract the moisture. While the extraction method is capable of being done now, today's energy costs are too high to make it viable.

In exemplary embodiments, the device may be utilized, in industrial facilities that currently use tremendous amounts of energy cooling and heating with no method of recycling the wasted thermal energies, to store that energy and move it electrically in the factory.

In exemplary embodiments, oceanic landmass building can be achieved by running current through wire frames, lowered into the ocean, attracting the skeletal remains of sea creatures. The remains attach and accumulate around the wire frame forming limestone. While this method can be currently achieved, today's energy costs are too high to make it viable.

In the exemplary embodiment described herein, the following reference numerals have the identified label/structure/operation:

1. Thermoelectric generator

2. High temperature storage

3. Low temperature storage

4. High temperature regenerator

5. Heater

6. Low temperature regenerator

7. Chiller

8. Insulating barrier

9. High side ambient temperature

10. Heat exchanger

11. Low temperature inlet

12. High temperature inlet

13. High temperature outlet

14. Low temperature outlet

15. Plenum or tank

16. Pump or fan

17. Low side ambient temperature

18. High temperature return

19. Low temperature return

20. Direct current

21. Capacitor array

22. Vacuum seal foils

23. Working fluid

24. Thermally conductive thermoplastic elastomer insulating skins

25. Electrical conductor layer

26. Semiconductor posts (negative)

27. Semiconductor posts (positive)

28. Electrical input/output layers

29. Positive electrical conductor I/O tab

30. Negative electrical conductor I/O tab

31. Voided areas

32. Wicking grooves

33. Insulating casket

34. High temperature phase change material

35. High temperature input thermally conductive heat pipe casing

36. Heat pipe working fluid

37. Sintered layer

38. High temperature output thermally conductive heat pipe casing

39. Thermoelectric generator stack

40. Low temperature output thermally conductive heat pipe casing

41. Low temperature input thermally conductive heat pipe casing

42. Low temperature phase change material

43. Thermoelectric heater module stacks

44. Positive polarity input electrical flow from harvest sources

45. Thermoelectric chiller module stacks

46. Negative polarity input electrical flow from harvest source

47. Positive polarity output electrical flow from harvest source

48. Heat source

49. Thermally non-conductive material

50. Cold temperature source

51. Photovoltaic direct current electric energy

52. Piezoelectric direct current electrical energy

53. Electromagnetic electrical energy

54. Thermoelectric heater

55. Working fluid vapor

56. High temperature heat pipe

57. Flow path

58. High temperature thermal storage

59. Condensed working fluid return

60. High temperature transfer

61. Thermoelectric chiller

62. Chilled working fluid

63. Low temperature heat pipe

64. Outer heat pipe walls

65. Warmed working fluid

66. Low temperature thermal storage

67. Low temperature transfer

68. Thermoelectric generator modules

69. Direct current output

70. Reinforced concrete outer wall

71. Interior liner

72. Low temperature phase change material

73. Heat pipes with low temperature working fluid

74. Low temperature thermoelectric generator module stacks

75. Outer seal plug

76. Helium (He) Gas

77. Liquid to vapor thermoelectric ring

78. High temperature thermoelectric ring

79. Alternating posts of SiC:Se and SiC:Sb

80. High temperature working fluid

81. Titanium seal plug

82. Primary SiC absorption wall

83. Carbon Dioxide working fluid

84. Spent nuclear fuel rods

85. High temperature heat plates

86. Low temperature heat plates

87. Thermoelectric generator core

88. Coil heater

89. Thermally conductive strap

90. Thermoelectric chiller modules

91. Conductive connection mount

92. Thermally insulated outer casing

93. Voltage/current pin-out board

94. Parabolic trough

95. Reflective surface

96. Glass panel

97. Sun's radiation

98. Oil filled pipe

99. Convection loop

100. Reservoir of organic phase change material

101. Cold waterline

102. Water storage tank

103. Heat loop inlet

104. Water pump

105. Waterline loop

106. Heat loop outlet

107. Hot water supply line

108. Insulated transfer pipes

109. Secondary reservoir of organic phase change material

110. Thermostat or control switch

111. Blower

112. Air

113. Filtered return air grill

114. Heat ducts

115. Insulated plenum

116. Conditioned area

117. Photovoltaic panels

118. Tertiary reservoir of organic phase change material

119. Chilling ducts

120. Electrical wiring

121. DC electrical sub-panel

122. Thermoelectric heater

123. Water

124. Heat sink

125. Blower chamber

126. Damper chamber

127. Control box

128. Support base

129. Reservoir stabilizing harness

130. Damper

131. Damper switching axle

132. Secondary reservoir of organic phase change material knockout

133. Tertiary reservoir of organic phase change material knockout

134. Dyson air-multiplier

135. Removable chill reservoir

136. Removable heat reservoir

137. Photovoltaic skirt

138. Wiring chases

139. Base

140. Base plug

141. Insulated Door

142. Door handle

143. Adjustable foot

144. Door panel frame

145. Refrigerator chamber

146. Freezer chamber

147. Shelve and bin rack

148. Sun

149. Thermally conductive skin

150. Thermally conductive foam

151. Breaking disc

152. Duct walls and vent plates

153. Heat pipe plates

154. Chassis

155. Harvest from outside skin

156. Harvest from breaking

157. Harvest from waste comfort heat

158. Harvest from waste comfort chilling

159. Harvest from breaking impulse energy

160. Heat rejection direction

161. Clouds or other shading device

162. Vessel interior ambient temperature

163. Outside vessel ambient temperature

164. Thermoelectric generating shell

165. Electrolysis terminals

166. Anode

167. Cathode

168. Water solution

169. Float valve

170. Water inlet

171. Air or compound inlet

172. Electrolysis Chamber

173. Common inlet

174. Hydrogen

175. Oxygen

176. Gas tank

177. Regulator

178. Mixing chamber

179. Burn fuel

180. Oven or fireplace valve

181. Oven or fireplace burner

182. Glow plug

183. Control switch

184. Thermally conductive membrane

185. Thermal Chamber

186. Filler cap

187. Organic phase change material

188. Xeon gas

189. Krypton gas

190. Argon gas

191. Nitrogen gas

192. Chill plate

193. Heat flow direction

194. Thermoelectric generator substrate (hot side)

195. Thermoelectric generator substrate (cold side)

196. Thermally conductive vertical path channels

197. Outer housing

198. DC positive lead

199. DC negative lead

200. Low temperature phase change pellet insulation

201. Polypropylene case walls

202. Ultra capacitor array

203. Bimetallic strip switch

204. Nichrome coil heat element

205. Enameled wire coil around cylindrical ferrite core

206. Rectifying circuit

207. Piezoelectric material

208. Turbine ventilator cap

209. Furnace

210. Chimney stack

211. Foundation

212. Cooling well

213. Cooling stack

214. Phase change insulation

215. Thermoelectric generator/heater/chiller

216. Nitrogen and carbon dioxide gas tank

217. Oxygen tank

218. Nutrient enriched water tank

219. Grow chamber

220. Electrical conduit

221. LED grow lights

222. Reflective hood

223. Misting pipe

224. Root chamber

225. Stabilizing fabric

226. Drainage valley

227. Rack standard

228. Atmospheric feed line

229. Isolation flooring

230. Shipping container

### EXAMPLES

### Example 1A

A system for converting thermal energy into electrical energy, the system comprising: a thermoelectric generator; a higher temperature storage in thermal contact with a first side of the thermoelectric generator; a lower temperature storage in thermal contact with a second side of the thermoelectric generator; a higher temperature regenerator for maintaining at least in part the high temperature storage at a higher temperature; a lower temperature regenerator for maintaining at least in part the low temperature storage at a low temperature; and wherein, the difference in the temperatures of the higher temperature storage and the lower temperature storage creates a thermal difference between the two sides of the thermoelectric generator, which creates the electrical energy.

2A. The system of example 1A wherein the higher temperature storage and lower temperature storage are phase change materials.

3A. The system of any of the preceding examples wherein the electrical energy is DC current.

4A. The system of any preceding examples wherein the thermally stored energy is used to heat or cool another application e.g., water heating, air conditioning.

5A. The system of any of the preceding examples wherein the higher temperature regenerator comprises:

a thermoelectric generator that uses the higher temperature storage on one side and an ambient temperature on the other side to create a temperature difference across the thermoelectric generator; wherein, the thermal difference across the thermoelectric generator generates electrical energy.

6A. The system of example 5A wherein the electrical energy of the higher temperature regenerator is used to power a heater to keep the high temperature storage at a high temperature.

7A. The system of any of the preceding examples wherein the lower temperature regenerator comprises: a thermoelectric generator that uses the lower temperature storage on one side and an ambient temperature on the other side to create a temperature difference across the thermoelectric generator; wherein, the thermal difference across the thermoelectric generator generates electrical energy.

8A. The system of example 6A wherein the electrical energy of the lower temperature regenerator is used to power a chiller to keep the lower temperature storage at a low temperature.

### Example 1B

A system comprising: at least one thermoelectric generator; a first temperature storage material in thermal communication with a first portion of the at least one thermoelectric generator; a second temperature storage material in thermal communication with a second portion of the at least one thermoelectric generator; at least one first temperature regenerator for maintaining at least in part the first temperature storage material at a first temperature range; at least one second temperature regenerator for maintaining at least in part the second temperature storage material at a second temperature range; wherein the first temperature is higher than the second temperature and the difference in the temperature of the first temperature storage material and the second temperature storage material creates a thermal difference between the two portions of the at least one thermoelectric generator which creates an electrical output; and wherein a portion of the electrical output is used to power at least in part the at least one first temperature regenerator, the at least one second temperature regenerator, or both.

2B. The system of example 1 wherein the first portion of the at least one thermoelectric generator is a first side of the generator.

3B. The systems of examples 1B or 2B wherein the second portion of the at least one thermoelectric generator is a second side of the generator.

4B. The systems of examples 1B, 2B or 3B wherein the system is a thermoelectric module that may be vertically stacked.

5B The system of example 5B wherein the stack comprises at least 1, 2, 3, 4, 5, 6, 7, 8, 10, 15, 20, 30, 40, or 100 of the thermoelectric modules.

6B. The systems of one or more of the proceeding examples wherein the system is able to operate in a self sustaining manner between 30% to 50%, 30% to 95%, 50% to 100%, 80% to 98%, 90% to 99.5%, 80% to 100% of the desired operating period.

7B The systems of one or more of the proceeding examples wherein the system provides sufficient electricity between 30% to 50%, 50% to 70%, 30% to 95%, 50% to 100%, 80% to 98%, 95% to 100%, or 80% to 100% of the time that the system is in operation.

8B The systems of one or more of the proceeding examples wherein the system that provides sufficient electricity, heating and/or cooling between 30% to 50%, 40% to 60%, 50% to 70%, 30% to 95%, 50% to 100%, 70% to 95%, 80% to 98%, 90% to 99.5%, 95% to 100%, or 80% to 100% of the time that the system is in operation.

9B. The systems of one or more of the proceeding examples wherein at least one of the first temperature storage material and the second temperature storage material is in thermal communication with the at least one thermoelectric generator by the use of at least one heat pipe or heat conduit.

10B. The systems of one or more of the proceeding examples wherein at least one of the first temperature storage material is in thermal communication with the surface of the first side of the at least one thermoelectric generator by the use of at least one heat pipe or heat conduit.

11B. The systems of one or more of the proceeding examples wherein at least one of the second temperature storage material is in thermal communication with the surface of the second side of the at least one thermoelectric generator by the use of at least one heat pipe or heat conduit.

12B. The systems of one or more of the proceeding examples wherein the at least one of the first temperature storage material and the second temperature storage material are partially or substantially thermally insulated from each other and/or the at least one thermoelectric generator and are still in thermal communication with the at least one thermoelectric generator by the use of at least one heat pipe or heat conduit.

13B. The systems of one or more of the proceeding examples wherein the thermally stored energy is used to heat or cool another application, (e.g., water heating, water cooling, comfort heating, comfort cooling, air conditioning or combinations thereof).

14B. The systems of one or more of the proceeding examples wherein one or more of the first temperature storage material and the second temperature storage material are selected from one or more of the following: air, ambient air, gas, solids such a cement, water, water based salt hydrates, various forms of paraffins, fatty acids and esters, trimethylolethane, organic thermal salts, inorganic thermal salts, ionic liquids, thermal composites, vegetable-based fats or oils.

15B. The systems of one or more of the proceeding examples wherein one or more of the first temperature storage material and the second temperature storage material are selected from vegetable-based fats or oils.

### Example 1C

A system comprising: at least one thermoelectric generator; a first temperature storage material in thermal communication with a first portion of the at least one thermoelectric generator; a second temperature storage material in thermal communication with a second portion of the at least one thermoelectric generator; at least one temperature regenerator for maintaining at least in part the first temperature storage material at a first temperature range or for maintaining at least in part the second temperature storage material at a second temperature range; wherein the first temperature is higher than the second temperature and the difference in the temperature of the first temperature storage material and the second temperature storage material creates a thermal difference between the two portions of the at least one thermoelectric generator which creates an electrical output; and wherein a portion of the electrical output is used to power at least in part the at least one temperature regenerator.

2C. The system of example 1C wherein the first portion of the at least one thermoelectric generator is a first side of the generator.

3C. The systems of examples 1C or 2C wherein the second portion of the at least one thermoelectric generator is a side of the generator.

4C. The systems of examples 1C, 2C, or 3C wherein the system is a thermoelectric module that may be vertically stacked.

5C. The system of example 4C wherein the stack comprises at least 1, 2, 3, 4, 5, 6, 7, 8, 10, 15, 20, 30, 40, or 100 of the thermoelectric modules.

6C. The systems of one or more of the proceeding examples wherein the system is able to operate in a self-sustaining manner between 30% to 50%, 30% to 95%, 50% to 100%, 80% to 98%, 90% to 99.5%, 80% to 100% of the desired operating period.

7C. The systems of one or more of the proceeding examples wherein the system provides sufficient electricity between 30% to 50%, 50% to 70%, 30% to 95%, 50% to 100%, 80% to 98%, 95% to 100%, or 80% to 100% of the time that the system is in operation.

8C. The systems of one or more of the proceeding examples wherein the system that provides sufficient electricity, heating and/or cooling between 30% to 50%, 40% to 60%, 50% to 70%, 30% to 95%, 50% to 100%, 70% to 95%, 80% to 98%, 90% to 99.5%, 95% to 100%, or 80% to 100% of the time that the system is in operation.

9C. The systems of one or more of the proceeding examples wherein at least one of the first temperature storage material and the second temperature storage material is in thermal communication with the at least one thermoelectric generator by the use of at least one heat pipe or heat conduit.

10C. The systems of one or more of the proceeding examples wherein at least one of the first temperature storage material is in thermal communication with the surface of the first side of the at least one thermoelectric generator by the use of at least one heat pipe or heat conduit.

11C. The systems of one or more of the proceeding examples wherein at least one of the second temperature storage material is in thermal communication with the surface of the second side of the at least one thermoelectric generator by the use of at least one heat pipe or heat conduit.

12C. The systems of one or more of the proceeding examples wherein the at least one of the first temperature storage material and the second temperature storage material are partially or substantially thermally insulated from each other and/or the at least one thermoelectric generator and are still in thermal communication with the at least one thermoelectric generator by the use of at least one heat pipe or heat conduit.

13C. The systems of one or more of the proceeding examples wherein the thermally stored energy is used to heat or cool another application, (e.g., water heating, water cooling, comfort heating, comfort cooling, air conditioning or combinations thereof).

14C. The systems of one or more of the proceeding examples wherein one or more of the first temperature storage material and the second temperature storage material are selected from one or more of the following: air, ambient air, gas, solids such a cement, water, water based salt hydrates, various forms of paraffins, fatty acids and esters, trimethylolethane, organic thermal salts, inorganic thermal salts, ionic liquids, thermal composites, vegetable-based fats or oils.

15C. The systems of one or more of the proceeding examples wherein one or more of the first temperature storage material and the second temperature storage material are selected from vegetable-based fats or oils.

### Example 1D

A system comprising: a) at least a first thermoelectric generator; a first temperature storage material in thermal communication with a first side of the at least first thermoelectric generator; a second temperature storage material in thermal communication with a second side of the at least first thermoelectric generator; b) at least a second thermoelectric generator; the first temperature storage material in thermal communication with a first side of the at least second thermoelectric generator; and a third temperature storage material in thermal communication with a second side of the at least second thermoelectric generator; c) at least a third thermoelectric generator; a fourth temperature storage material in thermal communication with a first side of the at least third thermoelectric generator; a third temperature storage material in thermal communication with a second side of the at least third thermoelectric generator; at least one first temperature regenerator for maintaining at least in part the first temperature storage material at a first temperature range; and at least one second temperature regenerator for maintaining at least in part the second temperature storage material at a second temperature range; wherein the first temperature is higher than the second temperature and the difference in the temperatures of the first temperature storage material and the second temperature storage material creates a thermal difference between the two sides of the at least one thermoelectric generator which creates an electrical output; wherein the first temperature is higher than the third temperature and the difference in the temperatures of the first temperature storage material and the third temperature storage material creates a thermal difference between the two sides of the at least second thermoelectric generator which creates an electrical output; wherein the fourth temperature is higher than the third temperature and the difference in the temperatures of the fourth temperature storage material and the third temperature storage material creates a thermal difference between the two sides of the at least third thermoelectric generator which creates an electrical output; and wherein a portion of the electrical output from the at least first, second and/or third thermoelectric generators is used to power at least in part the at least one first temperature regenerator, the at least one second temperature regenerator, or both.

### Example 2D

A system comprising: a) at least a first thermoelectric generator; a first temperature storage material in thermal communication with a first side of the at least first thermoelectric generator; a second temperature storage material in thermal communication with a second side of the at least first thermoelectric generator; b) at least a second thermoelectric generator; the first temperature storage material in thermal communication with a first side of the at least second thermoelectric generator; and a third temperature storage material in thermal communication with a second side of the at least second thermoelectric generator; c) at least a third thermoelectric generator; a fourth temperature storage material in thermal communication with a first side of the at least third thermoelectric generator; and a third temperature storage material in thermal communication with a second side of the at least third thermoelectric generator; at least one temperature regenerator for maintaining at least in part the first temperature storage material at a first temperature range or for maintaining at least in part the third temperature storage material at a third temperature range; wherein the first temperature is higher than the second temperature and the difference in the temperatures of the first temperature storage material and the second temperature storage material creates a thermal difference between the two sides of the at least one thermoelectric generator which creates an electrical output; wherein the first temperature is higher than the third temperature and the difference in the temperatures of the first temperature storage material and the third temperature storage material creates a thermal difference between the two sides of the at least second thermoelectric generator which creates an electrical output; wherein the fourth temperature is higher than the third temperature and the difference in the temperatures of the fourth temperature storage material and the third temperature storage material creates a thermal difference between the two sides of the at least third thermoelectric generator which creates an electrical output; and wherein a portion of the electrical output from the at least first, second and/or third thermoelectric generators is used to power at least in part the at least one temperature regenerator.

### Example 1E

method that uses one or more of the systems of the proceeding A, B, C, or D examples.

2E. A method for generating electricity that uses one or more of the systems of the proceeding A, B, C, or D examples.

3E. A method for generating one or more of the following: electricity, water heating, water cooling, comfort heating, comfort cooling, air conditioning or combinations thereof that uses one or more of the systems of the proceeding A, B, C or D examples.

1F. A device comprising: at least one thermoelectric generator; a first temperature storage material in thermal communication with a first portion of the at least one thermoelectric generator; a second temperature storage material in thermal communication with a second portion of the at least one thermoelectric generator; at least one first temperature regenerator for maintaining at least in part the first temperature storage material at a first temperature range and at least one second temperature regenerator for maintaining at least in part the second temperature storage material at a second temperature range; and wherein the first temperature is higher than the second temperature and the difference in the temperature of the first temperature storage material and the second temperature storage material creates a thermal difference between the two portions of the at least one thermoelectric generator which creates an electrical output; wherein a portion of the electrical output is used to power at least in part the at least one first temperature regenerator, the at least one second temperature regenerator, or both.

2F. The device of example 1F wherein the first portion of the at least one thermoelectric generator is a first side of the generator.

3F. The device of examples 1F or 2F wherein the second portion of the at least one thermoelectric generator is a second side of the generator.

4F. The device of examples 1F, 2F, or 3F wherein the device is a thermoelectric module that may be vertically stacked.

5F. The device of example 4F wherein the stack comprises at least 1, 2, 3, 4, 5, 6, 7, 8, 10, 15, 20, 30, 40, or 100 of the thermoelectric modules.

6F. The device one or more of the proceeding examples wherein the device is able to operate in a self sustaining manner between 30% to 50%, 30% to 95%, 50% to 100%, 80% to 98%, 90% to 99.5%, 80% to 100% of the desired operating period.

7F. The device of one or more of the proceeding examples wherein the device provides sufficient electricity between 30% to 50%, 50% to 70%, 30% to 95%, 50% to 100%, 80% to 98%, 95% to 100%, or 80% to 100% of the time that the device is in operation.

8F. The device of one or more of the proceeding examples wherein the device provides sufficient electricity, heating and/or cooling between 30% to 50%, 40% to 60%, 50% to 70%, 30% to 95%, 50% to 100%, 70% to 95%, 80% to 98%, 90% to 99.5%, 95% to 100%, or 80% to 100% of the time that the device is in operation.

9F. The device of one or more of the proceeding examples wherein at least one of the first temperature storage material and the second temperature storage material is in thermal communication with the at least one thermoelectric generator by the use of at least one heat pipe or heat conduit.

10F. The device of one or more of the proceeding examples wherein at least one of the first temperature storage material is in thermal communication with the surface of the first side of the at least one thermoelectric generator by the use of at least one heat pipe or heat conduit.

11F. The device of one or more of the proceeding examples wherein at least one of the second temperature storage material is in thermal communication with the surface of the second side of the at least one thermoelectric generator by the use of at least one heat pipe or heat conduit.

12F. The device of one or more of the proceeding examples wherein the at least one of the first temperature storage material and the second temperature storage material are partially or substantially thermally insulated from each other and/or the at least one thermoelectric generator and are still in thermal communication with the at least one thermoelectric generator by the use of at least one heat pipe or heat conduit.

13F. The device of one or more of the proceeding examples wherein one or more of the first temperature storage material and the second temperature storage material are selected from one or more of the following: air, ambient air, gas, solids such a cement, water, water based salt hydrates, various forms of paraffins, fatty acids and esters, trimethylolethane, organic thermal salts, inorganic thermal salts, ionic liquids, thermal composites, vegetable-based fats or oils.

14F. The device of one or more of the proceeding examples wherein one or more of the first temperature storage material and the second temperature storage material are selected from vegetable-based fats or oils.

In the description of exemplary embodiments of this disclosure, various features are sometimes grouped together in a single embodiment, figure or description thereof for the purpose of streamlining the disclosure and aiding in the understanding of one or more of the various disclosed aspects. This method of disclosure, however, is not to be interpreted as reflecting an intention that the claimed inventions requires more features than are expressly recited in each claim. Rather, as the following claims reflect, inventive aspects may lie in less than all features of a single foregoing disclosed embodiment. Thus, the claims following the Detailed Description are hereby expressly incorporated into this Description, with each claim standing on its own as a separate embodiment of this disclosure.

Furthermore, while some embodiments described herein include some but not other features included in other embodiments, combinations of features of different embodiments are meant to be within the scope of the disclosure, and form different embodiments, as would be understood by those in the art.

Although the present disclosure makes particular reference to exemplary embodiments thereof, variations and modifications can be effected within the spirit and scope of the following claims.

What is claimed is:

1. A system comprising:
at least one thermoelectric generator;
a first temperature storage material in thermal communication with a first portion of the at least one thermoelectric generator;
a second temperature storage material in thermal communication with a second portion of the at least one thermoelectric generator;
at least one first temperature regenerator for maintaining at least in part the first temperature storage material at a first temperature range;
at least one second temperature regenerator for maintaining at least in part the second temperature storage material at a second temperature range;
wherein the first temperature is higher than the second temperature and the difference in the temperature of the first temperature storage material and the second temperature storage material creates a thermal difference between the two portions of the at least one thermoelectric generator which creates an electrical output; and
wherein a portion of the electrical output is used to power at least in part the at least one first temperature regenerator, the at least one second temperature regenerator, or both.

2. The system of claim 1 wherein the first portion of the at least one thermoelectric generator is a first side of the generator.

3. The systems of claim 1 wherein the second portion of the at least one thermoelectric generator is a second side of the generator.

4. The systems of claim 1 wherein the system is a thermoelectric module that may be vertically stacked.

5. The system of claim 4 wherein the stack comprises at least 1, 2, 3, 4, 5, 6, 7, 8, 10, 15, 20, 30, 40, or 100 of the thermoelectric modules.

6. The systems of claim 1 wherein the system is able to operate in a self sustaining manner between 30% to 50%, 30% to 95%, 50% to 100%, 80% to 98%, 90% to 99.5%, 80% to 100% of the desired operating period.

7. The systems of claim 1 wherein the system provides sufficient electricity between 30% to 50%, 50% to 70%, 30% to 95%, 50% to 100%, 80% to 98%, 95% to 100%, or 80% to 100% of the time that the system is in operation.

8. The systems of claim 1 wherein the system that provides sufficient electricity, heating and/or cooling between 30% to 50%, 40% to 60%, 50% to 70%, 30% to 95%, 50% to 100%, 70% to 95%, 80% to 98%, 90% to 99.5%, 95% to 100%, or 80% to 100% of the time that the system is in operation.

9. The systems of claim 1 wherein at least one of the first temperature storage material and the second temperature storage material is in thermal communication with the at least one thermoelectric generator by the use of at least one heat pipe or heat conduit.

10. The systems of claim 1 wherein at least one of the first temperature storage material is in thermal communication with the surface of the first side of the at least one thermoelectric generator by the use of at least one heat pipe or heat conduit.

11. The systems of claim 1 wherein at least one of the second temperature storage material is in thermal communication with the surface of the second side of the at least one thermoelectric generator by the use of at least one heat pipe or heat conduit.

12. The systems of claim 1 wherein the at least one of the first temperature storage material and the second temperature storage material are partially or substantially thermally insulated from each other and/or the at least one thermoelectric generator and are still in thermal communication with the at least one thermoelectric generator by the use of at least one heat pipe or heat conduit.

13. The systems of claim 1 wherein the thermally stored energy is used to heat or cool another application, (e.g., water heating, water cooling, comfort heating, comfort cooling, air conditioning or combinations thereof).

14. The systems of claim 1 wherein one or more of the first temperature storage material and the second temperature storage material are selected from one or more of the following: air, ambient air, gas, solids such a cement, water, water based salt hydrates, various forms of paraffins, fatty acids and esters, trimethylolethane, organic thermal salts, inorganic thermal salts, ionic liquids, thermal composites, vegetable-based fats or oils.

15. The systems of claim 1 wherein one or more of the first temperature storage material and the second temperature storage material are selected from vegetable-based fats or oils.

16. A system comprising:
at least one thermoelectric generator;
a first temperature storage material in thermal communication with a first portion of the at least one thermoelectric generator;
a second temperature storage material in thermal communication with a second portion of the at least one thermoelectric generator;
at least one temperature regenerator for maintaining at least in part the first temperature storage material at a first temperature range or for maintaining at least in part the second temperature storage material at a second temperature range;
wherein the first temperature is higher than the second temperature and the difference in the temperature of the first temperature storage material and the second temperature storage material creates a thermal difference between the two portions of the at least one thermoelectric generator which creates an electrical output; and
wherein a portion of the electrical output is used to power at least in part the at least one temperature regenerator.

17. The system of claim 16 wherein the first portion of the at least one thermoelectric generator is a first side of the generator.

18. The systems of claim 16 wherein the second portion of the at least one thermoelectric generator is a side of the generator.

19. The systems of claim 16 wherein the system is a thermoelectric module that may be vertically stacked.

20. The system of claim 19 wherein the stack comprises at least 1, 2, 3, 4, 5, 6, 7, 8, 10, 15, 20, 30, 40, or 100 of the thermoelectric modules.

21. The systems of claim 16 wherein the system is able to operate in a self-sustaining manner between 30% to 50%, 30% to 95%, 50% to 100%, 80% to 98%, 90% to 99.5%, 80% to 100% of the desired operating period.

22. The systems of claim 16 wherein the system provides sufficient electricity between 30% to 50%, 50% to 70%, 30% to 95%, 50% to 100%, 80% to 98%, 95% to 100%, or 80% to 100% of the time that the system is in operation.

23. The systems of claim 16 wherein the system that provides sufficient electricity, heating and/or cooling between 30% to 50%, 40% to 60%, 50% to 70%, 30% to 95%, 50% to 100%, 70% to 95%, 80% to 98%, 90% to 99.5%, 95% to 100%, or 80% to 100% of the time that the system is in operation.

24. The systems of claim 16 wherein at least one of the first temperature storage material and the second temperature storage material is in thermal communication with the at least one thermoelectric generator by the use of at least one heat pipe or heat conduit.

25. The systems of claim 16 wherein at least one of the first temperature storage material is in thermal communication with the surface of the first side of the at least one thermoelectric generator by the use of at least one heat pipe or heat conduit.

26. The systems of claim 16 wherein at least one of the second temperature storage material is in thermal communication with the surface of the second side of the at least one thermoelectric generator by the use of at least one heat pipe or heat conduit.

27. The systems of claim 16 wherein the at least one of the first temperature storage material and the second temperature storage material are partially or substantially thermally insulated from each other and/or the at least one thermoelectric generator and are still in thermal communication with the at least one thermoelectric generator by the use of at least one heat pipe or heat conduit.

28. The systems of claim 16 wherein the thermally stored energy is used to heat or cool another application, (e.g., water heating, water cooling, comfort heating, comfort cooling, air conditioning or combinations thereof).

29. The systems of claim 16 wherein one or more of the first temperature storage material and the second temperature storage material are selected from one or more of the following: air, ambient air, gas, solids such a cement, water, water based salt hydrates, various forms of paraffins, fatty acids and esters, trimethylolethane, organic thermal salts, inorganic thermal salts, ionic liquids, thermal composites, vegetable-based fats or oils.

30. The systems of claim 16 wherein one or more of the first temperature storage material and the second temperature storage material are selected from vegetable-based fats or oils.

31. A system comprising:
a) at least a first thermoelectric generator;
a first temperature storage material in thermal communication with a first side of the at least first thermoelectric generator;
a second temperature storage material in thermal communication with a second side of the at least first thermoelectric generator;
b) at least a second thermoelectric generator;
the first temperature storage material in thermal communication with a first side of the at least second thermoelectric generator; and
a third temperature storage material in thermal communication with a second side of the at least second thermoelectric generator;
c) at least a third thermoelectric generator;
a fourth temperature storage material in thermal communication with a first side of the at least third thermoelectric generator;
a third temperature storage material in thermal communication with a second side of the at least third thermoelectric generator;
at least one first temperature regenerator for maintaining at least in part the first temperature storage material at a first temperature range; and
at least one second temperature regenerator for maintaining at least in part the second temperature storage material at a second temperature range;
wherein the first temperature is higher than the second temperature and the difference in the temperatures of the first temperature storage material and the second temperature storage material creates a thermal difference between the two sides of the at least one thermoelectric generator which creates an electrical output;
wherein the first temperature is higher than the third temperature and the difference in the temperatures of the first temperature storage material and the third temperature storage material creates a thermal difference between the two sides of the at least second thermoelectric generator which creates an electrical output;
wherein the fourth temperature is higher than the third temperature and the difference in the temperatures of the fourth temperature storage material and the third temperature storage material creates a thermal difference between the two sides of the at least third thermoelectric generator which creates an electrical output; and wherein a portion of the electrical output from the at least first, second and/or third thermoelectric generators is used to power at least in part the at least one first temperature regenerator, the at least one second temperature regenerator, or both.

32-49. (canceled)
